(19) United States
(12) Patent Application Publication
(10) Pub. No.: US 2012/0109566 A1
(43) Pub. Date: May 3, 2012

(54) METHOD AND APPARATUS FOR CALIBRATING A TEST SYSTEM FOR MEASURING A DEVICE UNDER TEST

(75) Inventor: Vahé A. Adamian, Westlake Village, CA (US)

(73) Assignee: ATE SYSTEMS, INC., North Billerica, MA (US)

(21) Appl. No.: 13/287,458

(22) Filed: Nov. 2, 2011

Related U.S. Application Data
(60) Provisional application No. 61/409,406, filed on Nov. 2, 2010.

(51) Int. Cl. G01R 35/00; G06F 19/00

(52) U.S. Cl. 702/107

(57) ABSTRACT

A calibration method for a two-port VNA includes presenting a high reflection calibration standard and measuring reflection data for each of the two ports, calculating a location of the high reflection calibration standard at each of the two ports, presenting a load calibration standard and measuring the reflection characteristic for each of the two ports to provide load data, converting the load data to the time domain to provide time domain impulse response load data, and gating the time domain impulse response load data based on the locations of the high reflection calibration standard at each of two ports. The method further includes reconstructing frequency domain load data from the gated time domain data, connecting the two ports together and determining forward and reverse transmission characteristics, and calculating systematic error coefficients for the VNA based on the reconstructed frequency domain data and the forward and reverse transmission characteristics.

### CROSS-REFERENCE TO RELATED APPLICATIONS

This application claims priority under 35 U.S.C. §119(e) to U.S. Provisional Application No. 61/409,406 filed Nov. 2, 2010 and titled “METHOD AND APPARATUS FOR CALIBRATING A TEST SYSTEM FOR MEASURING A DEVICE UNDER TEST,” which is herein incorporated by reference in its entirety.

### BACKGROUND

An un-calibrated modern vector network analyzer (VNA) is an extremely repeatable and stable apparatus if it is used in a specified environment recommended by the manufacturer. Although the un-calibrated VNA measurement is repeatable and stable, it inherently has random and systematic (stationary) errors. Measurement errors in any VNA contribute to the measurement uncertainties of the device being measured by the VNA. Systematic errors are the major source of a VNA measurement uncertainty. If systematic errors are characterized and their effects removed from the overall measurements, then the VNA uncertainties are reduced drastically, hence improving the device's measurement accuracy. The more accurately the systematic error coefficients are characterized, the less measurement uncertainty exists for the subject device under test.

Systematic error coefficients are determined by various algorithmic formulations where a set of previously characterized calibration artifacts are connected to a VNA ports and the response of the VNA measurements are subsequently analyzed against the previously characterized calibration artifacts. The accuracy of systematic error coefficients is directly related to the previously characterized calibration artifacts. In other words, the degree of accuracy with which the calibration artifacts are characterized dictates the degree of accuracy to which the subject device under test is measured by a VNA. Although not perfect, better characterization means exist for coaxial artifacts compared to non-coaxial standards. The non-coaxial environment such as on-wafer and fixture measurements is by far the majority of industry's requirement. In spite of this requirement, there is no viable solution for accurate measurement of devices in a non-coaxial environment. Also, the most common coaxial calibration procedure known as SOLT (short, open, load, thru) has accuracy limitations. The deployment of TRL (thru, reflect, load) or some derivative of TRL calibration procedure provides adequate accuracy, but it is cumbersome and time consuming where the industry does not use it in the manufacturing environment.

### SUMMARY OF INVENTION

Accordingly, it is the objective of this invention to provide a method and apparatus for calibrating a VNA to a higher degree of accuracy approaching coaxial TRL level of uncertainty, regardless of the measurement environment. According to one embodiment, the methodology is deployable in a manufacturing environment for two-port or multiport VNA configuration, as discussed further below.

According to one embodiment, a method of calibrating a measurement path in a vector network analyzer having two reference receivers and first and second measurement ports includes presenting a high reflection calibration standard and measuring a reflection characteristic for each of the first and second measurement ports to provide high reflection data, converting the high reflection data into the time domain and calculating a location of the high reflection calibration standard at each of a first device reference plane at the first measurement port and a second device reference plane at the second measurement port, presenting a load calibration standard and measuring the reflection characteristic for each of the first and second measurement ports to provide load data, and converting the load data to the time domain to provide time domain impulse response load data. The method further includes gating the time domain impulse response load data based on the locations of the high reflection calibration standard at each of the first and second device reference planes to provide gated time domain data, reconstructing frequency domain load data from the gated time domain data to provided reconstructed frequency domain data, connecting the first and second measurement ports together and measuring forward and reverse transmission characteristics, and calculating systematic error coefficients for the vector network analyzer based on the reconstructed frequency domain data and the forward and reverse transmission characteristics.

In one example, calculating the systematic error coefficients includes calculating directivity, source match, load match, reflection tracking, and transmission tracking error coefficients for each of the first and second measurement ports. In one example, presenting the high reflection standard includes presenting a short circuit. In another example, presenting the high reflection standard includes presenting an open circuit. Presenting the load calibration standard may include presenting matched loads to each of the first and second measurement ports. The method may further comprise measuring a device and de-embedding measurements of the device using the systematic error coefficients of the vector network analyzer. In one example, presenting the high reflection calibration standard, the load calibration standard and the connecting the first and second measurement ports together comprises providing an electronic calibration standard and coupling the electronic calibration standard to the first and second measurement ports. In another example, presenting the high reflection calibration standard and the load calibration standard comprises providing mechanical calibration standards and coupling the mechanical calibration standards to the first and second measurement ports. In another example, measuring the reflection characteristics and measuring forward and reverse transmission characteristics includes measuring raw data from each of the two reference receivers and first and second measurement ports, and from the raw data, determining the reflection characteristics and the forward and reverse transmission characteristics.

Another embodiment is directed to a method of calibrating a measurement path in a vector network analyzer having at least two reference receivers and a total of 2N measurement ports, N being an integer. In one embodiment the method comprises presenting a high reflection calibration standard and measuring a reflection characteristic for each of the 2N measurement ports, converting the high reflection data into the time domain and calculating a location of the high reflection calibration standard at a device reference plane of each of the 2N measurement ports, presenting a matched load calibration standard at each one of N direct pairs of the 2N measurement ports and measuring forward and reverse reflection and transmission characteristics for each measurement port to provide load data, converting the load data into the time domain to provide time domain impulse response data, and gating the time domain impulse response data by the locations of the high reflection calibration standard at the device reference plane of each measurement port to provide gated time domain data. The method further includes reconstructing frequency domain data from the gated time domain data to provide gated load data, presenting a through calibration standard between the N direct pairs of the 2N measurement ports and measuring forward and reverse reflection and transmission characteristics for each one of the N direct pairs of the 2N measurement ports to provide through data, and calculating systematic error coefficients for each of the 2N measurement ports based on the gated load data and the through data.

In one example, calculating the systematic error coefficients includes calculating directivity, source match, load match, reflection tracking, and transmission tracking error coefficients for each one of the measurement ports. The method may further comprise connecting a 2N port device to the vector network analyzer, measuring the 2N port device to provide measurement data, and correcting the measurement data using the systematic error coefficients. In one example, presenting the high reflection standard includes presenting a short circuit. In another example, presenting the high reflection standard includes presenting an open circuit. In another example, presenting the through calibration standard includes connecting together the two measurement ports of each N direct pairs of measurement ports. In one example, presenting the high reflection calibration standard, the load calibration standard and the connecting the first and second measurement ports together comprises providing an electronic calibration standard and coupling the electronic calibration standard to the first and second measurement ports. In another example, presenting the high reflection calibration standard and the load calibration standard comprises providing mechanical calibration standards and coupling the mechanical calibration standards to the first and second measurement ports.

According to another embodiment, a method of measuring a device under test comprises providing a vector network analyzer having at least two measurement ports, measuring a first reflection characteristic of a high reflection calibration standard at each measurement port, measuring a second reflection characteristic of a matched load calibration standard at each measurement port, converting the first reflection characteristic from frequency-domain into an input time-domain impulse response and calculating a location of the high reflection calibration standard at a device reference plane of each measurement port, and converting the second reflection characteristic from the frequency domain into a time-domain impulse response and gating the time domain impulse response by the location of the high reflection calibration standard at the device reference plane of each respective measurement port. The method further includes reconstructing a corrected second reflection characteristic from the gated time-domain impulse response, connecting the measurement ports together and measuring forward and reverse reflection and transmission characteristics, calculating error coefficients for the at least two measurement ports based upon the forward and reverse reflection and transmission characteristics and the corrected second reflection characteristic, connecting the device under test to the measurement ports, measuring S-parameters at the measurement ports, and correcting for systematic errors in the S-parameters based upon the error coefficients to yield a corrected S-parameter matrix for the device under test.

In one example wherein the vector network analyzer further includes two reference channels, measuring the first and second reflection characteristics includes collecting first raw data from each of the two reference channels and the at least two measurement ports, and determining the first and second reflection characteristics from the first raw data. Measuring the forward and reverse reflection and transmission characteristics may include collecting second raw data from each of the two reference channels and the at least two measurement ports, and determining the forward and reverse reflection and transmission characteristics from the second raw data.

According to another embodiment, a method of calibrating a 2N-port test system for measurement of a 2N-port device under test (DUT), where N is an integer, comprises coupling each port of a 2N-port automatic calibration device to a respective port of the 2N-port test system, presenting with the 2N-port automatic calibration device a high reflection calibration standard and measuring a reflection characteristic for each of the 2N measurement ports, converting the high reflection data into the time domain and calculating a location of the high reflection calibration standard at a device reference plane of each of the 2N measurement ports, presenting with the 2N-port automatic calibration device a matched load calibration standard at each one of N direct pairs of the 2N measurement ports and measuring forward and reverse reflection and transmission characteristics for each measurement port to provide load data, and converting the load data into the time domain to provide time domain impulse response data. The method further includes gating the time domain impulse response data by the locations of the high reflection calibration standard at the device reference plane of each of the 2N measurement ports to provide gated time domain data, reconstructing frequency domain data from the gated time domain data to provide gated load data, presenting with the 2N-port automatic calibration device a through calibration standard between the N direct pairs of the measurement ports and measuring forward and reverse reflection and transmission characteristics for each one of the N direct pairs of the 2N measurement ports to provide through data, and calculating systematic error coefficients for each of the 2N measurement ports based on the gated load data and the through data.

In one example determining the systematic error coefficients comprises determining corresponding one-port error coefficients for each port of the 2N-port multiport test system. In another example, determining systematic error coefficients comprises determining a load match for each port of the 2N-port multiport test system. In another example, determining systematic error coefficients comprises determining a directivity for each port of the 2N-port test system. The step of determining systematic error coefficients may comprise determining a source match for each port of the 2N-port multiport test system. The step of determining systematic error coefficients may comprise determining a reflection tracking for each port of the 2N-port multiport test system. In one example, determining the systematic error coefficients comprises determining N(N−1)/2 forward transmission tracking coefficients for all N(N−1)/2 two-port paths between all 2N-ports of the 2N-port test system. In another example, determining the systematic error coefficients comprises determining N(N−1)/2 reverse transmission tracking coefficients for all N(N−1)/2 two-port paths between all 2N-ports of the 2N-port multiport test system.

According to another embodiment, an apparatus for calibrating a measurement path comprises a vector network analyzer having at least two reference receivers, two test channels, a first measurement port and a second measurement port, means for measuring and storing high reflection characteristics for each of the first and second measurement ports when a high reflection calibration standard is connected thereto, load reflection characteristics for each of the first and second measurement ports when a matched load calibration standard is attached thereto, and through forward and reverse reflection and transmission characteristics for each of the first and second measurement ports when connected to each other, and a processor configured to convert the high reflection characteristics into reflection time-domain data and calculate a location of the high reflection calibration standard at each of the first and second measurement ports, to convert the load reflection characteristics into load time-domain data, to gate the load time-domain data by the location of the high reflection calibration standard at each respective measurement port to provide gated load time-domain data, and to reconstruct corrected frequency-domain load reflection characteristics from the gated load time-domain data, the controller being further configured to calculate error coefficients for the first and second measurement ports based on the corrected frequency-domain load reflection characteristics and the through forward and reverse reflection and transmission characteristics.

In one example of the apparatus, the error coefficients include directivity, source match, load match, transmission tracking, and reflection tracking coefficients. The apparatus may further comprise means for measuring two port device resulting in a raw measurement of the device, wherein the controller is further configured to correct the raw measurement using the error coefficients. In one example, the high reflection calibration standard is a short circuit calibration standard. In another example, the high reflection calibration standard is an open circuit calibration standard. The means for measuring may further comprise means for measuring a two port device to obtain DUT measurements, wherein said processor is further configure to correct said DUT measurements using the error coefficients for the first and second measurement ports.

According to another embodiment, an apparatus for calibrating a measurement path comprises a vector network analyzer having at least two reference receivers, two test channels, and 2N measurement ports, wherein N is an integer, means for measuring and storing high reflection characteristics for each of the 2N measurement ports when a high reflection calibration standard is connected thereto, load reflection characteristics for each of the 2N measurement ports when a matched load calibration standard is attached thereto, and through forward and reverse reflection and transmission characteristics for each one of N direct pairs of said measurement ports when connected to each other, and a processor configured to convert the high reflection characteristics into reflection time-domain data and calculate a location of the high reflection calibration standard at each of the 2N measurement ports, to convert the load reflection characteristics into load time-domain data, to gate the load time-domain data by the location of the high reflection calibration standard at each respective measurement port to provide gated load time-domain data, and to reconstruct corrected frequency-domain load reflection characteristics from the gated load time-domain data, the controller being further configured to calculate error coefficients for the 2N measurement ports based on the corrected frequency-domain load reflection characteristics and the through forward and reverse reflection and transmission characteristics.

Another embodiment is directed to a combination of a 2N-port test set that can characterize a multi-port device under test (DUT) and an 2N-port multiport automatic calibration device, wherein each port of the 2N-port automatic calibration device is coupled to a respective port of the 2N-port test set, the 2N-port test set and the 2N port automatic calibration device in combination being configured to present with the 2N-port automatic calibration device a high reflection calibration standard and measuring a reflection characteristic for each of the 2N measurement ports, and convert the high reflection data into the time domain and calculating a location of the high reflection calibration standard at a device reference plane of each of the 2N measurement ports. The combination is further configured to present with the 2N-port automatic calibration device a matched load calibration standard at each one of N direct pairs of the 2N measurement ports and measuring forward and reverse reflection and transmission characteristics for each measurement port to provide load data, convert the load data into the time domain to provide time domain impulse response data, gate the time domain impulse response data by the locations of the high reflection calibration standard at the device reference plane of each of the 2N measurement ports to provide gated time domain data, reconstruct frequency domain data from the gated time domain data to provide gated load data, present with the 2N-port automatic calibration device a through calibration standard between the N direct pairs of the measurement ports and measuring forward and reverse reflection and transmission characteristics for each one of the N direct pairs of the 2N measurement ports to provide through data, and calculate systematic error coefficients for each of the 2N measurement ports based on the gated load data and the through data.

In one example, the combination is further configured to determine corresponding one-port error coefficients for each port of the 2N-port test set. The combination may be further configured to determine a load match for each port of the 2N-port test set. The combination may be further configured to determine a directivity for each port of the 2N-port test set. In another example, the combination is further configured to determine a source match for each port of the 2N-port test set. In another example, the combination is further configured to determine a reflection tracking for each port of the 2N-port test set. The combination may be further configured to determine N(N−1)/2 forward transmission tracking coefficients for N(N−1)/2 two-port paths between all 2N-ports of the 2N-port test set. In another example, the combination is further configured to determine N(N−1)/2 reverse transmission tracking coefficients for N(N−1)/2 two-port paths between all 2N-ports of the 2N-port test set.

Still other aspects, embodiments, and advantages of these exemplary aspects and embodiments, are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a simplified block diagram of one example of a two-port vector network analyzer;

FIG. 2 is a block diagram of the two-port vector network analyzer showing a high reflection standard connected at the port 1 device reference plane in a first step of a calibration procedure according to aspects of the invention;

FIG. 3 is a block diagram of the two-port vector network analyzer showing the high reflection standard connected at the port 2 device reference plane in a second step of the calibration procedure according to aspects of the invention;

FIG. 4 is a graph showing the A/R1 time domain impulse response of the high reflection standard at the port 1 device reference plane of the vector network analyzer, according to aspects of the invention;

FIG. 5 is a graph showing the B/R2 time domain impulse response of the high reflection standard at the port 2 device reference plane of the vector network analyzer, according to aspects of the invention;

FIG. 6 is a block diagram of the two-port vector network analyzer showing a high quality matched termination standard connected to each of the port 1 and port 2 device reference planes in a next step of the calibration procedure according to aspects of the invention;

FIG. 7 is another block diagram of the two-port vector network analyzer showing a high quality matched termination standard connected to each of the port 1 and port 2 device reference planes in a next step of the calibration procedure according to aspects of the invention;

FIG. 8 is a graph showing the A/R1 time domain impulse response of the termination standard gated between −700 cm and 7.67 cm, with 7.67 cm being the location of the high reflection port 1 device reference plane, according to aspects of the invention;

FIG. 9A is a graph showing the reconstructed frequency domain of the magnitude (in dB) of A/R1 from the gated time domain impulse response of the termination standard at the port 1 device reference plane (FIG. 8), according to aspects of the invention;

FIG. 9B is a graph showing the reconstructed frequency domain of the argument (in degrees) of A/R1 from the gated time domain impulse response of the termination standard at the port 1 device reference plane (FIG. 8), according to aspects of the invention;

FIG. 10 is a graph showing the B/R2 time domain impulse response of the termination standard gated between −700 cm and 235.24 cm, with 235.24 cm being the location of the high reflection port 2 device reference plane, according to aspects of the invention;

FIG. 11A is a graph showing the reconstructed frequency domain of the magnitude (in dB) of B/R2 from the gated time domain impulse response of the termination standard at the port 2 device reference plane (FIG. 10), according to aspects of the invention;

FIG. 11B is a graph showing the reconstructed frequency domain of the argument (in degrees) of B/R2 from the gated time domain impulse response of the termination standard at the port 2 device reference plane (FIG. 10), according to aspects of the invention;

FIG. 12 is a block diagram of the two-port vector network analyzer showing the port 1 device reference plane connected to the port 2 device reference plane to provide a thru standard, according to aspects of the invention;

FIG. 13 is another block diagram of the two-port vector network analyzer showing the port 1 device reference plane connected to the port 2 device reference plane to provide the thru standard, according to aspects of the invention;

FIG. 14 is a flow graph illustrating an example of an unknown short, load and thru calibration according to aspects of the invention;

FIG. 15A is a graph showing a comparison of the magnitude (in dB) of the S₁₁ coefficient of a 50 Ohm airline measured using a TRL calibration procedure and a conventional SOLT calibration procedure;

FIG. 15B is graph showing a comparison of the argument (in degrees) of the S₁₁ coefficient of a 50 Ohm airline measured using a TRL calibration procedure and a conventional SOLT calibration procedure;

FIG. 16A is a graph showing a comparison of the magnitude (in dB) of the S₂₁ coefficient of the 50 Ohm airline measured using the TRL calibration procedure and the conventional SOLT calibration procedure;

FIG. 16B is a graph showing a comparison of the argument (in degrees) of the S₂₁ coefficient of the 50 Ohm airline measured using the TRL calibration procedure and the conventional SOLT calibration procedure;

FIG. 17A is a graph showing a comparison of the magnitude (in dB) of the S₁₁ coefficient of a 50 Ohm airline measured using a TRL calibration procedure and a modified SOLT calibration procedure according to aspects of the invention;

FIG. 17B is graph showing a comparison of the argument (in degrees) of the S₁₁ coefficient of the 50 Ohm airline measured using a TRL calibration procedure a modified SOLT calibration procedure according to aspects of the invention;

FIG. 18A is a graph showing a comparison of the magnitude (in dB) of the S₂₁ coefficient of the 50 Ohm airline measured using the TRL calibration procedure and the modified SOLT calibration procedure according to aspects of the invention;

FIG. 18B is a graph showing a comparison of the argument (in degrees) of the S₂₁ coefficient of the 50 Ohm airline measured using the TRL calibration procedure and the modified SOLT calibration procedure according to aspects of the invention;

FIG. 19A is a graph showing a comparison of the magnitude (in dB) of the S₁₁ coefficient of a 50 Ohm airline measured using a TRL calibration procedure and an embodiment of an unknown short, load and thru (uSLT) time domain calibration procedure according to aspects of the invention;

FIG. 19B is graph showing a comparison of the argument (in degrees) of the S₁₁ coefficient of the 50 Ohm airline measured using a TRL calibration procedure the uSLT calibration procedure according to aspects of the invention;

FIG. 20A is a graph showing a comparison of the magnitude (in dB) of the S₂₁ coefficient of the 50 Ohm airline measured using the TRL calibration procedure and the uSLT calibration procedure according to aspects of the invention;

FIG. 20B is a graph showing a comparison of the argument (in degrees) of the S₂₁ coefficient of the 50 Ohm airline measured using the TRL calibration procedure and the uSLT calibration procedure according to aspects of the invention;

FIG. 21A is a graph showing a comparison of the magnitude (in dB) of the S₁₁ coefficient of a 25 Ohm mismatched airline measured using a TRL calibration procedure and the uSLT time domain calibration procedure according to aspects of the invention;

FIG. 21B is graph showing a comparison of the argument (in degrees) of the S₁₁ coefficient of the 25 Ohm mismatched airline measured using the TRL calibration procedure the uSLT calibration procedure according to aspects of the invention;

FIG. 22A is a graph showing a comparison of the magnitude (in dB) of the S₂₁ coefficient of the 25 Ohm mismatched airline measured using the TRL calibration procedure and the uSLT time domain calibration procedure according to aspects of the invention;

FIG. 22B is graph showing a comparison of the argument (in degrees) of the S₂₁ coefficient of the 25 Ohm mismatched airline measured using the TRL calibration procedure the uSLT calibration procedure according to aspects of the invention;

FIG. 23 is a block diagram of one example of a four-port vector network analyzer;

FIG. 24 a flow graph illustrating an example of decomposition of 4-by-4 S-parameters into six subsets of 2-by-2 S-parameters, according to aspects of the invention;

FIG. 25 is a block diagram of one example of a vector network analyzer showing a high reflection standard connected at the port 1 device reference plane in a first step of a calibration procedure according to aspects of the invention;

FIG. 26 is a block diagram of the vector network analyzer showing the high reflection standard connected at the port 3 device reference plane in a next step of a calibration procedure according to aspects of the invention;

FIG. 27 is a graph illustrating the A/R1 time domain impulse response of the high reflection standard at the port 1 device reference plane of the vector network analyzer, according to aspects of the invention;

FIG. 28 is a graph illustrating the B/R2 time domain impulse response of the high reflection standard at the port 3 device reference plane of the vector network analyzer, according to aspects of the invention;

FIG. 29 is a block diagram of the vector network analyzer showing a high quality matched termination standard connected to each of the port 1 and port 3 device reference planes, according to aspects of the invention;

FIG. 30 is another block diagram of the vector network analyzer showing the high quality matched termination standards connected to each of the port 1 and port 3 device reference planes in a next step of the calibration procedure according to aspects of the invention;

FIG. 31 is a graph showing the A/R1 time domain impulse response of the termination standard gated between −250 cm and 29.68 cm, with 29.68 cm being the location of the high reflection port 1 device reference plane, according to aspects of the invention;

FIG. 32A is a graph showing the reconstructed frequency domain of the magnitude (in dB) of A/R1 from the gated time domain impulse response of the termination standard at the port 1 device reference plane, according to aspects of the invention;

FIG. 32B is a graph showing the reconstructed frequency domain of the argument (in degrees) of A/R1 from the gated time domain impulse response of the termination standard at the port 1 device reference plane, according to aspects of the invention;

FIG. 33 is a graph showing the B/R2 time domain impulse response of the termination standard gated between −250 cm and 30.49 cm, with 30.49 cm being the location of the high reflection port 3 device reference plane, according to aspects of the invention;

FIG. 34A is a graph showing the reconstructed frequency domain of the magnitude (in dB) of B/R2 from the gated time domain impulse response of the termination standard at the port 3 device reference plane, according to aspects of the invention;

FIG. 34B is a graph showing the reconstructed frequency domain of the argument (in degrees) of B/R2 from the gated time domain impulse response of the termination standard at the port 3 device reference plane, according to aspects of the invention;

FIG. 35 is a block diagram of the vector network analyzer showing port 1 and port 3 connected together to provide a thru standard, and the switch set in a first configuration, according to aspects of the invention;

FIG. 36 is a block diagram of the vector network analyzer showing port 1 and port 3 connected together to provide the thru standard, and the switch set in a second configuration, according to aspects of the invention;

FIG. 37 is a block diagram of the vector network analyzer showing port 1 and port 3 connected together to provide the thru standard, and the switch set in a third configuration, according to aspects of the invention;

FIG. 38 is a block diagram of the vector network analyzer showing port 1 and port 3 connected together to provide the thru standard, and the switch set in a second configuration, according to aspects of the invention;

FIG. 39 is a block diagram the vector network analyzer showing the high reflection standard connected at the port 2 device reference plane, according to aspects of the invention;

FIG. 40 is a block diagram of the vector network analyzer showing the high reflection standard connected at the port 4 device reference plane, according to aspects of the invention;

FIG. 41 is a graph illustrating the A/R1 time domain impulse response of the high reflection standard at the port 2 device reference plane of the vector network analyzer, according to aspects of the invention;

FIG. 42 is a graph illustrating the B/R2 time domain impulse response of the high reflection standard at the port 4 device reference plane of the vector network analyzer, according to aspects of the invention;

FIG. 43 is a block diagram of the vector network analyzer showing the high quality matched termination standards connected to each of the port 2 and port 4 device reference planes, according to aspects of the invention;

FIG. 44 is another block diagram of the vector network analyzer showing the high quality matched termination standards connected to each of the port 2 and port 2 device reference planes, according to aspects of the invention;

FIG. 45 is a graph showing the A/R1 time domain impulse response of the termination standard gated between −250 cm and 29.68 cm, with 29.68 cm being the location of the high reflection port 2 device reference plane, according to aspects of the invention;

FIG. 46A is a graph showing the reconstructed frequency domain of the magnitude (in dB) of A/R1 from the gated time domain impulse response of the termination standard at the port 2 device reference plane, according to aspects of the invention;

FIG. 46B is a graph showing the reconstructed frequency domain of the argument (in degrees) of A/R1 from the gated time domain impulse response of the termination standard at the port 2 device reference plane, according to aspects of the invention;

FIG. 47 is a graph showing the B/R2 time domain impulse response of the termination standard gated between −250 cm and 32.91 cm, with 32.91 cm being the location of the high reflection port 4 device reference plane, according to aspects of the invention;

FIG. 48A is a graph showing the reconstructed frequency domain of the magnitude (in dB) of B/R2 from the gated time domain impulse response of the termination standard at the port 4 device reference plane, according to aspects of the invention;

FIG. 48B is a graph showing the reconstructed frequency domain of the argument (in degrees) of B/R2 from the gated time domain impulse response of the termination standard at the port 4 device reference plane, according to aspects of the invention;

FIG. 49 is a block diagram of the vector network analyzer showing port 2 and port 4 connected together to provide the thru standard, and the switch set in a first configuration, according to aspects of the invention;

FIG. 50 is a block diagram of the vector network analyzer showing port 2 and port 4 connected together to provide the thru standard, and the switch set in a second configuration, according to aspects of the invention;

FIG. 51 is a block diagram of the vector network analyzer showing port 2 and port 4 connected together to provide the thru standard, and the switch set in a third configuration, according to aspects of the invention;

FIG. 52 is a block diagram of the vector network analyzer showing port 2 and port 4 connected together to provide the thru standard, and the switch set in a fourth configuration, according to aspects of the invention;

FIG. 53 is a block diagram of the vector network analyzer showing port 2 and port 3 connected together to provide the thru standard, and the switch set in a first configuration, according to aspects of the invention;

FIG. 54 is a block diagram of the vector network analyzer showing port 2 and port 3 connected together to provide the thru standard, and the switch set in a second configuration, according to aspects of the invention;

FIGS. 55A-55P are graphs illustrating the overlay of S-parameter magnitude of a directional coupler measured on the same VNA by using conventional TRL (solid lines) and SOLT (dotted lines) calibration procedures;

FIGS. 56A-56P are graphs illustrating the overlay of S-parameter magnitude of the directional coupler measurement with the same VNA using an uSLT calibration procedure according to an embodiment of the invention (dotted lines), overlaid with the TRL data (solid lines) of FIGS. 55A-55P, respectively;

FIG. 57 is a block diagram of one example of a 20 port fixture showing unknown short measurements at the device reference plane, according to aspects of the invention;

FIG. 58 is a block diagram of the 20 port fixture showing the load measurements at the device reference plane, according to aspects of the invention;

FIG. 59 is a block diagram of the 20 port fixture showing 10 direct opposite port connections, according to aspects of the invention;

FIG. 60 is a block diagram of the 20 port fixture showing 9 closest direct opposite port connections, according to aspects of the invention; and

FIG. 61 is a block diagram of the 20 port fixture showing the device under test (DUT) inserted for measurement, according to aspects of the invention.

### DETAILED DESCRIPTION

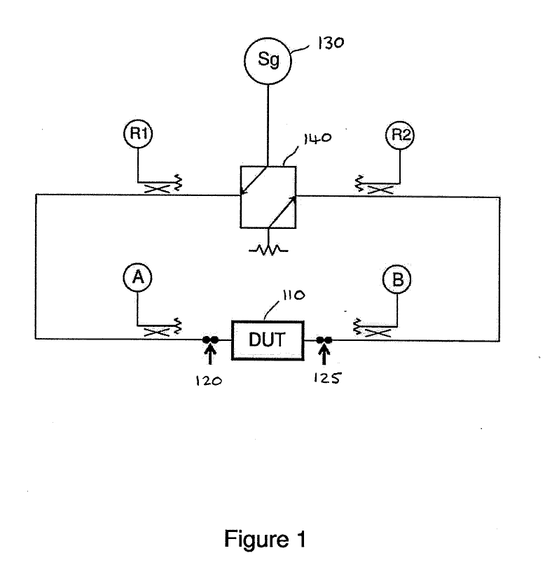

With reference to FIG. 1, there is shown a simple block diagram of a modern two-port vector network analyzer (VNA) for use in certain embodiments of the invention. The device under test (DUT) 110 is connected to the VNA at the port 1 device reference plane (DRP) 120 and port 2 DRP 125. Aspects and embodiments of the invention are applicable to two-port as well as multiport configurations of a VNA. First the two-port configuration and then the multiport configuration will be described.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. Any references to embodiments or elements or acts of the systems and methods herein referred to in the singular may also embrace embodiments including a plurality of these elements, and any references in plural to any embodiment or element or act herein may also embrace embodiments including only a single element. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

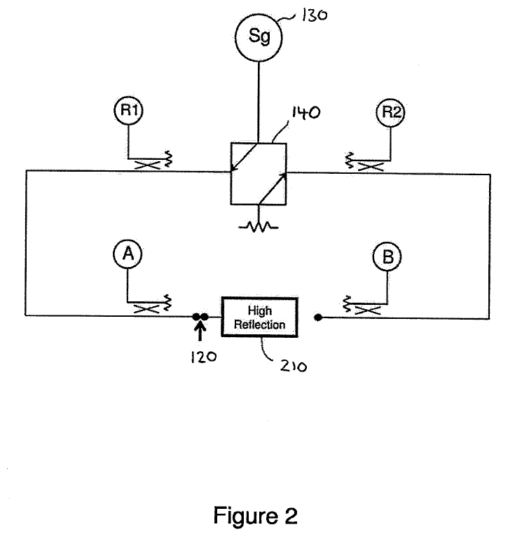

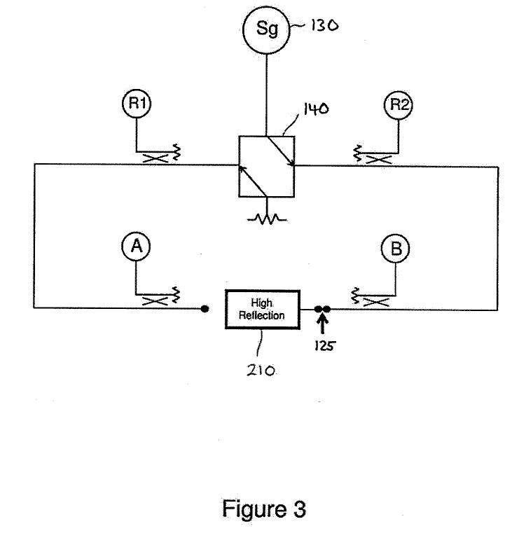

Referring to FIG. 2, an unknown high reflection standard 210 such as short circuit is connected to VNA's port 1 DRP 120 while the signal generator 130 is directed to R1 reference channel path (forward direction) by the transfer switch 140. By sweeping the signal generator 130 through a desired frequency range, a measurement of A/R1 reflection coefficient of unknown reflection standard 210 is performed. With reference to FIG. 3, the same unknown high reflection 210 is disconnected from port 1 and then connected to the port 2 DRP 125. The signal generator 130 is now directed to R2 reference channel path (reverse direction) by the switch 140 and a measurement of B/R2 reflection coefficient is performed by sweeping through the same desired frequency range. In a non-coaxial configuration two different high reflection standards are connected to the VNA ports and it is assumed these two standards are substantially the same.

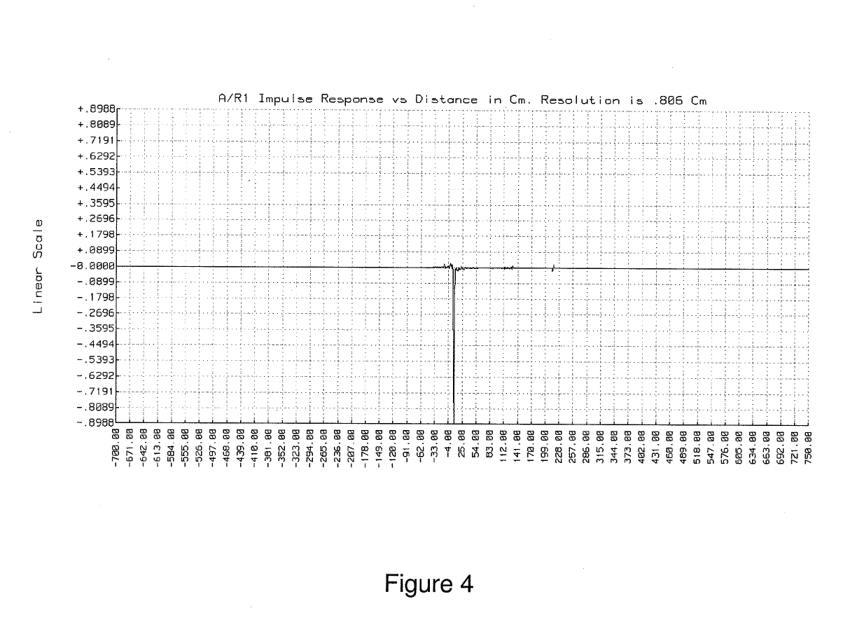

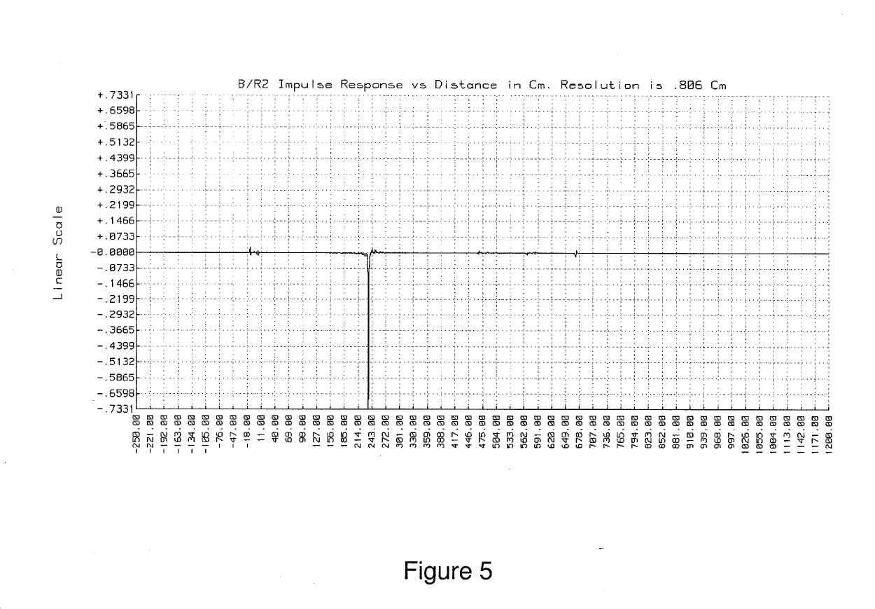

With reference to FIG. 4, the measured high reflection A/R1 data is converted from frequency domain into time-domain impulse response by the procedure described in “An Analysis of Vector Measurement Accuracy,” Douglas Rytting, Hewlett-Packard Technical Seminar, May 1986 (which is herein incorporated by reference in its entirety). In this example, the frequency domain was swept from 10 MHz to 18000 MHz. The high reflection standard 210 is a short circuit with a negative magnitude of approximately 0.9 ratio, located approximately 7.67 centimeters (cm); a distance in air. Time and distance are interchangeable, where one nanosecond is approximately 30 cm in air. The time domain was swept in distance from −700 cm to 750 cm. A broad time sweep insures capturing all frequency domain responses without causing aliasing. This procedure can be verified by reconverting back the time domain into frequency domain and correlating the result with the original measured data. In this example, the location of short circuit at port 1 DRP 120 is 7.67 cm. This distance has been influenced by the port 1 VNA's systematic error coefficients. Referring to FIG. 5, the measured high reflection B/R2 data is converted from frequency domain into time-domain impulse response. Again the frequency domain was swept from 10 MHz to 18000 MHz and time domain observed from −250 cm to 1200 cm. The high reflection is a short circuit with a negative magnitude of approximately 0.73 ratio, located approximately 235.24 cm. The location of short circuit at port 2 DRP 125 is approximately 235.24 cm. This distance has been influenced by the port 2 VNA's systematic error coefficients.

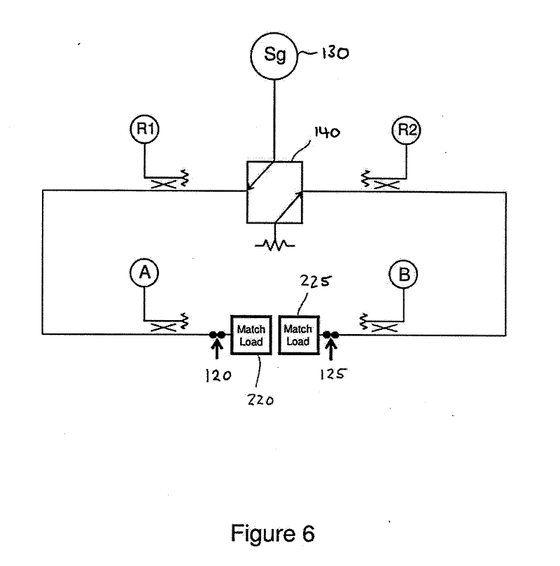

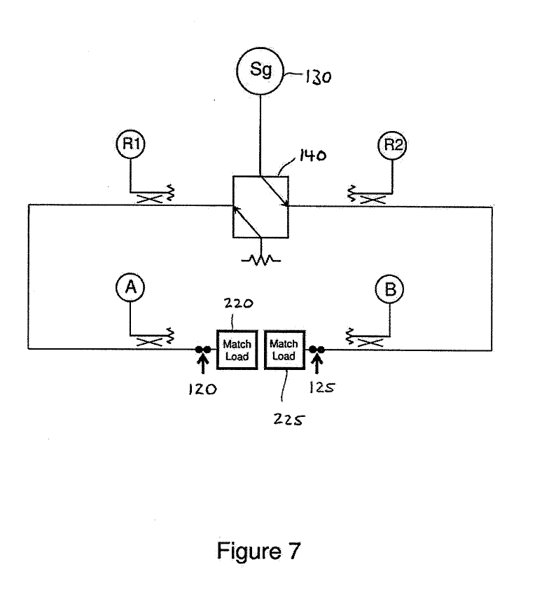

Referring to FIG. 6, a high quality termination standard 220 is connected to VNA's port 1 DRP 120 and another high quality termination 225 is connected to VNA's port 2 DRP 125 while the signal generator 130 is directed to R1 reference channel path by the transfer switch 140. By sweeping the signal generator 130 through the same desired frequency range as before, R1, A, B and R2 receiver channels are measured in the forward direction. Referring to FIG. 7, without removing the high quality terminations 220, 225, the signal generator 130 is directed to R2 reference channel path by the transfer switch 140 and R2, B, A and R1 receiver channels are measured in the reverse direction.

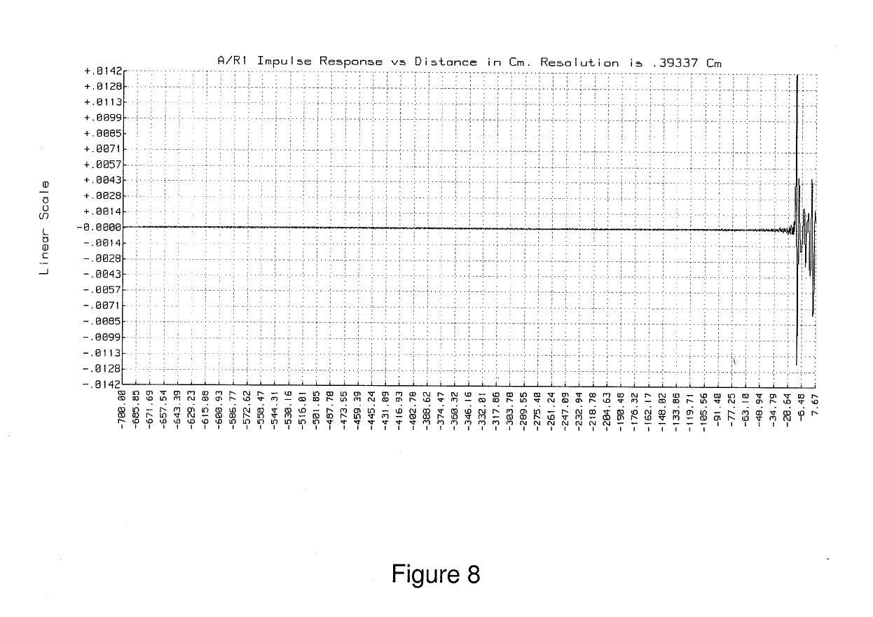

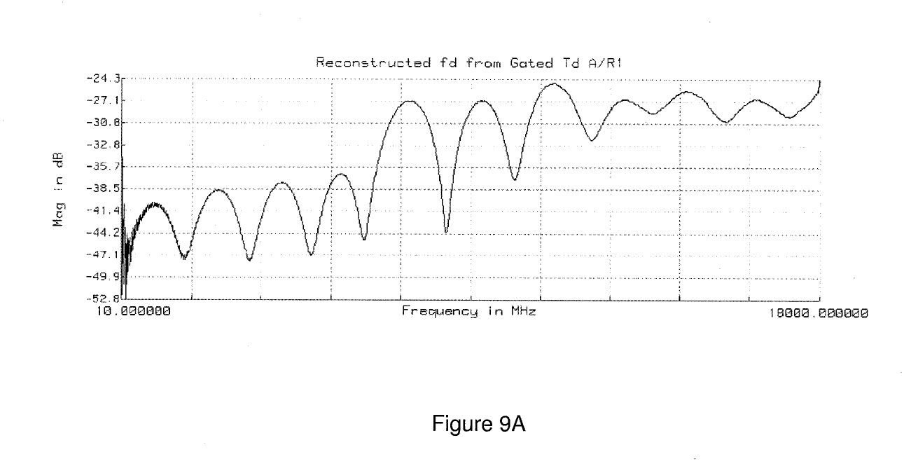

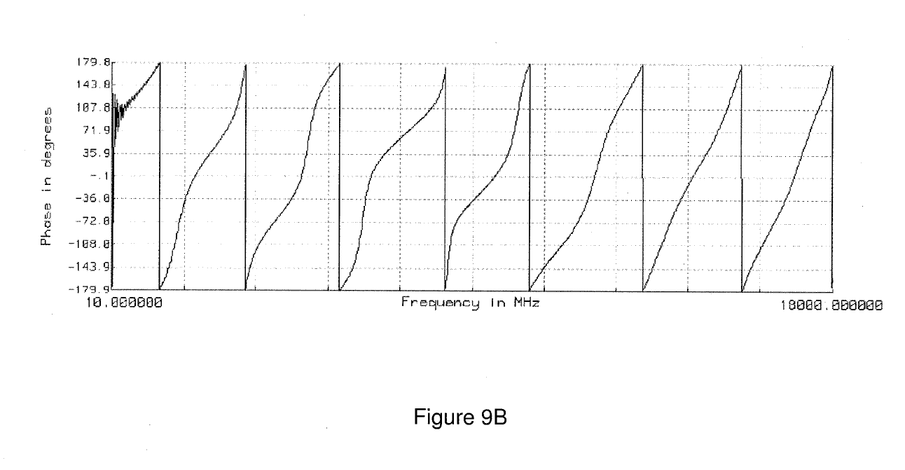

Referring to FIG. 8, in forward direction the ratio of A/R1 is converted to time domain impulse response and gated between the port1 time start sweep and the port 1 DRP location of the high reflection standard. Then, the gated impulse response is converted back to frequency domain; the reconstructed frequency domain response is equivalent of putting a perfect termination on the original A/R1 frequency domain VNA measurement. FIGS. 9A and 9B illustrate the A/R1 magnitude (9A) and phase (9B) response as if a perfect termination is connected at port1 DRP 120.

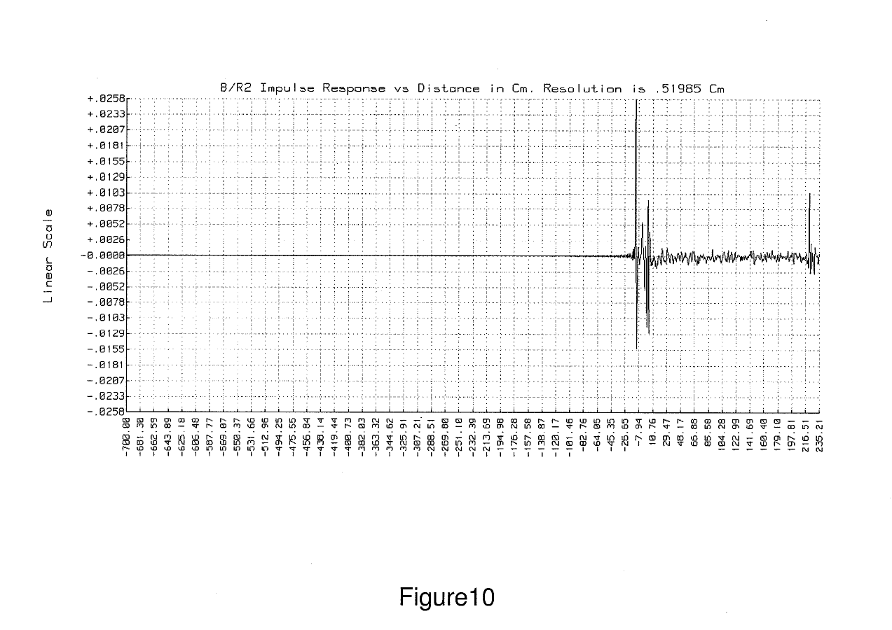

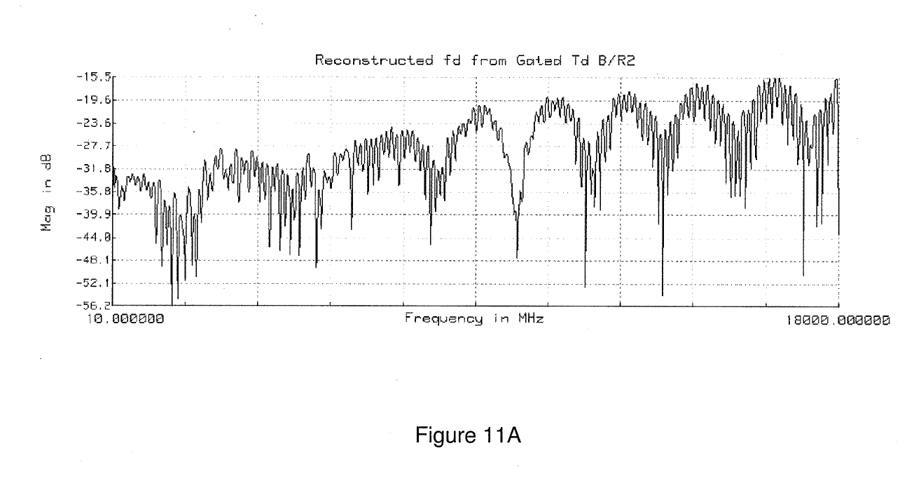

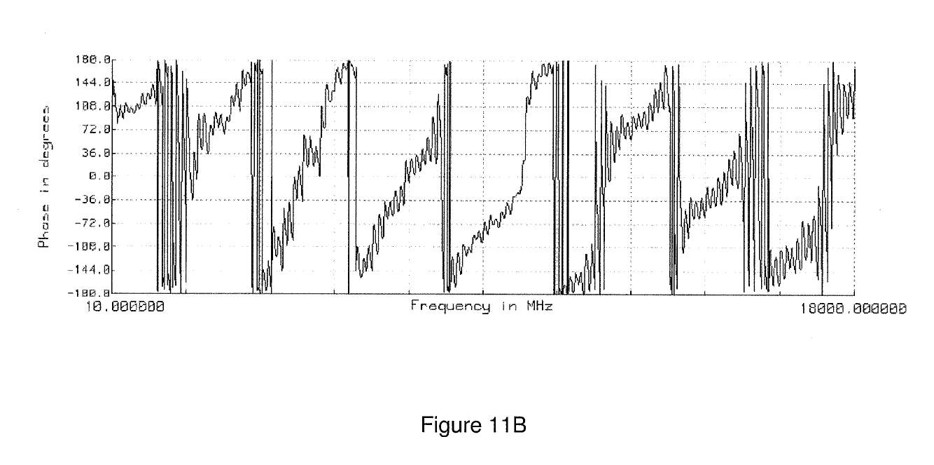

With reference to FIG. 10, in reverse direction the ratio of B/R2 is converted to time domain impulse response and gated between the port 1 time start sweep and the port 2 DRP location of the high reflection standard. Then, the gated impulse response is converted back to frequency domain; the reconstructed frequency domain response is equivalent of putting a perfect termination on the original B/R2 frequency domain VNA measurement. FIGS. 11A and 11B illustrate the B/R2 magnitude (11A) and phase (11B) response as if a perfect termination is connected at the port2 DRP.

In any calibration procedure in which one of the calibration standards used is a termination (load), ideally one would like the high quality termination or load to have a perfect match over the entire frequency range of calibration, but that is physically impossible. However, according to aspects of this disclosure, by gating the termination/load time-domain impulse response by the location of high reflection standard, as discussed above, the appearance of a perfectly matched termination is achieved. Mechanical calibration procedures such as SOLT, an unknown-thru, TRL, LRM, etc. use a termination as one of the calibration standards. In mechanical calibration procedures, the directivity error is solely determined by the termination standard. Therefore, by gating the load as discussed above according to this disclosure, the directivity error is similarly gated, thus improving its accuracy, as discussed further below. It is to be appreciated that this is one advantage achieved by the gating of the load standard according to this disclosure.

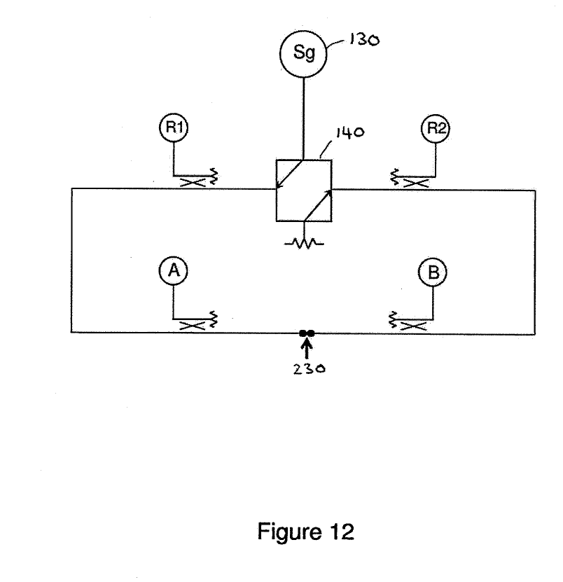

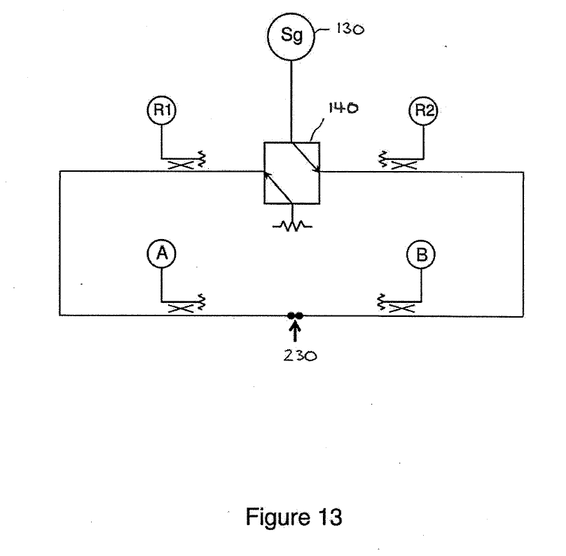

Referring to FIG. 12, the port 1 DRP is connected directly to the port 2 DRP as a thru standard connection 230. The signal generator 130 is directed to R1 reference channel path by the transfer switch 140. By sweeping the signal generator through the same desired frequency range as before, R1, A, B and R2 receiver channels are measured in forward direction. With reference to FIG. 13, the signal generator 130 is directed to R2 reference channel path by the transfer switch 140 and R2, B, A and R1 receiver channels are measured in reverse direction.

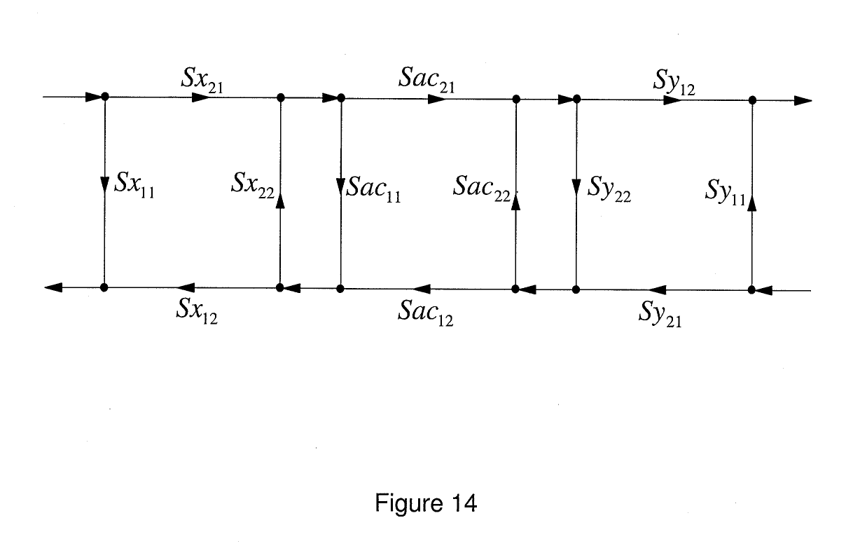

Referring to FIG. 14, the calibration procedure for unknown short, load and thru between port 1 and port 2 of a VNA is presented. The flow graph represents error adapter S-parameters matrix Sx corresponding to the first port, error adapter matrix S-parameters Sy corresponding to the second port and an actual calibration standard S-parameters matrix S_{ac} embedded between the two error adapters. Converting the S-parameters in terms of their equivalent T-parameters the following equations can be written

TxTₐₜTy=Tₘₜ (1)

TxTₐₗTy=Tₘₗ (2)

Tx is the T-parameters of error adapter Sx, Ty is the T-parameters of error adapter Sy, Tₐₜ is the T-parameters of actual thru standard, Tₘₜ is the T-parameters of measured thru standard, Tₐₗ is the T-parameters of actual load standard and Tₘₗ is the T-parameters of measured load standard. From Equations (1) and (2) and definitions of Tₐ=TₐₗTₐₜ⁻¹, Tₘ=TₘₗTₘₜ⁻¹ the following equation can be written:

TxTₐ=TₘTx (3)

Referring to the Sx error adapter of FIG. 14, the general equation for T-parameters in terms of corresponding S-parameters where port 1 is on the left and port 2 is on the right is given by:

$$[ \begin{matrix}{Tx}_{11} & {Tx}_{12} \\ {Tx}_{21} & {Tx}_{22}\end{matrix} ] = [ \begin{matrix}\frac{1}{{Sx}_{21}} & \frac{- {Sx}_{22}}{{Sx}_{21}} \\ \frac{{Sx}_{11}}{{Sx}_{21}} & \frac{{Sx}_{12} {Sx}_{21} - {Sx}_{11} {Sx}_{22}}{{Sx}_{21}}\end{matrix} ] \qquad ( 4 )$$

The thru and load standards are assumed both to have perfectly matched reflection coefficients. Therefore, the value of their reflection coefficient is set to zero. If through standard has a non-zero-length transmission coefficient defined by Sₗ₁=S₂₁ₜₕᵣᵤ=S₁₂ₜₕᵣᵤ and two high quality loads with a transmission isolation coefficient defined by S_{ε}=S_{21load}=S_{12load} then Tₐ can be calculated. S_{ε} is, the transmission isolation has a very small value. Tₐ is given by:

$${T}_{a} = [ \begin{matrix}\frac{{S}_{l 1}}{{S}_{ɛ}} & 0 \\ 0 & \frac{{S}_{ɛ}}{{S}_{l 1}}\end{matrix} ] \qquad ( 5 )$$

The thru or load calibration step each provides a total of eight receiver measurements during the forward and reverse settings of VNA transfer switch 140. The flow graph model shown in FIG. 14 does not take the source and load changes of the transfer switch into consideration as it switches from forward to reverse position. This error for termination standard in a coaxial environment is extremely small due to high transmission isolation, but this may not be the case for a non-coaxial environment. The change in source and load variations is corrected by an algorithmic formulation in the S-parameter domain before calculating the Tₘ matrix. The correction algorithmic is given by:

$${S}_{m} = [ \begin{matrix}( \frac{\frac{{A}_{f}}{{R}_{1 f}} - \frac{{A}_{r}}{{R}_{2 r}} \frac{{R}_{2 f}}{{R}_{1 f}}}{1 - \frac{{R}_{2 f}}{{R}_{1 f}} \frac{{R}_{1 r}}{{R}_{2 r}}} ) & ( \frac{\frac{{A}_{r}}{{R}_{2 r}} - \frac{{A}_{f}}{{R}_{1 r}} \frac{{R}_{1 r}}{{R}_{2 r}}}{1 - \frac{{R}_{2 f}}{{R}_{1 f}} \frac{{R}_{1 r}}{{R}_{2 r}}} ) \\ ( \frac{\frac{{B}_{f}}{{R}_{1 f}} - \frac{{B}_{r}}{{R}_{2 r}} \frac{{R}_{2 f}}{{R}_{1 f}}}{1 - \frac{{R}_{2 f}}{{R}_{1 f}} \frac{{R}_{1 r}}{{R}_{2 r}}} ) & ( \frac{\frac{{B}_{r}}{{R}_{2 r}} - \frac{{B}_{f}}{{R}_{1 r}} \frac{{R}_{1 r}}{{R}_{2 r}}}{1 - \frac{{R}_{2 f}}{{R}_{1 f}} \frac{{R}_{1 r}}{{R}_{2 r}}} )\end{matrix} ] \qquad ( 6 )$$

A_{f}, B_{f}, R_{1f} and R_{2f} are the raw measured data in forward direction when the switch is directing the signal generator to R1 reference channel path. Also, Aᵣ, Bᵣ, R₁ᵣ and R₂ᵣ are the raw measured data in reverse direction when the switch is directing the signal generator to R2 reference channel path.
Tx and Tₘ can be defined by their matrix elements as

$$Tx = [ \begin{matrix}{Tx}_{11} & {Tx}_{12} \\ {Tx}_{21} & {Tx}_{22}\end{matrix} ] and {T}_{m} = [ \begin{matrix}{m}_{11} & {m}_{12} \\ {m}_{21} & {m}_{22}\end{matrix} ] .$$

Tₘ is modified by Equation (6). From Equations (3) and (5) and eliminating

$$\frac{{S}_{l 1}}{{S}_{ɛ}}$$

the following equation can be written:

$$\begin{matrix}\frac{{Tx}_{21}}{{Tx}_{11}} = \frac{( - {m}_{11} + \sqrt{4 {m}_{12} {m}_{21} + {( {m}_{11} - {m}_{22} )}^{2}} + {m}_{22} )}{2 {m}_{12}} and & ( 7 ) \\ \frac{{Tx}_{22}}{{Tx}_{12}} = \frac{( - {m}_{11} + \sqrt{4 {m}_{12} {m}_{21} + {( {m}_{11} - {m}_{22} )}^{2}} + {m}_{22} )}{2 {m}_{12}} & ( 8 )\end{matrix}$$

### From Equation (4),

$$\frac{{Tx}_{21}}{{Tx}_{11}} and \frac{{Tx}_{22}}{{Tx}_{12}}$$

in terms of corresponding S-parameter error adapter are also given by:

$$\begin{matrix}\frac{{Tx}_{21}}{{Tx}_{11}} = {Sx}_{11} = B and & ( 9 ) \\ \frac{{Tx}_{22}}{{Tx}_{12}} = {Sx}_{11} - \frac{{Sx}_{12} {Sx}_{21}}{{Sx}_{22}} = A & ( 10 )\end{matrix}$$

Equations (7) and (8) are equal and because of the square root have two solutions. The smaller value or the first solution, defined by B, corresponds to the directivity error coefficient of the VNA reflectometer. The larger value or the second solution, defined by A, corresponds to the

$${Sx}_{11} - \frac{{Sx}_{12} {Sx}_{21}}{{Sx}_{22}}$$

error coefficient.

Error adapter Sy can be described by a similar procedure as described by error adapter Sx. From Equations (1) and (2) and definition of Tₐ=Tₐₜ⁻¹Tₐₗ, Tₘ=Tₘₜ⁻¹Tₘₗ the following equation can be written:

TₐTy=TyTₘ (12)

With reference to Sy error adapter of FIG. 14, the general equation for T-parameters in terms of corresponding S-parameters where port 1 is on the right and port 2 is on the left is given by:

$$[ \begin{matrix}{Ty}_{11} & {Ty}_{12} \\ {Ty}_{21} & {Ty}_{22}\end{matrix} ] = [ \begin{matrix}\frac{1}{{Sy}_{12}} & \frac{- {Sy}_{11}}{{Sy}_{12}} \\ \frac{{Sy}_{22}}{{Sy}_{12}} & \frac{{Sy}_{12} {Sy}_{21} - {Sy}_{11} {Sy}_{22}}{{Sy}_{12}}\end{matrix} ] \qquad ( 13 )$$

From Equations (5), (12) and eliminating

$$\frac{{S}_{l 1}}{{S}_{ɛ}} ,$$

the following equations can be written:

$$\begin{matrix}\frac{{Ty}_{12}}{{Ty}_{11}} = \frac{( - {m}_{11} + \sqrt{4 {m}_{12} {m}_{21} + {( {m}_{11} - {m}_{22} )}^{2}} + {m}_{22} )}{2 {m}_{21}} and & ( 14 ) \\ \frac{{Ty}_{22}}{{Ty}_{21}} = \frac{( - {m}_{11} + \sqrt{4 {m}_{12} {m}_{21} + {( {m}_{11} - {m}_{22} )}^{2}} + {m}_{22} )}{2 {m}_{21}} & ( 15 )\end{matrix}$$

### From Equation (13),

$$\frac{{Ty}_{12}}{{Ty}_{11}} and \frac{{Ty}_{22}}{{Ty}_{21}}$$

in terms of corresponding S-parameter error adapter are also given by:

$$\begin{matrix}\frac{{Ty}_{12}}{{Ty}_{11}} = {Sy}_{11} = D and & ( 16 ) \\ \frac{{Ty}_{22}}{{Ty}_{12}} = \frac{{Sy}_{12} {Sy}_{21}}{{Sy}_{22}} - {Sy}_{11} = C & ( 17 )\end{matrix}$$

Equations (14) and (15) are equal and because of the square root have two solutions. The smaller value or the first solution, defined by D, corresponds to the directivity error coefficient of the VNA reflectometer. The larger value or the second solution, defined by C, corresponds to the

$$\frac{{Sy}_{12} {Sy}_{21}}{{Sy}_{22}} - {Sy}_{11}$$

error coefficient.

During calibration procedure, as shown in FIGS. 2 and 3, an unknown high reflection standard is connected to the first port of VNA and then the same unknown high reflection is disconnected from port 1 and connected to port 2 of the VNA. Referring again to FIG. 14, by connecting the high reflection standard to port 1, the following equation can be written:

$${Γ}_{mrx} = {Sx}_{11} + \frac{{Sx}_{12} {Sx}_{21} {Γ}_{ar}}{1 - {Sx}_{22} {Γ}_{ar}} \qquad ( 18 )$$

Γₘᵣₓ is the measured high reflection standard at port 1 DRP and Γₐᵣ is the actual high reflection standard value. Also, by connecting the same high reflection standard to port 2, the following equation can be written:

$${Γ}_{mry} = {Sy}_{11} + \frac{{Sy}_{12} {Sy}_{21} {Γ}_{ar}}{1 - {Sy}_{22} {Γ}_{ar}} \qquad ( 19 )$$

Γ_{mry} is the measured high reflection standard at port 2 DRP. From Equations (8), (9), (16), (17), (18) and (19), the following can be written:

$${Sx}_{22} = \frac{( B - {Γ}_{mrx} ) ( C - {Γ}_{mry} ) {Sy}_{22}}{( A - {Γ}_{mrx} ) ( D - {Γ}_{mry} )} \qquad ( 20 )$$

Referring to FIGS. 6 & 14, during the through calibration, the following equation can be written:

$${Γ}_{mt 11} = {Sx}_{11} + \frac{{Sx}_{12} {Sx}_{21} {Sy}_{22}}{1 - {Sx}_{22} {Sy}_{22}} \qquad ( 21 )$$

In Equation (21), Γₘₜ₁₁ is the measured through reflection coefficient during the calibration procedure. From Equations (9), (10), (21) and (20), the following can be written:

$${Sx}_{22} = \sqrt{\frac{( B - {Γ}_{mrx} ) ( C - {Γ}_{mry} ) ( B - {Γ}_{mt 11} )}{( A - {Γ}_{mrx} ) ( D - {Γ}_{mry} ) ( A - {Γ}_{mt 11} )}} \qquad ( 22 )$$

Sx₂₂ is the source match error coefficient at the port 1 of VNA. Due to square root of equation (22), there are at least two solutions. By having an approximate value of the argument of the standard the correct choice can be made. For example a short standard should have an argument of 180 degrees and an open standard should have an argument of zero degree. If a non-zero through standard is used, then the phase rotation of the reflection standard can be calculated from the length of the non-zero through and subsequently, a correct choice of Equation (22) is made. Accordingly, the type of high reflection standard, namely, whether short or open, and the electrical length of non-zero through must be known. From Equation (20) Sy₂₂ is calculated. Sy₂₂ is the source match error coefficient at the port 2. From Equations (9), (10) and (22) the reflection tracking for port 1 is given by:

Sx₁₂Sx₂₁=(B−A)Sx₂₂ (23)

From Equations (16), (17) and (20) the reflection tracking for port 2 is given by:

Sy₁₂Sy₂₁=(D−C)Sy₂₂ (24)

Referring to FIG. 12, from A/R1 and B/R1 measurements the load match presented by port 2 and the transmission tracking from port 1 to port 2 can be determined. In this case the measured parameters by the VNA do not have to be modified by Equation (6). The load match, Γ_{L2}, and forward transmission tracking, τ₂₁, are given by:

$$\begin{matrix}{Γ}_{L 2} = \frac{{Sx}_{11} - ( A / R 1 )}{{Sx}_{11} {Sx}_{22} - {Sx}_{12} {Sx}_{21} - {Sx}_{22} ( A / R 1 )} & ( 25 ) \\ {τ}_{21} = ( B / R 1 ) ( 1 - {Sx}_{22} {Γ}_{L 2} ) & ( 26 )\end{matrix}$$

Referring to FIG. 13, from A/R2 and B/R2 measurements the load match presented by port 1 and the transmission tracking from port 2 to port 1 can be determined. In this case the measured parameters by the VNA do not have to be modified by Equation (6). The load match, Γ_{L1}, and reverse transmission tracking, τ₁₂, are given by

$$\begin{matrix}{Γ}_{L 1} = \frac{{Sy}_{11} - ( B / R 2 )}{{Sy}_{11} {Sy}_{22} - {Sy}_{12} {Sy}_{21} - {Sy}_{22} ( B / R 2 )} & ( 27 ) \\ {τ}_{12} = ( A / R 2 ) ( 1 - {Sy}_{22} {Γ}_{L 1} ) & ( 28 )\end{matrix}$$

At this point, all systematic error coefficients are calculated by using unknown high reflection, matched load and thru standard. Once the systematic error coefficients are known they can be removed from the DUT measurement by the procedure described in L. W Rabiner, R. Schafer, “The Chirp z-Transform Algorithm”, IEEE Transaction on Audio and Electroacoustics, Vol. AU-17, No. 2, June 1969, which is herein incorporated by reference in its entirety. The accuracy of DUT measurement depends on how well the systematic error coefficients are removed from the overall measurement. This calibration procedure provides similar type of accuracy as a TRL method without the burden of multiline delay standards. The accuracy of this procedure comes from the time gating of the measured termination impulse response by the location of measured unknown high reflection standards.

Present VNA calibration procedures, such as disclosed in, by way example only and not limited to these patents, U.S. Pat. Nos. 7,157,918; 7,068,049; 7,030,625; 7,019,535; 6,853,198; 6,826,506; 6,744,262; and 6,653,848, by common inventor Vahe Adamian and which are herein incorporated by reference, deploy high reflection and termination standards. It is to be understood that every one of these procedures, calibration standards, and systems can benefit from embodiments and aspects of the present invention. For example, for mechanical calibration procedures where the mechanical termination standard alone determines the directivity error, in one embodiment, the time domain termination standard is gated/windowed by the location of high reflection standard, as discussed above, and the directivity error is deduced. This results in an increased accuracy of the directivity error. In another example, in electronic calibration procedures where there is no high quality termination standard used (all states are characterized), the directivity error, along with source match and reflection tracking, are determined from a measurement of a minimum of three electronic standards. After determining the directivity error using an electronic calibration of three electronic standards, the accuracy of this determined directivity error is improved by time gating the calculated directivity error by the location of high reflect standard, as discussed above. Thus, it is to be appreciated that the load-gating procedure of various embodiments discussed above may be used to improve the accuracy of the determined directivity error in both electronic and mechanical calibration procedures. Using Agilent technologies 85050C 7 mm precision calibration kit, 85051B 7 mm verification kit and 10 MHz to 20 GHz VNA; various measurement comparisons may be made by employing different calibration procedures, as discussed below.

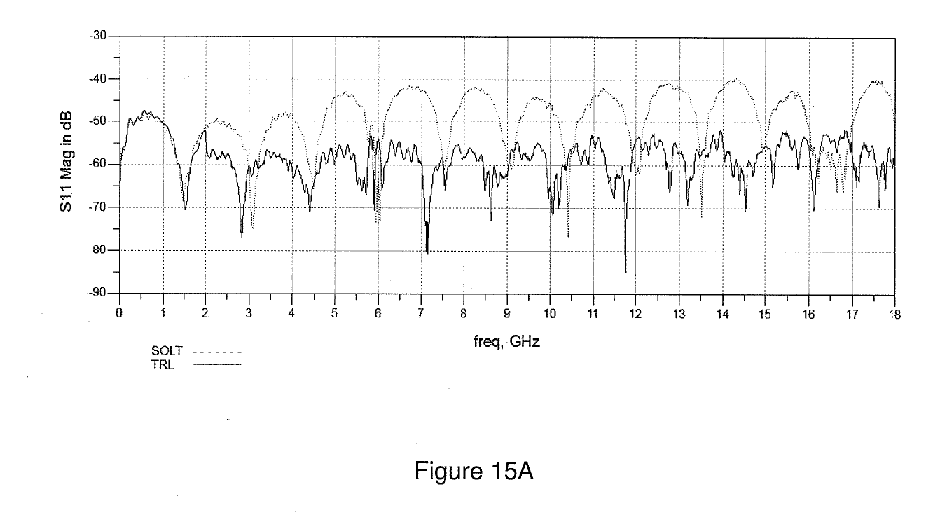

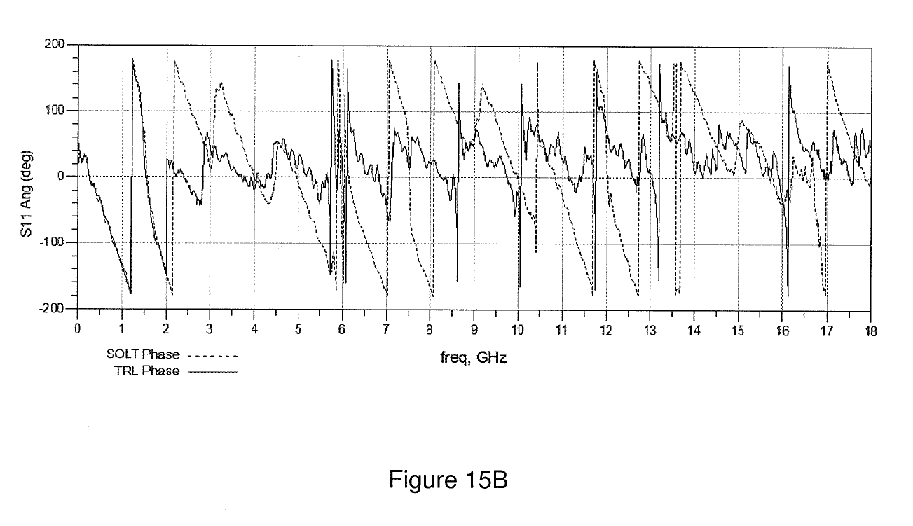

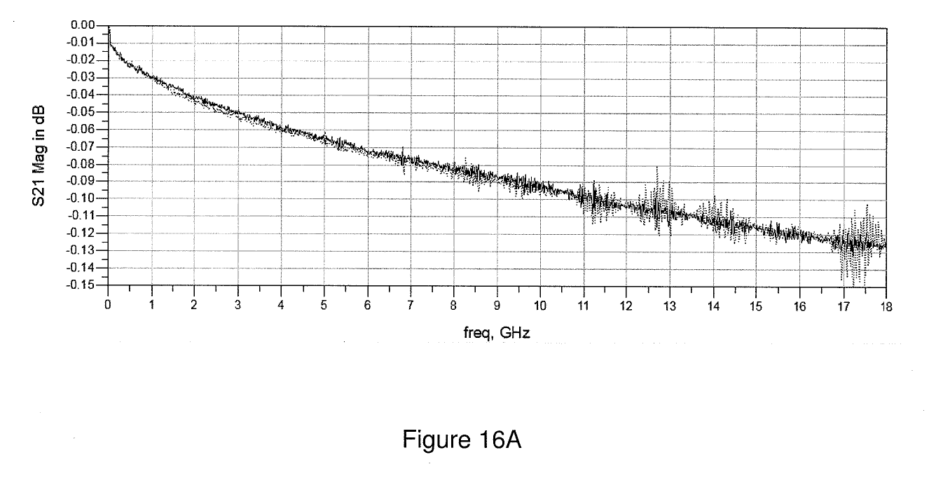

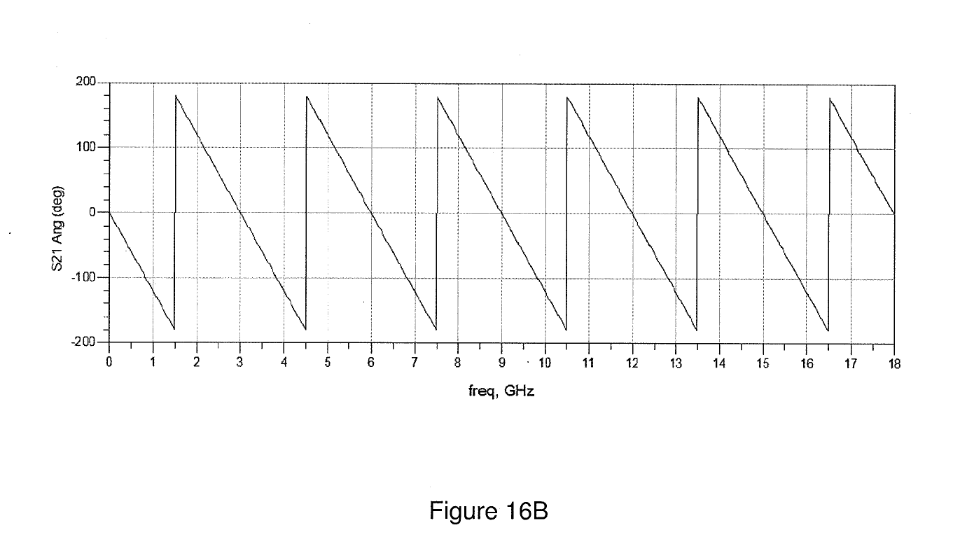

Referring to FIGS. 15A through 16B, the VNA is calibrated with a SOLT procedure using the above-identified calibration kit. The 50-ohm bead-less precision airline from the verification kit was measured. The same VNA was calibrated using the TRL procedure and again the same 50-ohm bead-less precision airline was measured. The SOLT method (dotted line) displays its reflection and transmission limitations when compared with the TRL procedure. No calibration improvement (e.g., time domain modification of calibration artifacts) of embodiments of the present invention was applied to the SOLT calibration. As mentioned above, SOLT is the most common calibration procedure in the industry. TRL is the most accurate calibration procedure, but it is time consuming and cumbersome.

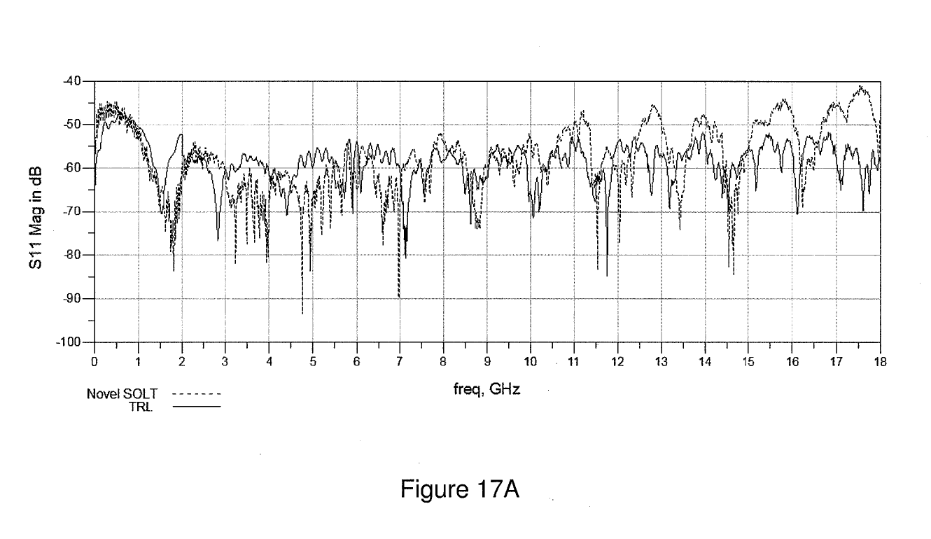

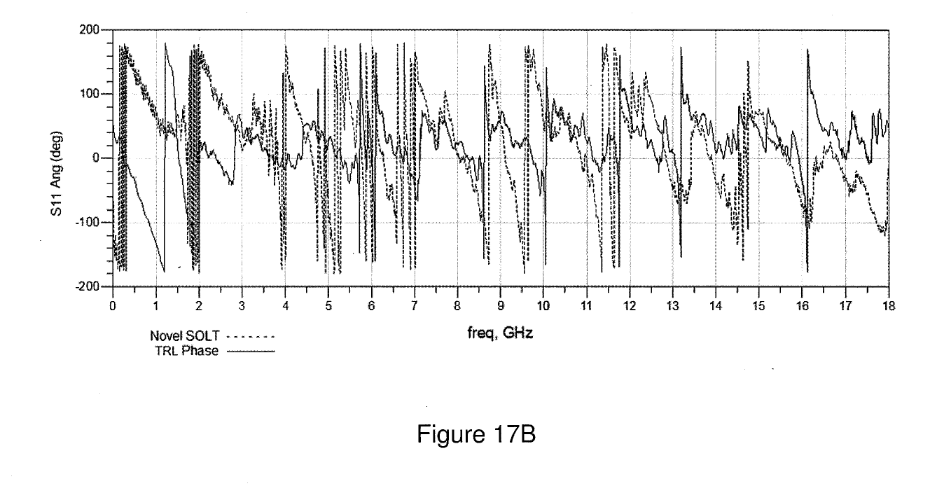

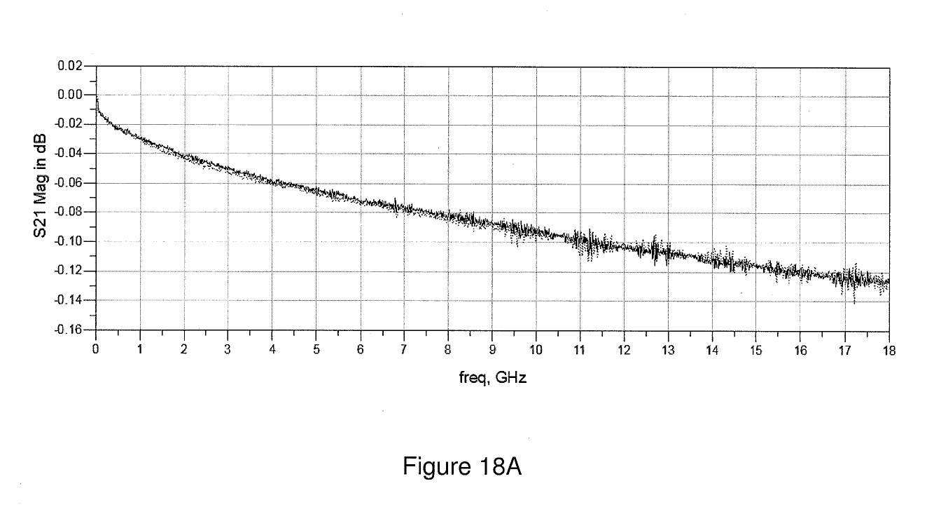

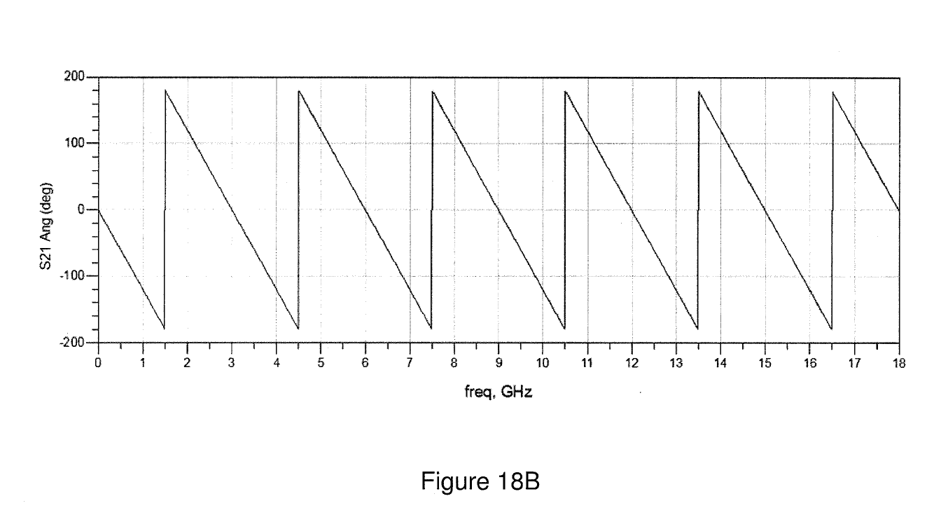

Referring to FIGS. 17A through 18B, the SOLT calibration procedure was enhanced by the applying the principles of embodiments of the present invention, as discussed above, and then compared with a TRL procedure. Considerable improvement is observed on reflection parameters but there is hardly any improvement on transmission parameters. Although, the enhanced algorithms for SOLT are not shown, the procedure is very similar to embodiments of the present invention. In one embodiment, the measured short time domain response determines the location of uncorrected response at DRP and the time domain gated load response, determined from the location of short standard, simulate a perfect termination when reconverted back to frequency domain.

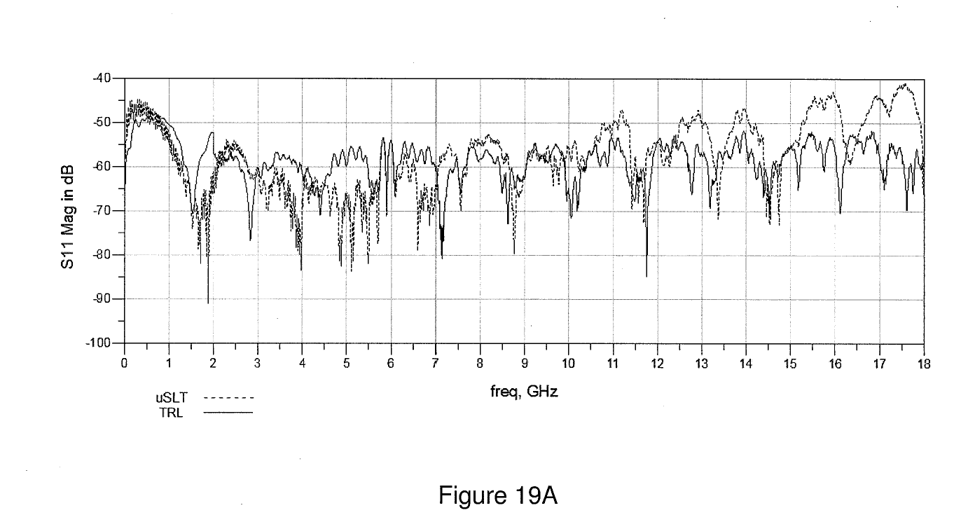

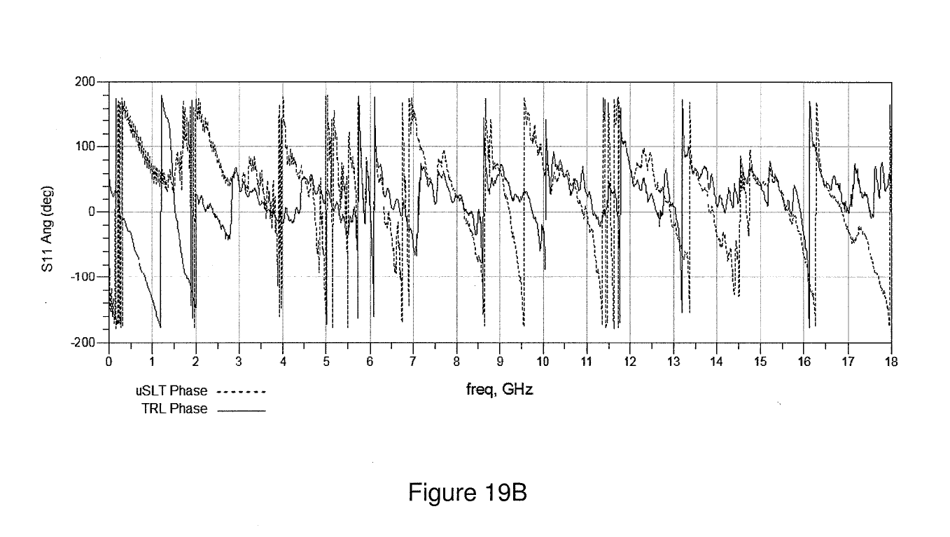

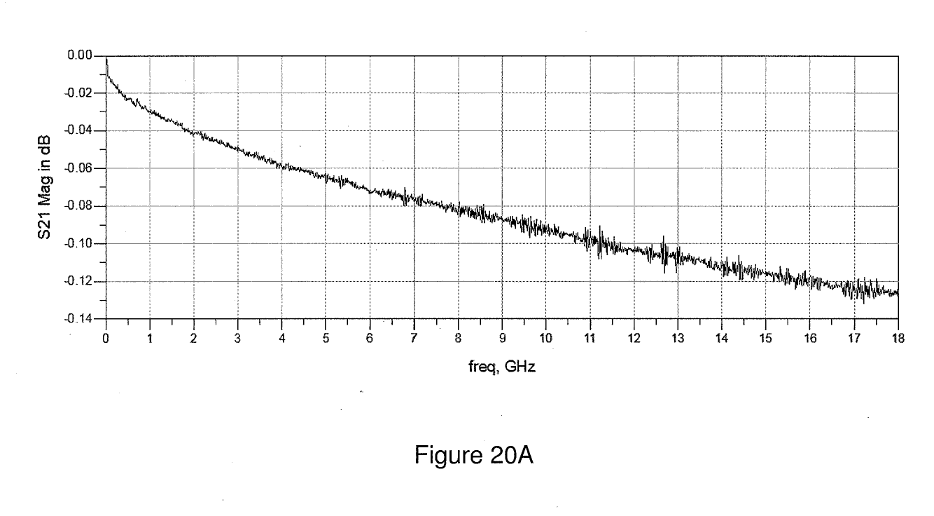

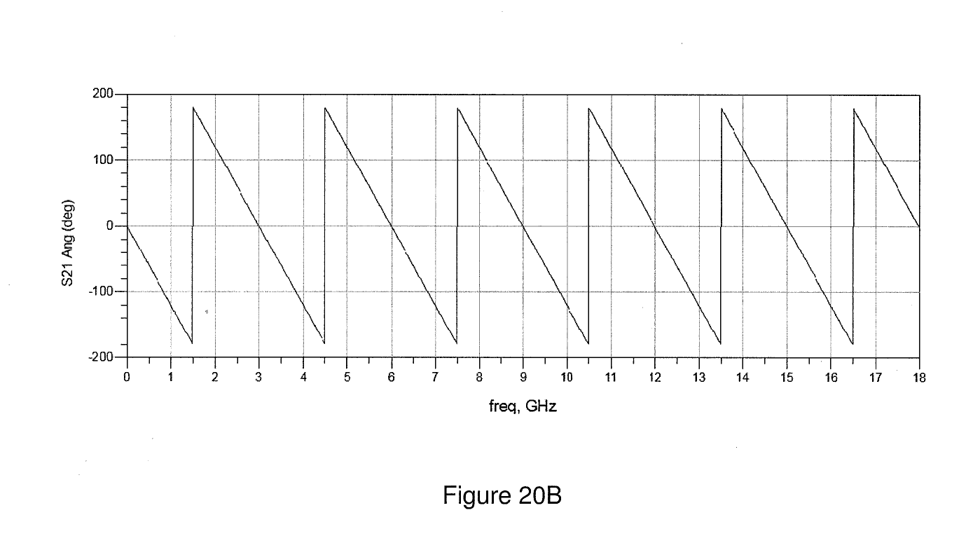

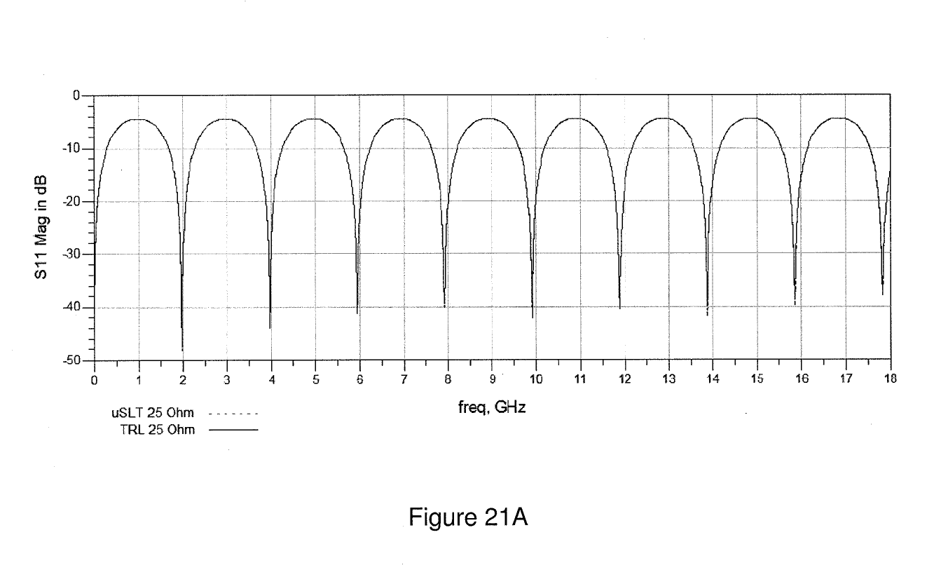

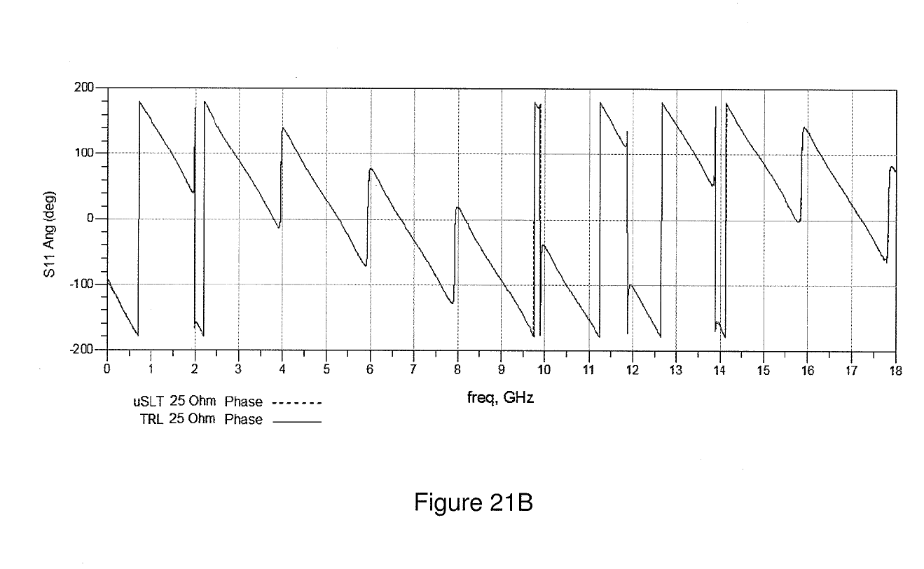

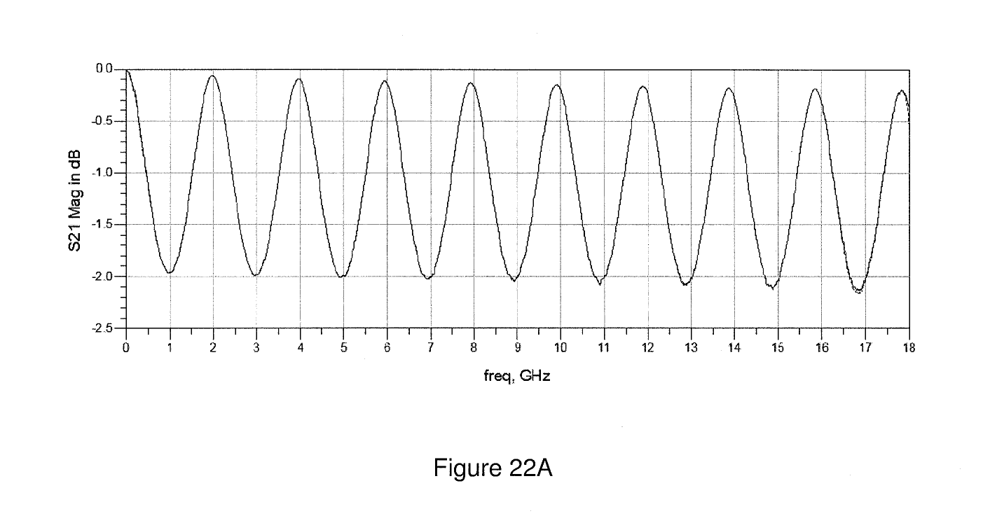

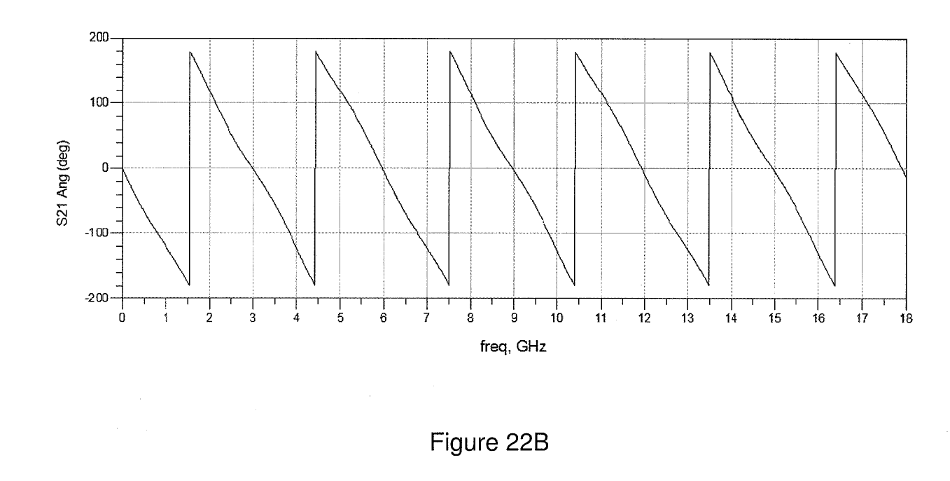

Referring to FIGS. 19A through 22B, an embodiment of the present invention calibration procedure of unknown short, load and thru (uSLT) correlates the best with TRL procedure. FIGS. 19A through 20B illustrate comparisons of the S-parameters of a 50-ohm bead-less precision airline from the verification kit, and FIGS. 21A through 22B illustrate comparisons of the S-parameters of a 25-ohm mismatched bead-less precision airline from the verification kit.

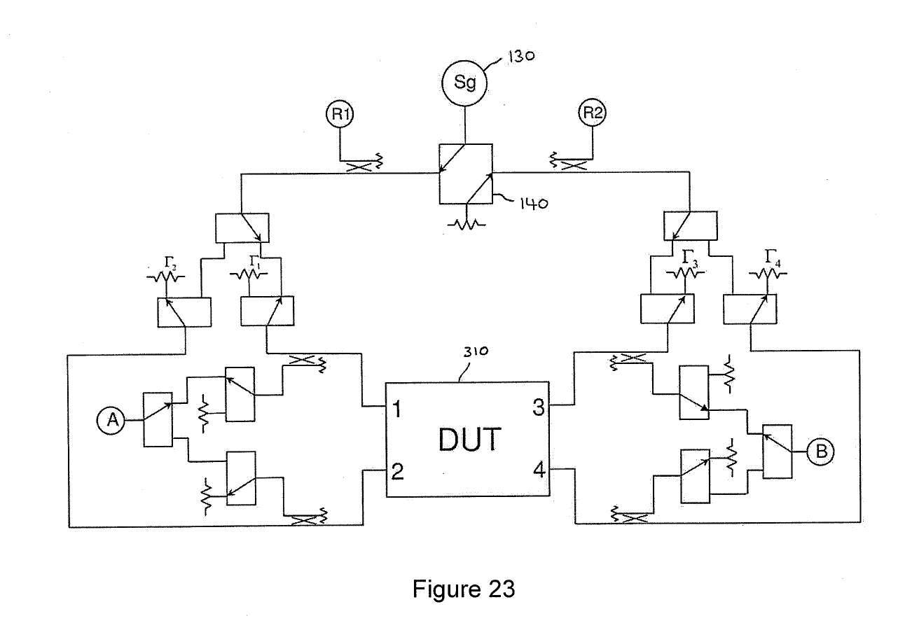

With reference to FIG. 23, there is shown a simple block diagram of a four-port VNA for use with certain embodiments of the present invention. The DUT 310 is connected to the VNA at the port 1, port 2, port 3 and port 4 device reference planes, as shown.

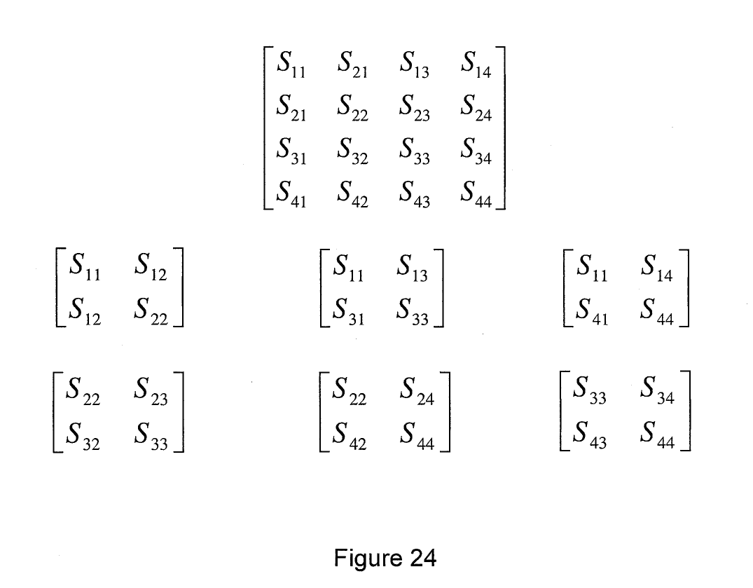

For an N-port DUT, a minimum of N-by-N measurements have to be made. Also, the N-port DUT will have a total of N(N−1)/2 two-port S-parameters. Each measured two-port S-parameter, has four corresponding elements which are the subset of the N-by-N multiport S-parameter. In other words, the N-by-N multiport S-parameter can be broken down into N(N−1)/2 subset two-port S-parameters. For example, a four-port DUT has 16 elements, but it can be broken down into six two-port subsets, totaling 24 elements. Referring to FIG. 24, the break down subset has more elements than the multiport S-parameter due to the redundant count of the reflection element. In the four-port example, S₁₁, S₂₂, S₃₃ and S₄₄ are counted two additional times. Therefore, during N(N−1)/2 two-port measurements of a multiport device, the redundant reflections do not have to be measured several times. Again referring to FIG. 24, there are six two-port paths that need to be calibrated. Based on the above-discussed time domain modeling of a perfect termination at DRP location determined by the high reflection unknown standard, very accurate (similar to TRL accuracy) systematic error coefficients for each of six two-port paths are calculated. Accordingly, having more accurate systematic error coefficients corresponds to more accurate 4-by-4 DUT measurement. The four-port (N=4) example is merely exemplary; N can be any number. Of course, as N increases so does the test-set hardware complexity.

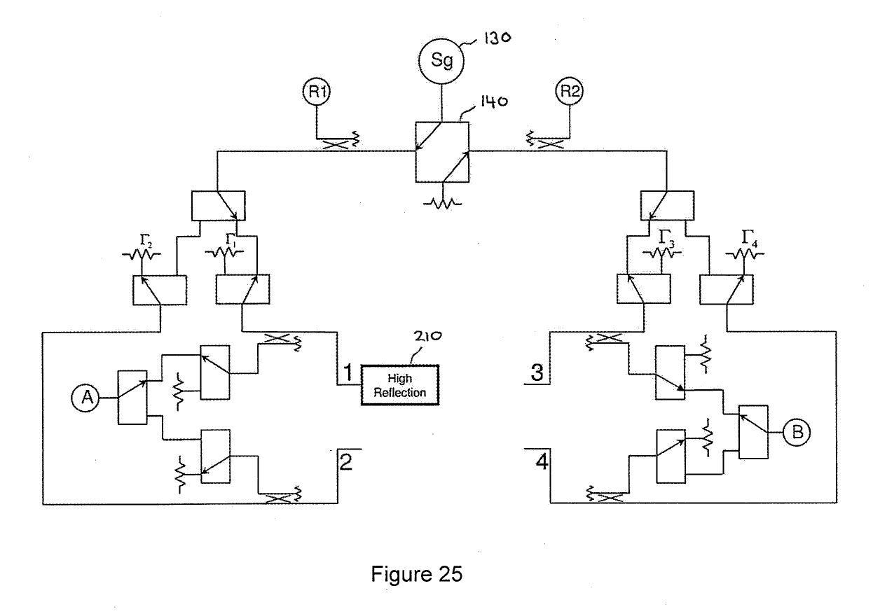

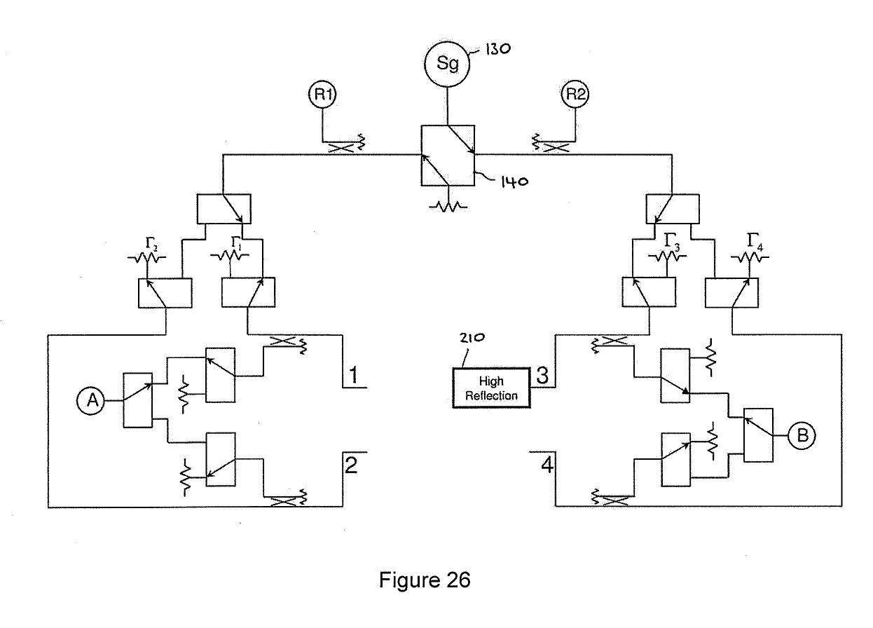

A calibration procedure for a four-port VNA employing embodiments of the present invention is described now. Referring to FIG. 25, an unknown high reflection standard 210 is connected to port 1 and then the test-set switches are set in the position shown by the diagram. The signal generator 130 is directed to R1 reference channel path and then swept through a desired frequency range by taking the measurement of A/R1 of unknown high reflection standard 210. Referring to FIG. 26, the same unknown high reflection standard 210 is disconnected from port 1 and then connected to the port 3 device reference plane, as illustrated. The signal generator 130 is now directed to R2 reference channel path shown by switch settings in the diagram and a measurement of B/R2 is taken by sweeping through the same desired frequency range. In a non-coaxial configuration two different high reflections are connected to port 1 and port 3 are assumed to be substantially the same.

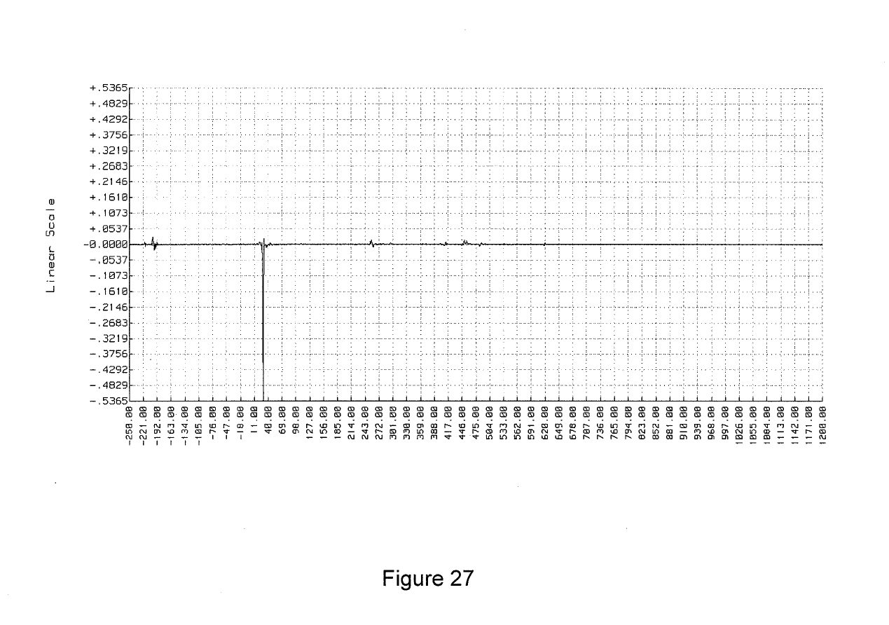

Referring to FIG. 27, the measured high reflection A/R1 data is converted from frequency domain into time-domain impulse response. In this example, the frequency domain was swept from 10 MHz to 18000 MHz. The high reflection is a short circuit with a negative magnitude of approximately 0.54 ratio, located approximately 29.68 centimeters (cm); a distance in air. The time domain was swept in distance from −250 cm to 1200 cm. A broad time sweep insures capturing all frequency domain responses without causing aliasing. This procedure can be verified by reconverting back the time domain into frequency domain and correlating the result with the original measured data. The location of short circuit at port 1 DRP is 29.68 cm. This distance has been influenced by the port1 VNA's systematic error coefficients.

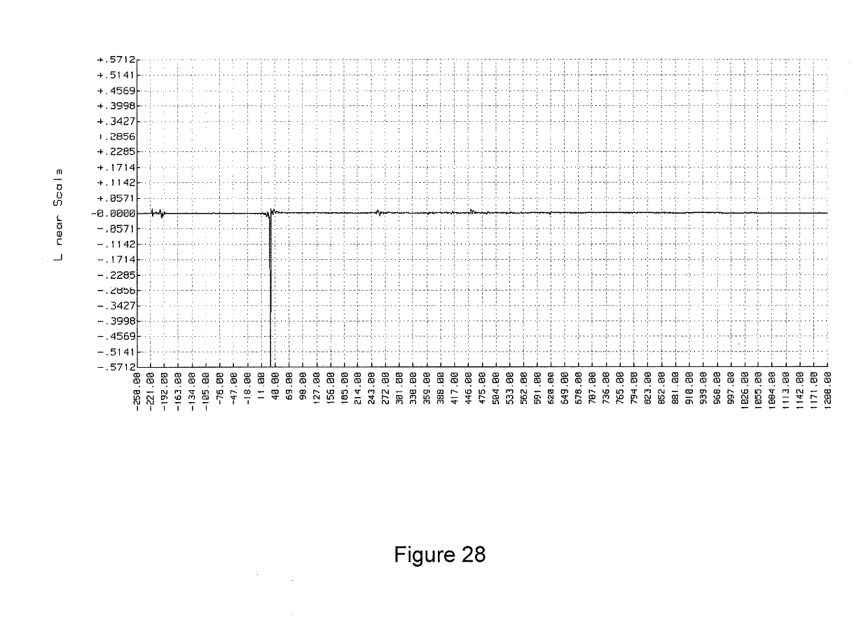

Referring to FIG. 28, the measured high reflection B/R2 data is converted from frequency domain into time-domain impulse response. Again the frequency domain was swept from 10 MHz to 18000 MHz and time domain observed from −250 cm to 1200 cm. The high reflection is a short circuit with a negative magnitude of approximately 0.57 ratio, located approximately 30.49 cm. The location of short circuit at port 3 DRP is approximately 30.49 cm. This distance has been influenced by the port 3 VNA's systematic error coefficients.

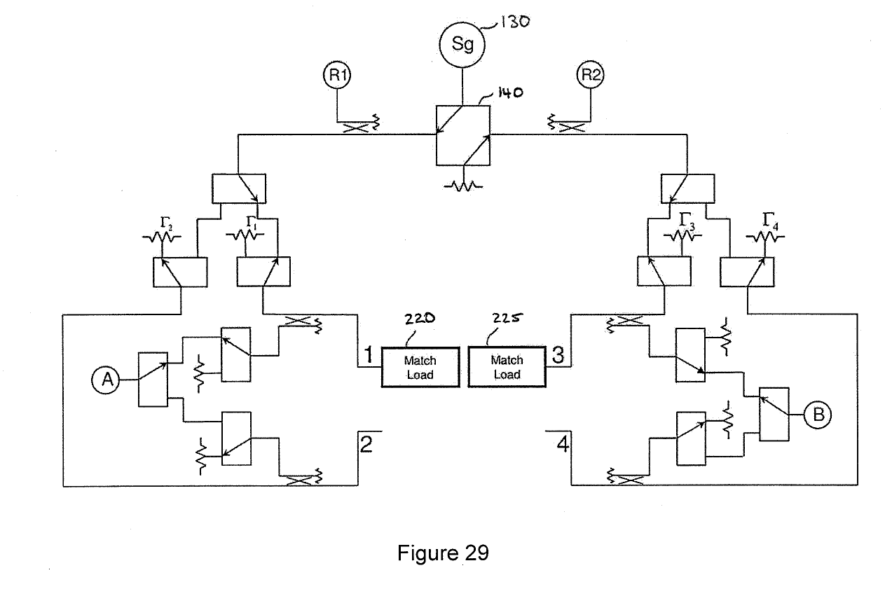

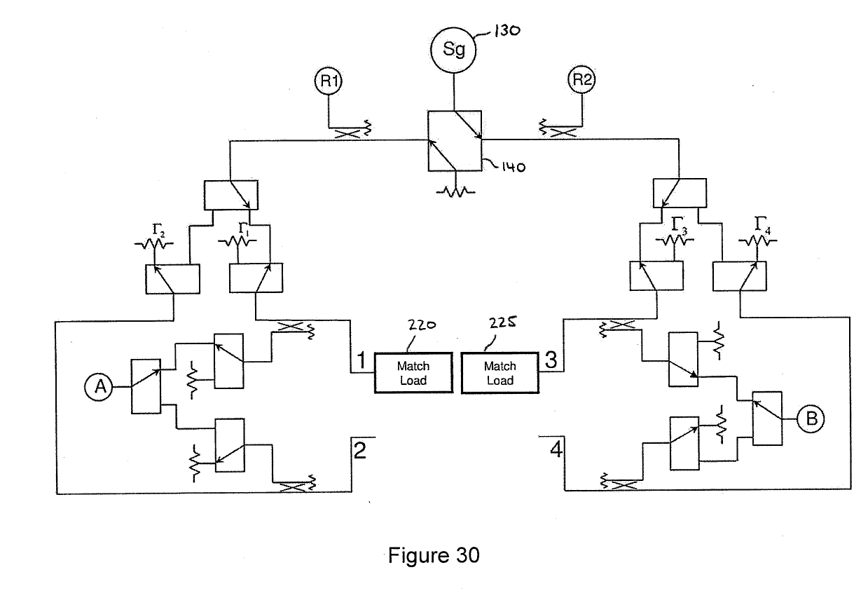

Referring to FIG. 29, a high quality termination standard 220 is connected to VNA's port 1 DRP and another high quality termination 225 is connected to VNA's port 3 DRP while the signal generator 130 is directed to R1 reference channel path by the switches configured as shown in the diagram. By sweeping the signal generator 130 through the same desired frequency range as before, R1, A, B and R2 receiver channels are measured. With reference to FIG. 30, without removing the high quality terminations 220, 225, the signal generator 130 is directed to R2 reference channel path by the switches configured as shown in the diagram, and then R2, B, A and R1 receiver channels are measured.

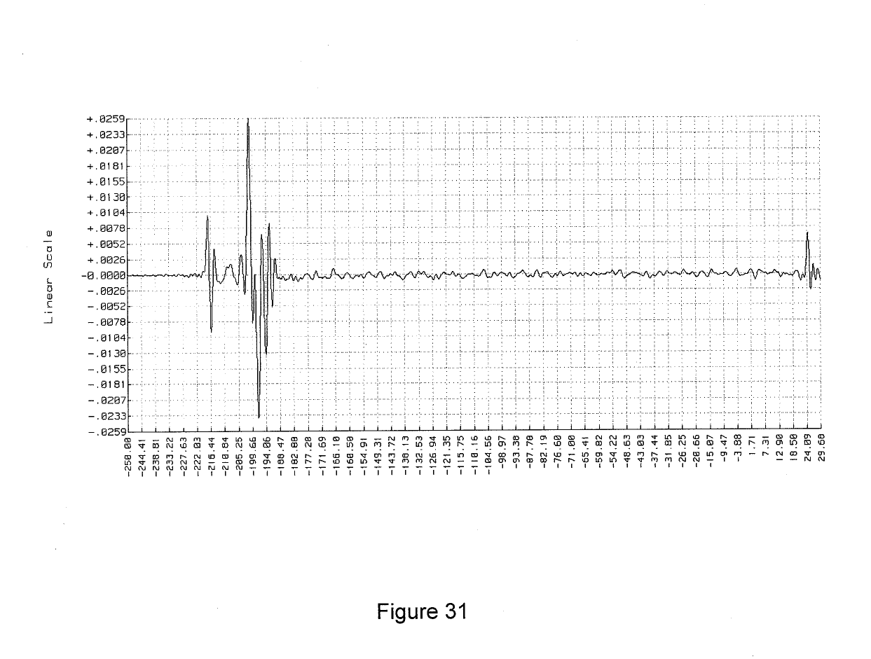

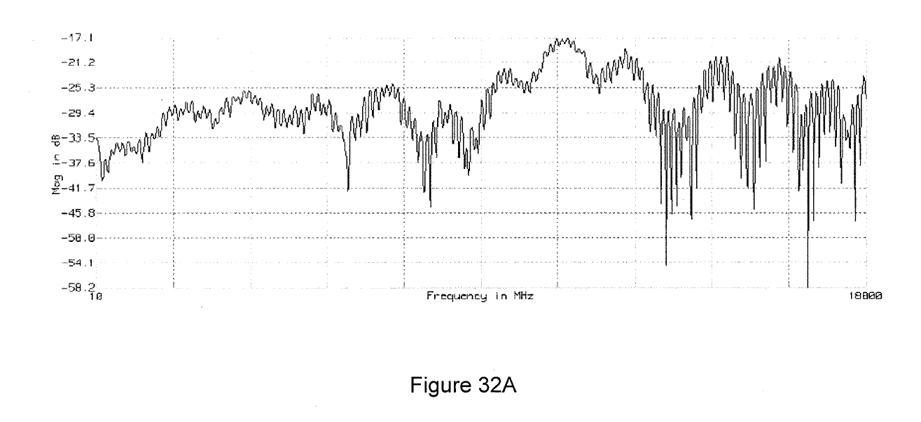

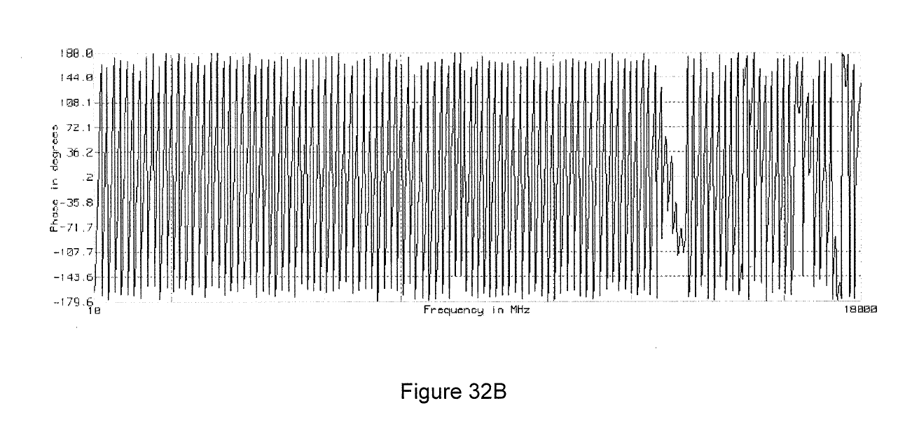

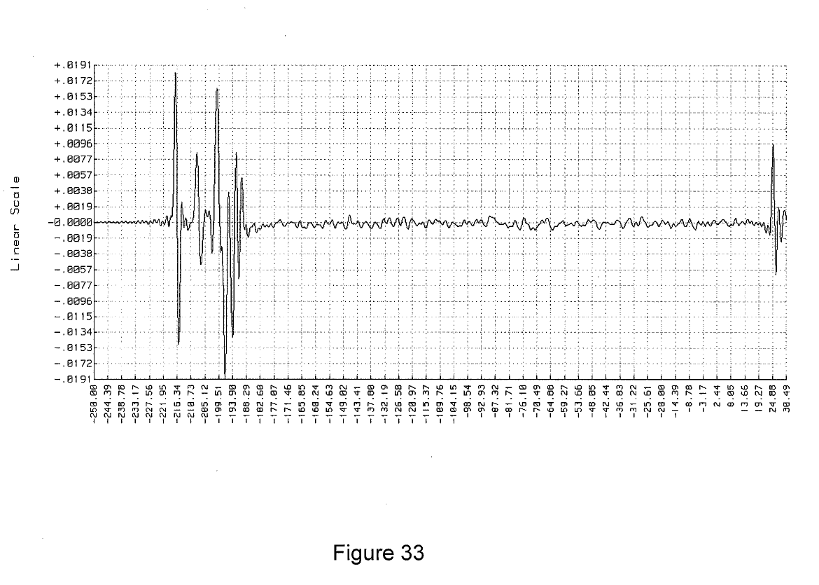

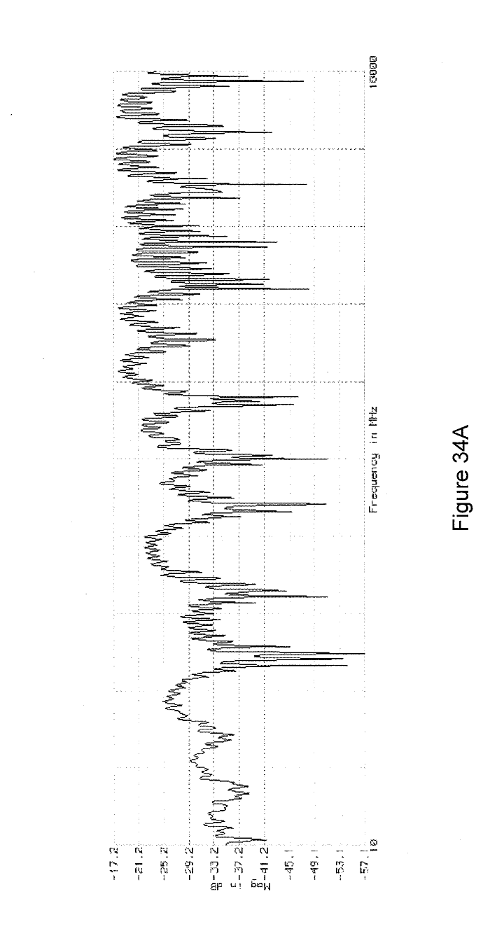

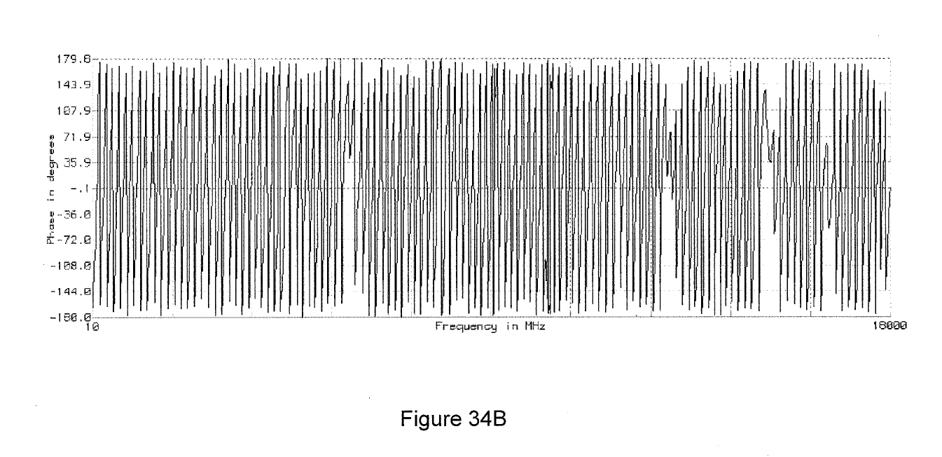

Referring to FIG. 31, the ratio of A/R1 is converted to time domain impulse response and gated between the port1 time start sweep and the port 1 DRP location of the high reflection standard. Then, the gated impulse response is converted back to frequency domain. The reconstructed frequency domain response is equivalent of putting a perfect termination on the original A/R1 frequency domain VNA measurement. FIGS. 32A and 32B illustrate the A/R1 magnitude (32A) and phase (32B) response as if a perfect termination is connected at port1 DRP. Referring to FIG. 33, the ratio of B/R2 is converted to time domain impulse response and gated between the port 1 time start sweep and the port 3 DRP location of the high reflection standard. Then, the gated impulse response is converted back to frequency domain. The reconstructed frequency domain response is equivalent of putting a perfect termination on the original B/R2 frequency domain VNA measurement. FIGS. 34A and 34B illustrate the B/R2 magnitude (34A) and phase (34B) response as if a perfect termination is connected at the port 3 DRP.

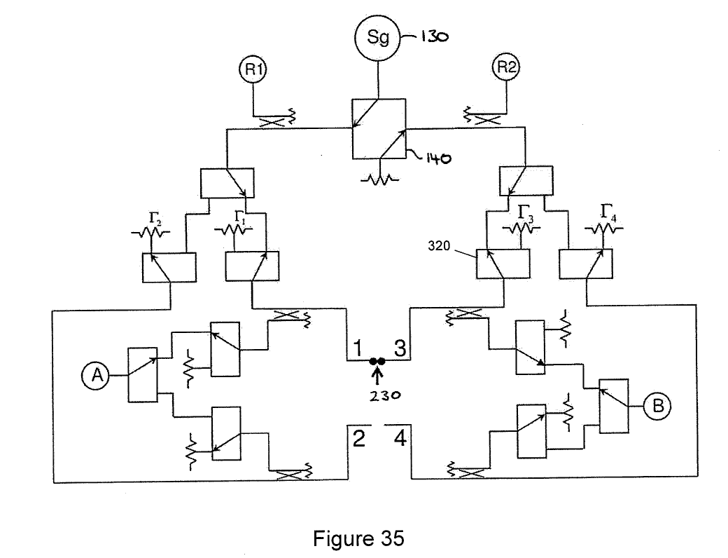

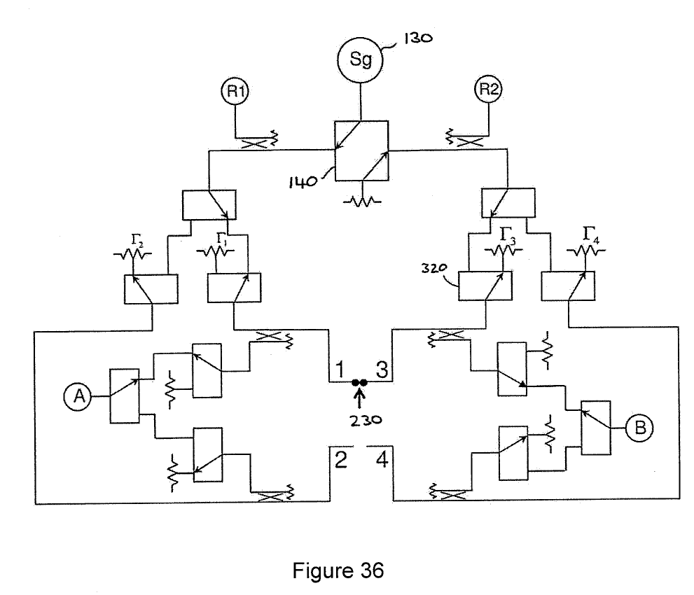

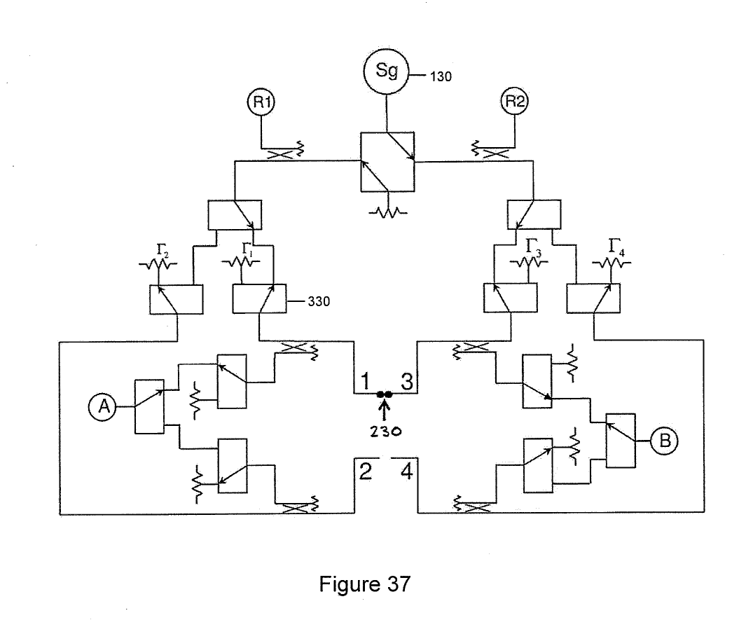

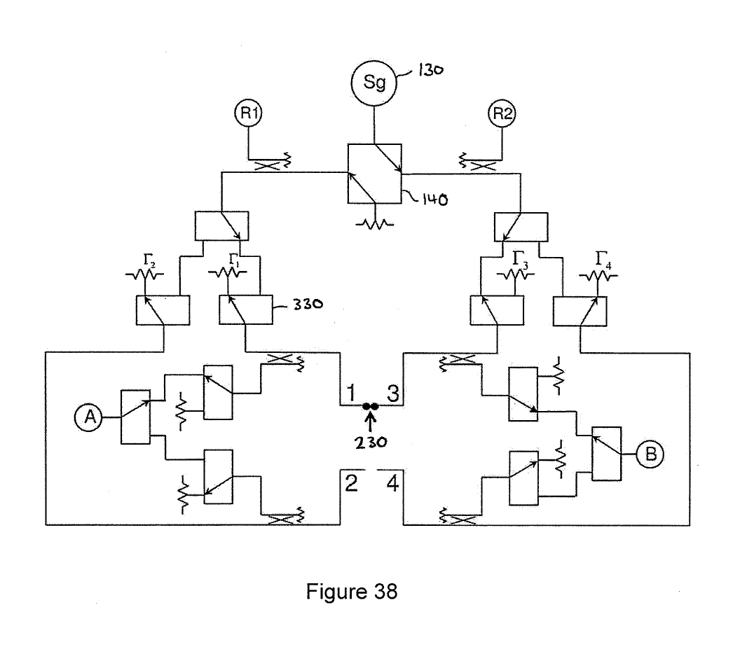

Referring to FIG. 35, the port 1 DRP is connected directly to the port 3 DRP as a thru standard connection 230. The signal generator 130 is directed to R1 reference channel path by the switch settings shown in the diagram. By sweeping the signal generator through the same desired frequency range as before, R1, A, B and R2 receiver channels are measured. With reference to FIG. 36, the switch 320 is forced to its other position (i.e., changes state relative to its position in FIG. 35) and A/R1 and B/R1 are measured. With reference to FIG. 37, the signal generator 130 is directed to R2 reference channel path by the switch settings shown in the diagram, and then R2, B, A and R1 receiver channels are measured. With reference to FIG. 38, the switch 330 is forced to its other position (i.e., changes state relative to its position shown in FIG. 37) and B/R2 and A/R2 are measured. Directivity, source match, reflection tracking, load match and transmission tracking for port 1 and port 3 can be determined by applying Equations (1) through (28).

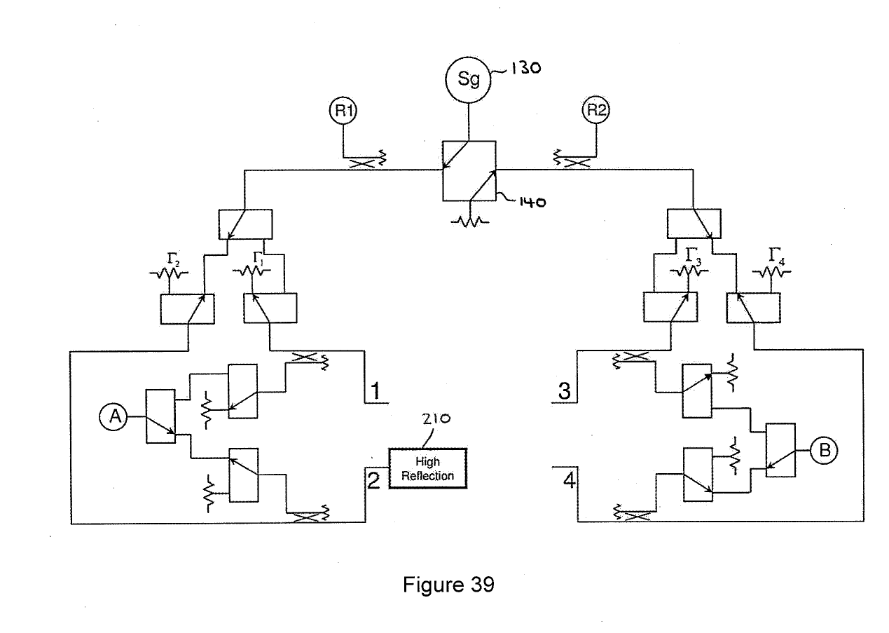

With reference to FIGS. 39-52, the above-discussed procedure may be repeated for port 2 and port 4, and directivity, source match, reflection tracking, load match and transmission tracking for port 2 and port 4 can be determined by applying Equations (1) through (28).

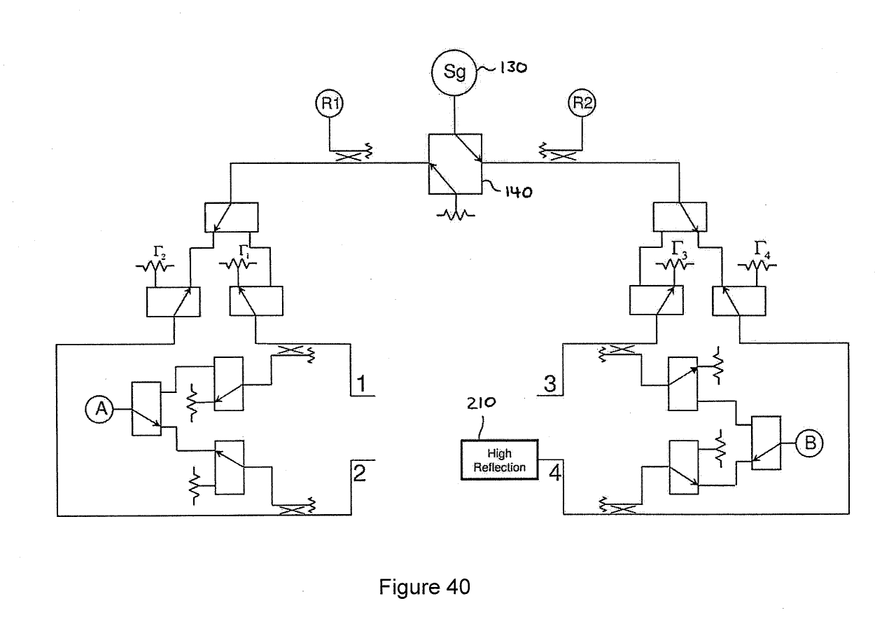

Referring to FIG. 39, the unknown high reflection standard 210 is connected to port 2 and then the test-set switches are set in the position shown by the diagram. The signal generator 130 is directed to R1 reference channel path and then swept through a desired frequency range by taking the measurement of A/R1 of unknown high reflection standard 210. Referring to FIG. 40, the same unknown high reflection standard 210 is disconnected from port 2 and then connected to the port 4 device reference plane, as illustrated. The signal generator 130 is now directed to R2 reference channel path shown by switch settings in the diagram and a measurement of B/R2 is taken by sweeping through the same desired frequency range. As discussed above, in a non-coaxial configuration two different high reflections are connected to port 2 and port 4 are assumed to be substantially the same.

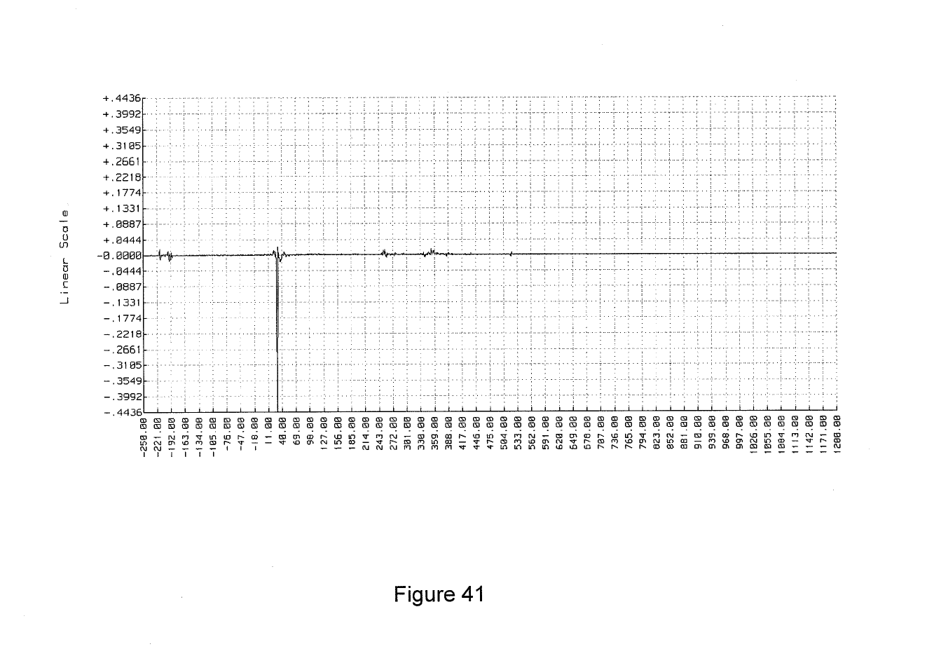

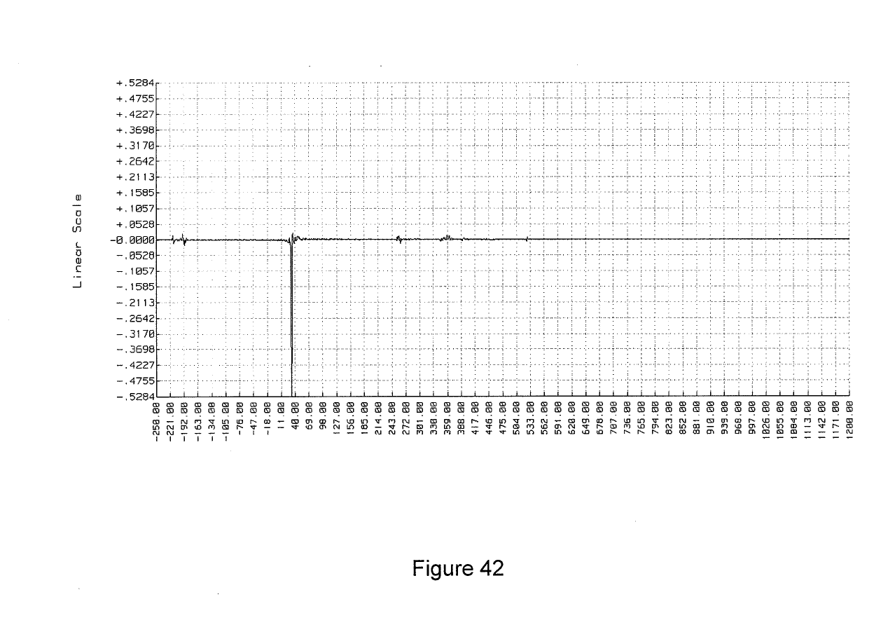

Referring to FIG. 41, the measured high reflection A/R1 data is converted from frequency domain into time-domain impulse response. In this example, the frequency domain was swept from 10 MHz to 18000 MHz. The time domain was swept in distance from −250 cm to 1200 cm. The location of the high reflection standard 210 at the port 2 DRP is 30.49 cm. This distance has been influenced by the port 2 VNA's systematic error coefficients. Referring to FIG. 42, the measured high reflection B/R2 data is converted from frequency domain into time-domain impulse response. Again the frequency domain was swept from 10 MHz to 18000 MHz and time domain observed from −250 cm to 1200 cm. The location of the high reflection standard 210 at the port 4 DRP is approximately 32.91 cm. This distance has been influenced by the port 4 VNA's systematic error coefficients.

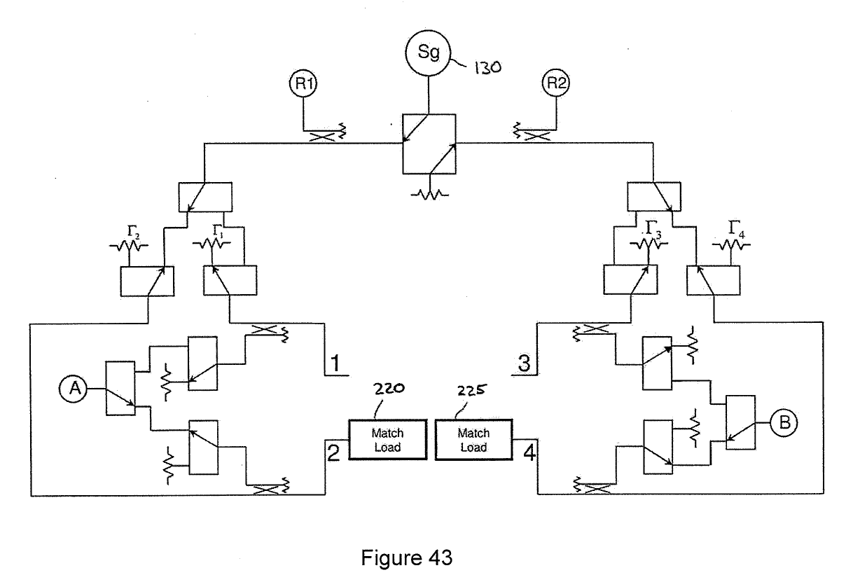

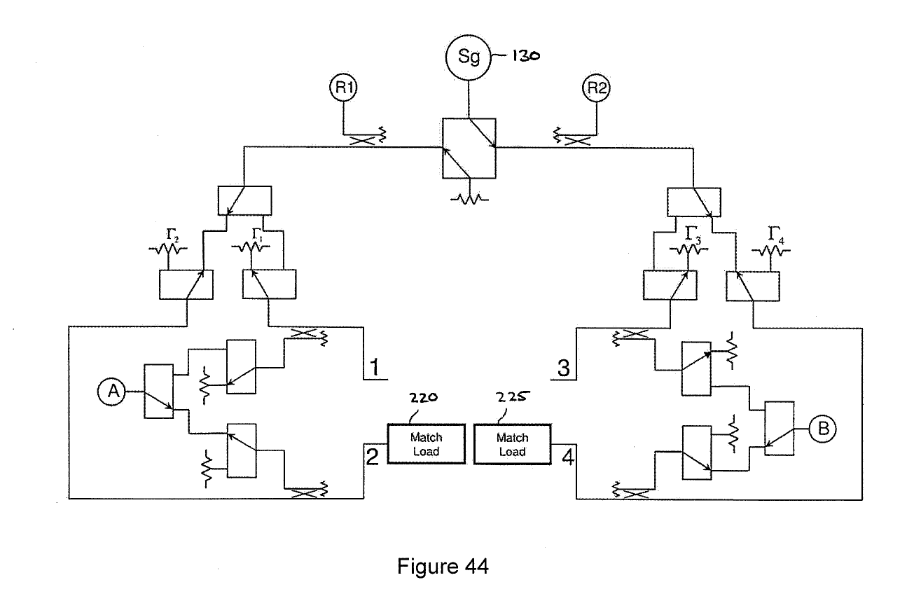

Referring to FIG. 43, the high quality termination standard 220 is connected to VNA's port 2 DRP and the other high quality termination 225 is connected to VNA's port 4 DRP, while the signal generator 130 is directed to R1 reference channel path by the switches configured as shown in the diagram. By sweeping the signal generator 130 through the same desired frequency range as before, R1, A, B and R2 receiver channels are measured. With reference to FIG. 44, without removing the high quality terminations 220, 225, the signal generator 130 is directed to R2 reference channel path by the switches configured as shown in the diagram, and then R2, B, A and R1 receiver channels are measured.

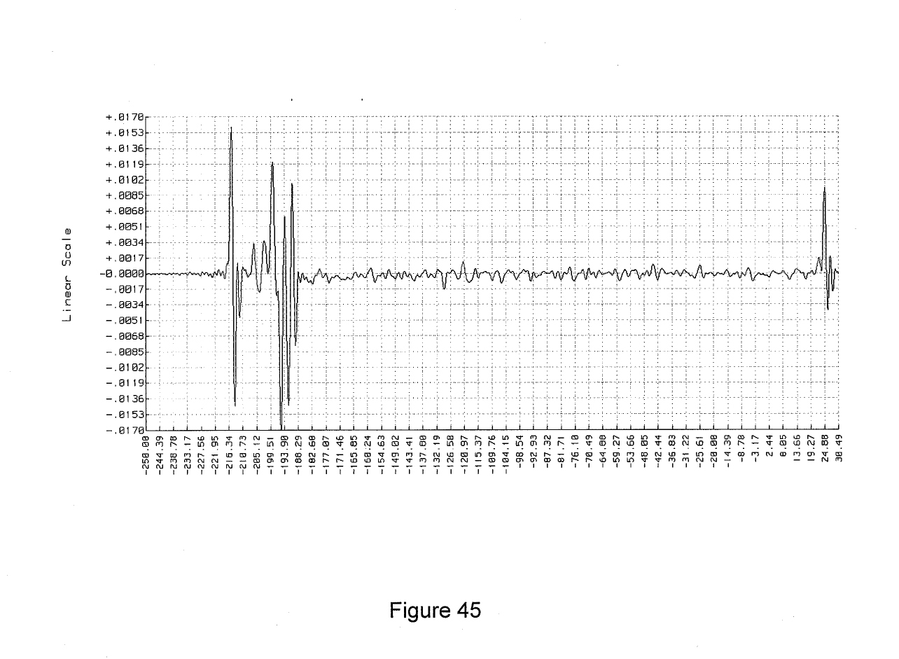

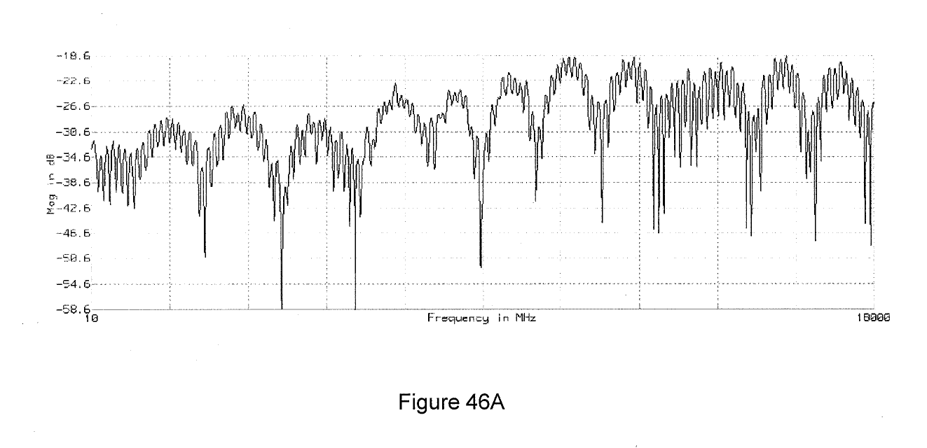

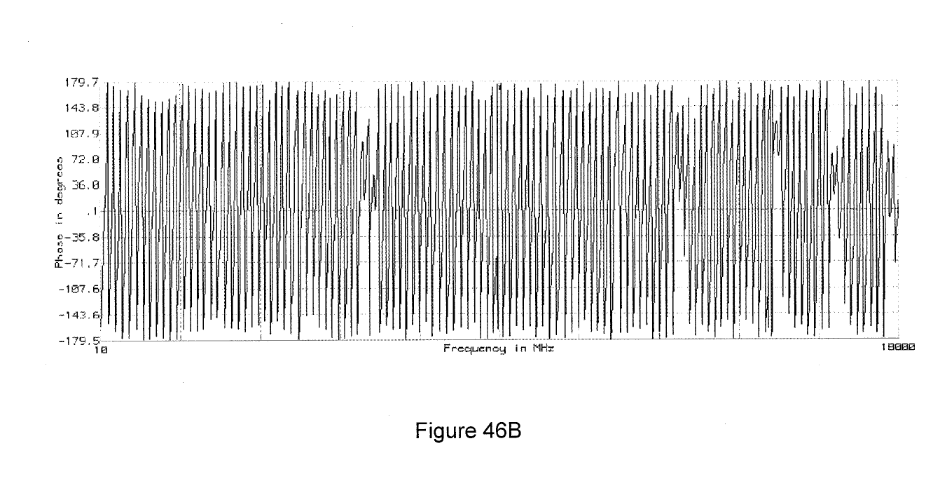

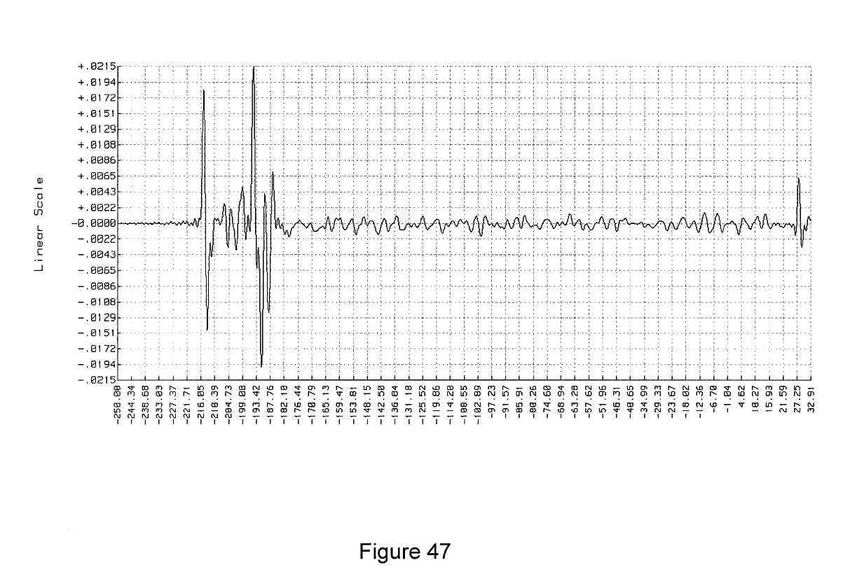

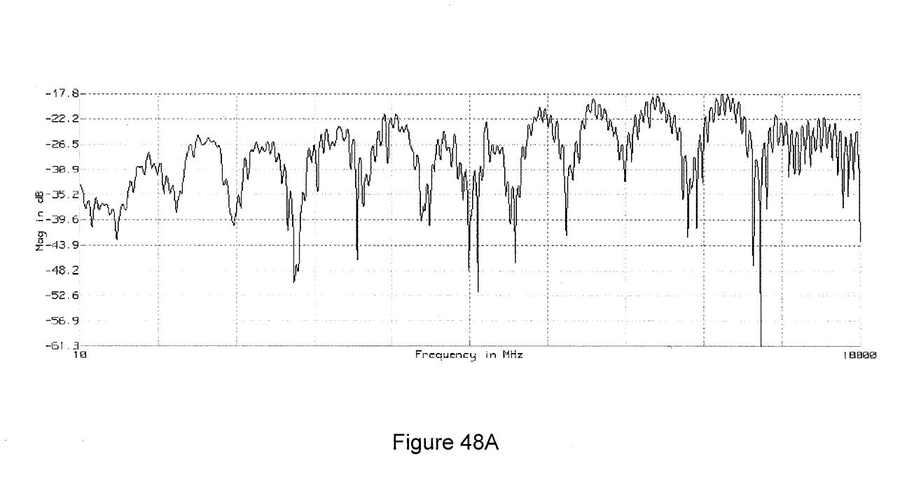

Referring to FIG. 45, the ratio of A/R1 is converted to time domain impulse response and gated between the port1 time start sweep and the port 2 DRP location of the high reflection standard. Then, the gated impulse response is converted back to frequency domain. The reconstructed frequency domain response is equivalent of putting a perfect termination on the original A/R1 frequency domain VNA measurement. FIGS. 46A and 46B illustrate the A/R1 magnitude (46A) and phase (46B) response as if a perfect termination is connected at the port 2 DRP. Referring to FIG. 47, the ratio of B/R2 is converted to time domain impulse response and gated between the port 2 time start sweep and the port 4 DRP location of the high reflection standard. Then, the gated impulse response is converted back to frequency domain. As discussed above, the reconstructed frequency domain response is equivalent of putting a perfect termination on the original B/R2 frequency domain VNA measurement. FIGS. 48A and 48B illustrate the B/R2 magnitude (48A) and phase (48B) response as if a perfect termination is connected at the port 4 DRP.

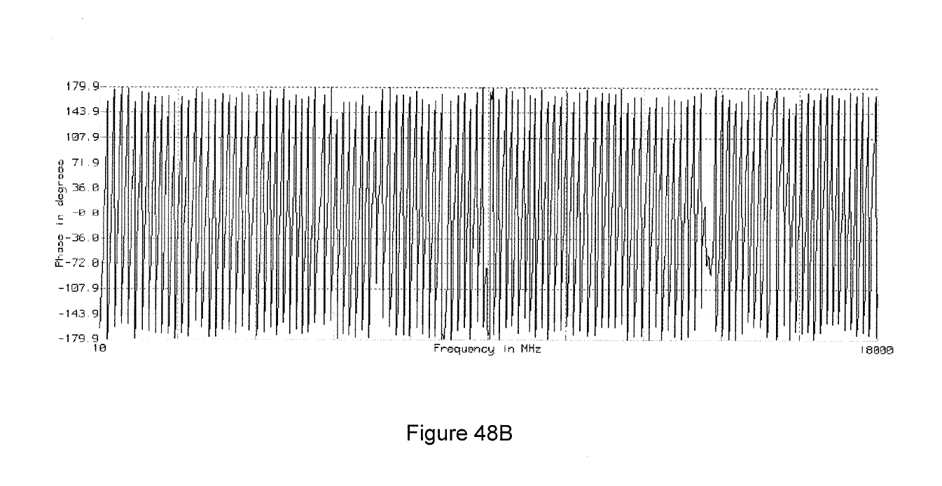

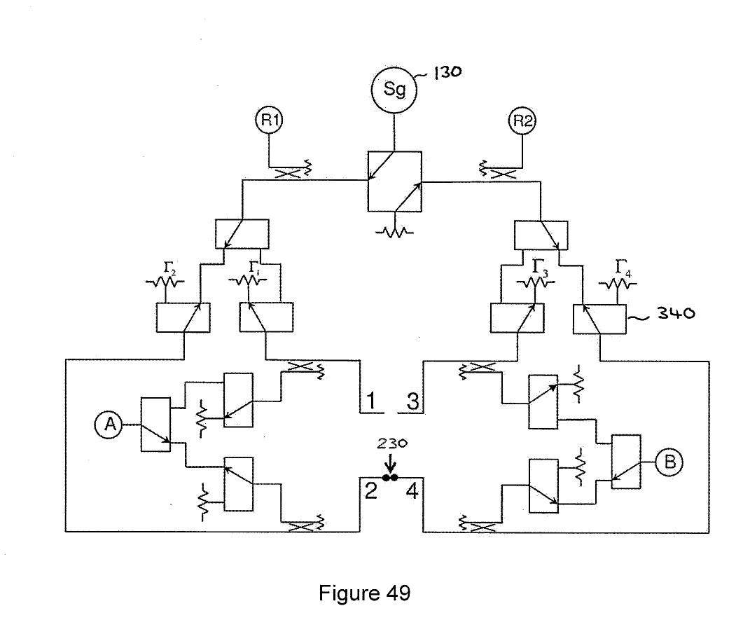

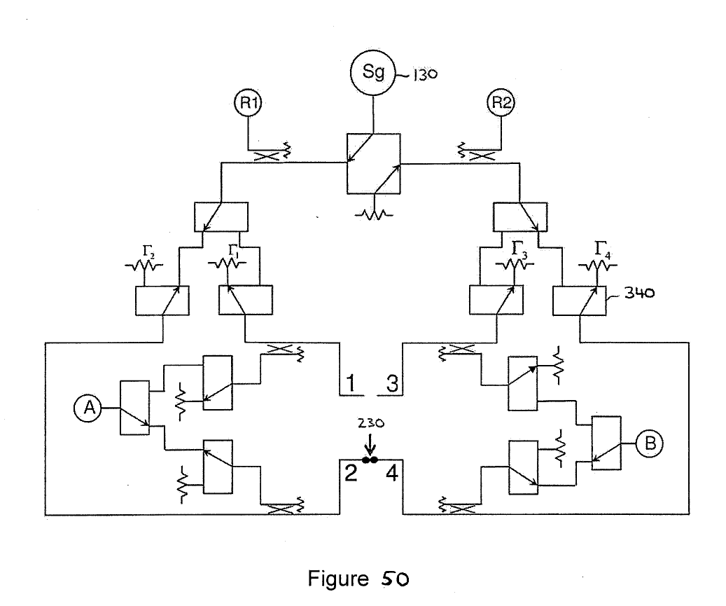

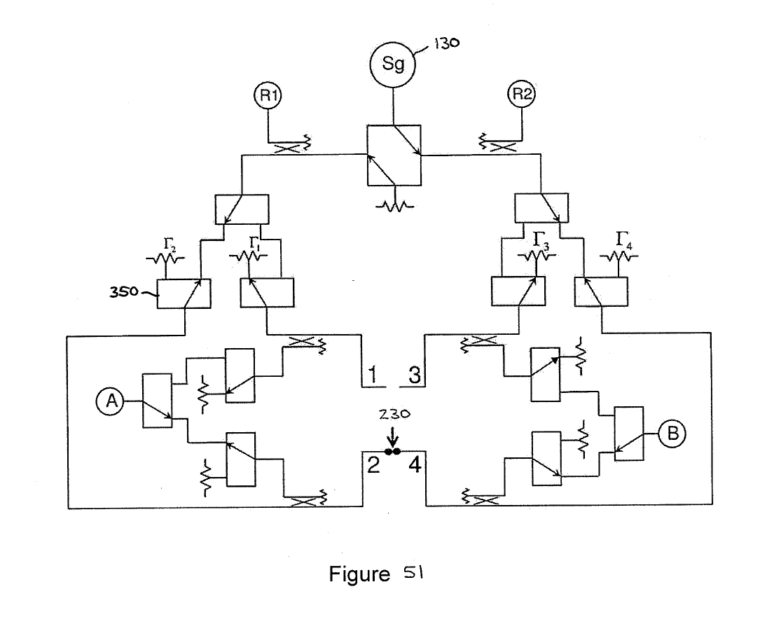

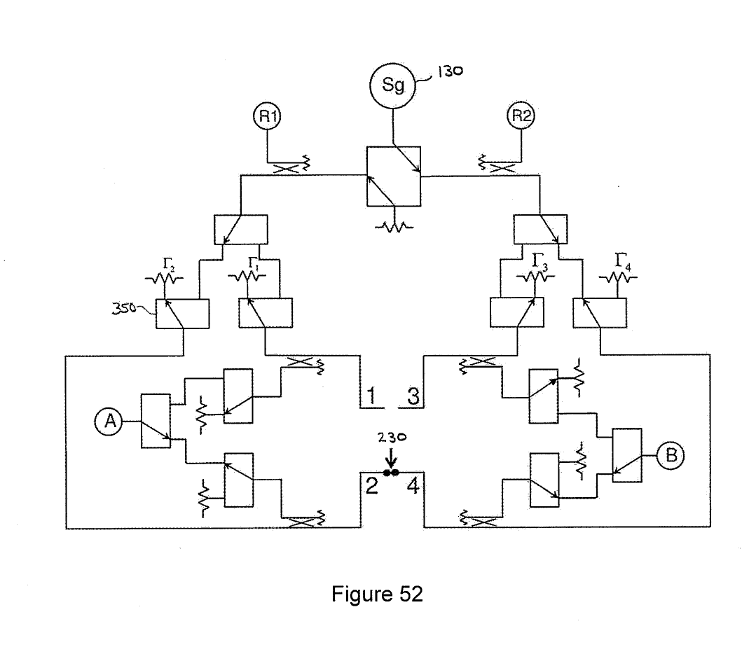

Referring to FIG. 49, the switches are set as shown to direct the signal generator 130 to the R1 reference channel path, the port 2 DRP is connected directly to the port 4 DRP as a thru standard connection 230, and R1, A, B and R2 receiver channels are measured by sweeping the signal generator through the same desired frequency range as before. With reference to FIG. 50, the thru connection is left as is, and the switch 340 is changed into its other position (i.e., changes state relative to its position in FIG. 49) and A/R1 and B/R1 are measured. With reference to FIG. 51, the signal generator 130 is directed to R2 reference channel path by the switch settings shown in the diagram, and then R2, B, A and R1 receiver channels are measured. With reference to FIG. 52, the thru standard 230 remains connected as before, the switch 350 is changed to its other position, and B/R2 and A/R2 are measured.

By connecting the unknown shorts, high quality terminations to ports plus thru standards between ports 1-3 and ports 2-4, all systematic error coefficients for six, two-port paths are determined with exception of transmission tracking terms for some paths. The transmission tracking terms for paths 1-3 and paths 2-4 are known. In order to determine the transmission tracking terms for other paths at least one more thru standard has to be connected. In other words, in an N-port calibration having N(N−1)/2 two-port paths, N−1 thru standard connections have to be made. For a four-port calibration having six two-port paths three thru standards are required. Generally speaking from the plurality of thru standards in a multiport calibration, a set may be selected such that the least physical stress is exerted on the flexible test port cables while connecting the subject DUT 310. The wearing-out, stress and physical changes of cable position from its original orientation are non-repeatability issues that become a major source of error regardless of calibration methodology. A good choice of thru standard connections is direct opposite ports, such as 1-3 & 2-4 and closest direct opposite diagonal ports such as 1-4 & 2-3. Thru connections such as 1-2 & 3-4 exert maximum stress to flexible test port cables.

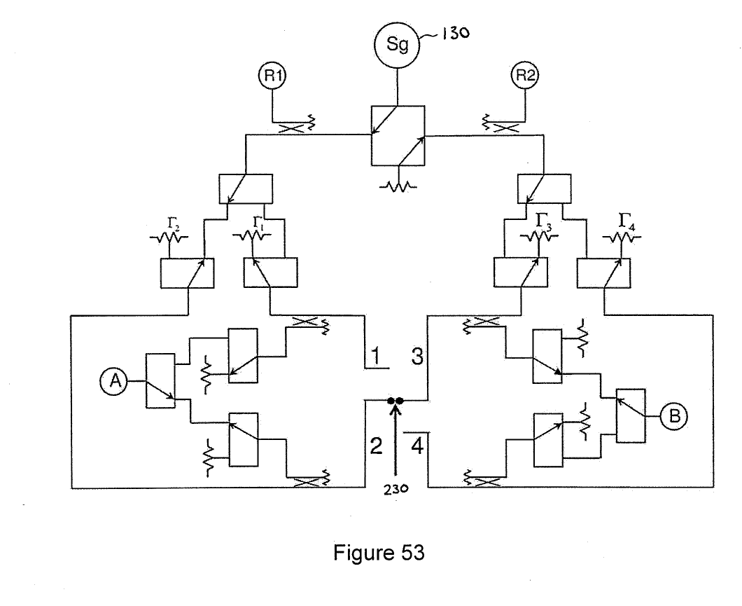

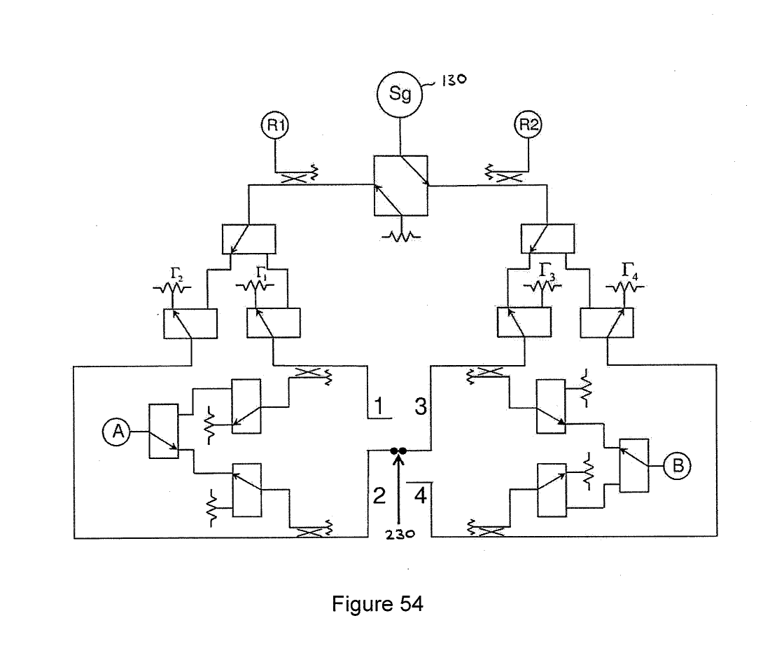

With reference to FIG. 53, from Equation (26), the transmission tracking for the thru connection 2-3 (i.e., with port 2 connected to port 3, as shown) when the signal is directed to R1 reference channel can be determined. Similarly, with reference to FIG. 54, from Equation (28), the transmission tracking for thru connection 2-3 when the signal is directed to R2 reference channel can be determined. The correct corresponding error coefficients are substituted in Equations (26) and (28).

The unknown two-port transmission tracking paths can be calculated from the known adjacent transmission and reflection tracking paths. τ_{ab} is the transmission tracking where the signal is sourced at “a” and travels toward “b”. Rₚ is the reflection tracking term for port “p”.

The path 1-2 transmission tracking terms can be calculated from path 1-3 and path 2-3 from the following:

$${τ}_{21} = \frac{{R}_{2} {τ}_{31}}{{τ}_{32}} , \\ {τ}_{12} = \frac{{R}_{1} {R}_{2}}{{τ}_{21}} \qquad ( 29 )$$

The path 3-4 transmission tracking terms can be calculated from path 2-3 and path 2-4 from the following:

$${τ}_{43} = \frac{{R}_{3} {τ}_{42}}{{τ}_{32}} , \\ {τ}_{34} = \frac{{R}_{3} {R}_{4}}{{τ}_{43}} \qquad ( 30 )$$

The path 1-4 transmission tracking terms can be calculated from path 1-2 and path 2-4 from the following:

$${τ}_{41} = \frac{{τ}_{21} {τ}_{42}}{{R}_{2}} , \\ {τ}_{14} = \frac{{R}_{1} {R}_{4}}{{τ}_{41}} \qquad ( 31 )$$

The general solution for Equation (29), an unknown x-y transmission tracking term derived from path x-c and path y-c where y>x is given by:

$${τ}_{yx} = \frac{{R}_{3} {τ}_{cx}}{{τ}_{cy}} , \\ {τ}_{xy} = \frac{{R}_{x} {R}_{y}}{{τ}_{yx}} \qquad ( 32 )$$

The general solution for Equation (30), an unknown x-y transmission tracking term derived from path c-x and path c-y where y>x is given by:

$${τ}_{yx} = \frac{{R}_{x} {τ}_{yc}}{{τ}_{xc}} , \\ {τ}_{xy} = \frac{{R}_{x} {R}_{y}}{{τ}_{yx}} \qquad ( 33 )$$

The general solution for Equation (31), an unknown x-y transmission tracking term derived from path x-c and path c-y where y>x is given by:

$${τ}_{yx} = \frac{{τ}_{cx} {τ}_{yc}}{{R}_{c}} , \\ {τ}_{xy} = \frac{{τ}_{x} {R}_{y}}{{τ}_{yx}} \qquad ( 34 )$$

Conventional calibration procedures require precise knowledge of the calibration standards at any desired frequency. By contrast, that requirement is not present with embodiments of the uSLT procedure discussed above. Instead, as discussed above, unknown calibration standards can be used. In one example, very accurate measurements can be deduced if the termination standard has a 25 to 30 dB return loss at the highest frequency and high reflection standard has about a 3 dB return loss. Embodiments of the uSLT procedure are ideal for non-coaxial media where there is no NIST traceability for the calibration standards. In-fixture, on-wafer and some non-traceable quick-connect and disconnect coaxial connectors may also benefit from the uSLT procedure.

Once the systematic error coefficients for all six paths are determined, then the DUT 310 is inserted for measurement. In one embodiment, although there are six two-port paths corresponding to 24 S-parameters, only 16 S-parameters are measured. As discussed above, the redundant reflection coefficients are not measured. Each DUT's two-port path is corrected by its corresponding systematic error coefficients. Since the load Γ_{L} and source Γ_{S} reflection coefficients of each six paths are not a perfect match, then each path has to be normalized with its corresponding load and source reflection coefficients before they are put into their normalized 4-by-4, S-parameter matrix. Each two-port path is normalized by:

Snⱼ=[Γ*+S][I−ΓS]⁻¹ j=1, 2, . . . , N(N−1)/2 (35)

$$Γ = [ \begin{matrix}{Γ}_{s} & 0 \\ 0 & {Γ}_{L}\end{matrix} ] ,$$

Γ* is complex conjugate of Γ (Hermitian conjugate) and

$$I = [ \begin{matrix}1 & 0 \\ 0 & 1\end{matrix} ]$$

is the 2-by-2 identity matrix. The six two-port normalized S-parameters are grouped into a one 4-by-4 matrix. The normalized 4-by-4, S-parameter matrix is given by Sn:

$$Sn = [ \begin{matrix}{S}_{11 n} & {S}_{21 n} & {S}_{13 n} & {S}_{14 n} \\ {S}_{21 n} & {S}_{22 n} & {S}_{23 n} & {S}_{24 n} \\ {S}_{31 n} & {S}_{32 n} & {S}_{33 n} & {S}_{34 n} \\ {S}_{41 n} & {S}_{42 n} & {S}_{43 n} & {S}_{44 n}\end{matrix} ] \qquad ( 36 )$$

Also, the six two-port matrix of load reflection coefficients, are grouped into one 4 by 4 matrix and given by Γ

$$Γ = [ \begin{matrix}{Γ}_{1} & 0 & 0 & 0 \\ 0 & {Γ}_{2} & 0 & 0 \\ 0 & 0 & {Γ}_{3} & 0 \\ 0 & 0 & 0 & {Γ}_{4}\end{matrix} ] \qquad ( 37 )$$

Defining I, the 4-by-4 identity matrix as:

$$I = [ \begin{matrix}1 & 0 & 0 & 0 \\ 0 & 1 & 0 & 0 \\ 0 & 0 & 1 & 0 \\ 0 & 0 & 0 & 1\end{matrix} ] \qquad ( 38 )$$

Then finally, the DUT 4-by-4, S-parameter matrix is given by:

S=[I+SnΓ]⁻¹[Sn−Γ*] (39)

Or, S in matrix form is presented by:

$$S = [ \begin{matrix}{S}_{11 } & {S}_{21} & {S}_{13 } & {S}_{14 } \\ {S}_{21 } & {S}_{22 } & {S}_{23 } & {S}_{24 } \\ {S}_{31 } & {S}_{32 } & {S}_{33 } & {S}_{34 } \\ {S}_{41 } & {S}_{42 } & {S}_{43 } & {S}_{44 }\end{matrix} ] \qquad ( 40 )$$

Although, 4-by-4 matrix was used as an example, the algorithmic formulation is applicable to any N-port VNA calibration and measurement.

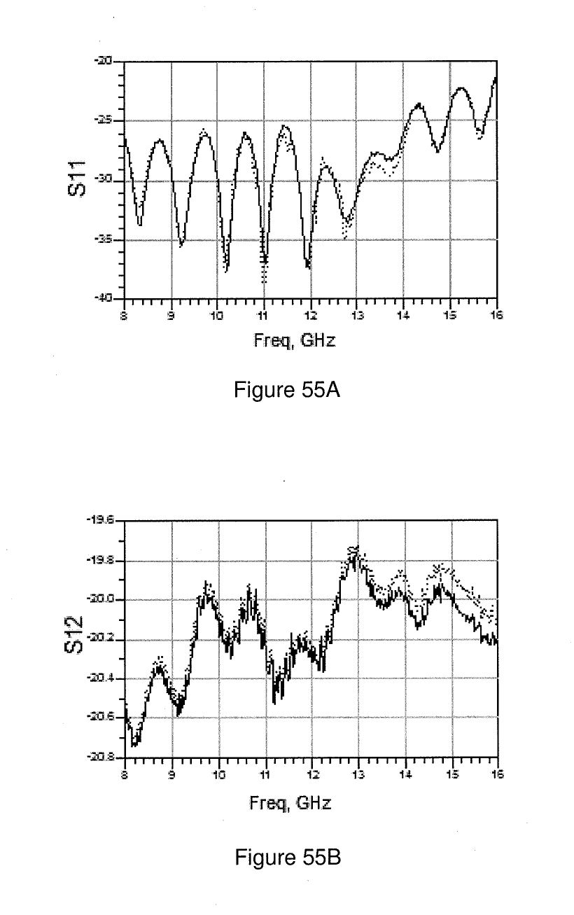

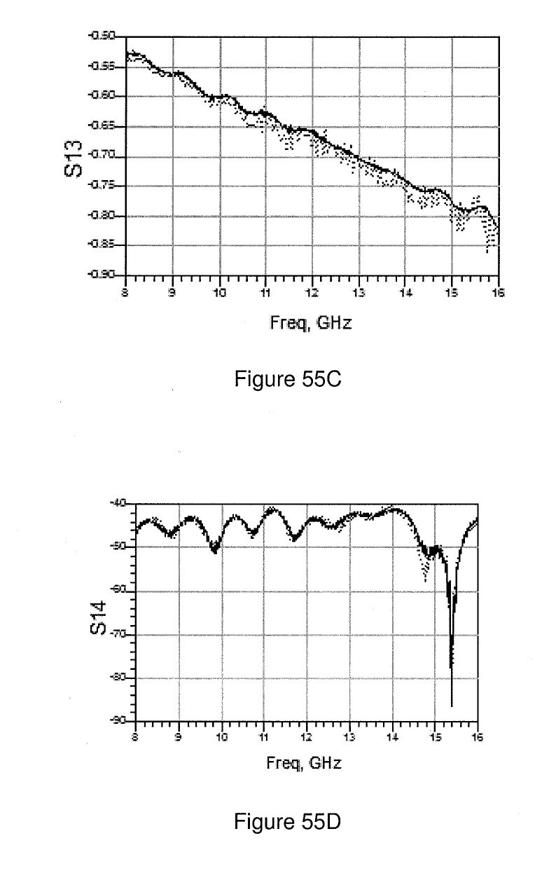

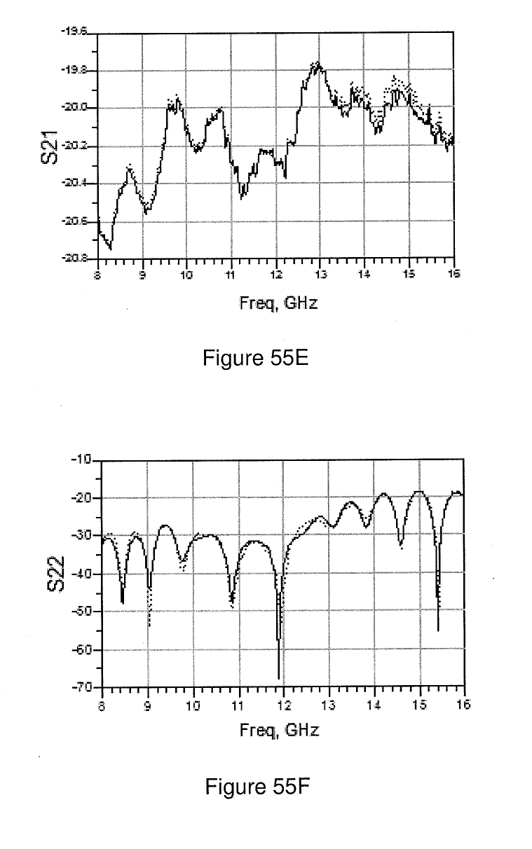

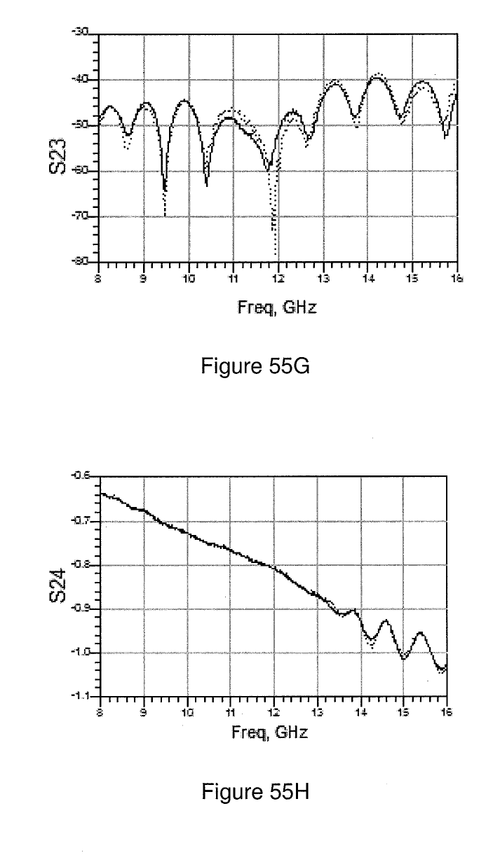

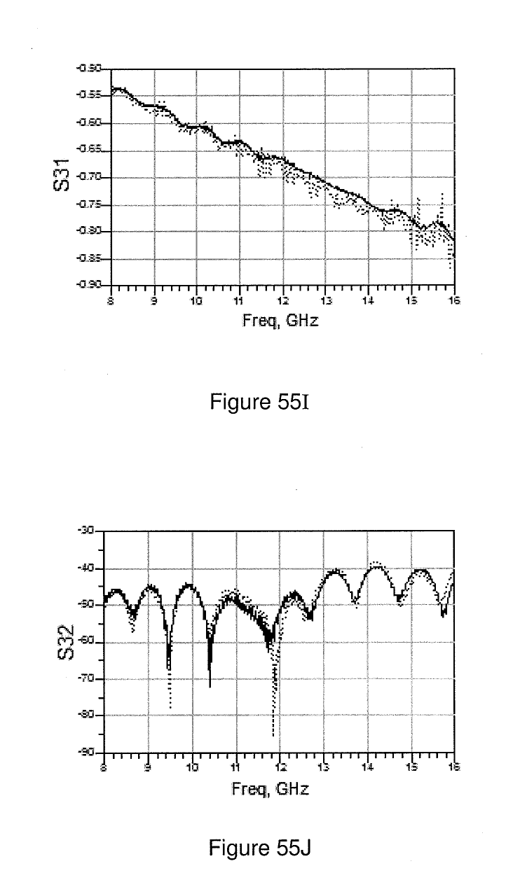

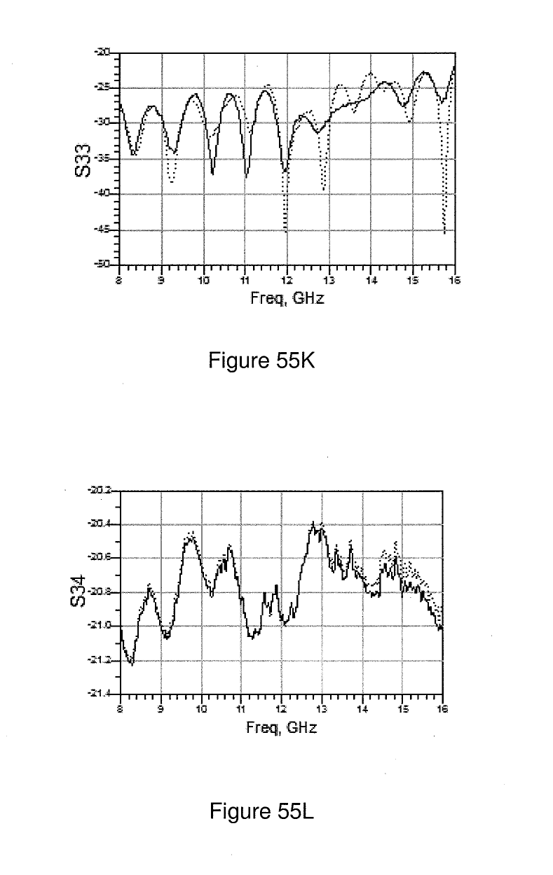

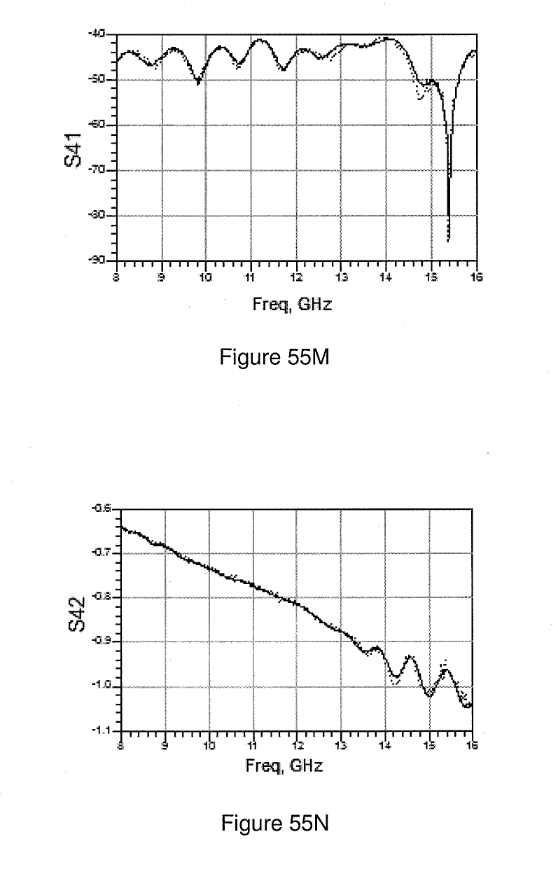

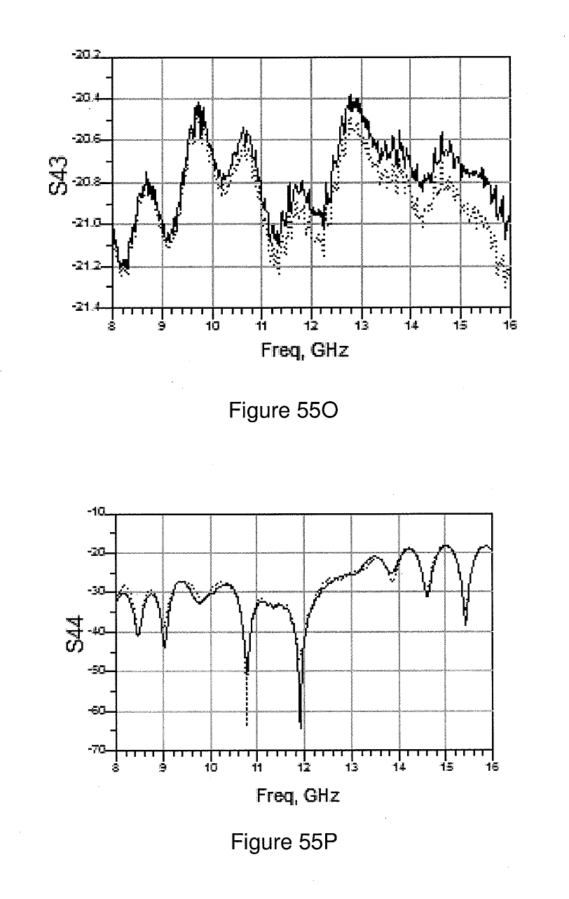

FIGS. 55A-55P illustrate the overlay of S-parameter magnitude of a directional coupler measured on the same VNA by using TRL and SOLT calibration. In each of FIGS. 55A-55P, the SOLT data is shown as the dotted lines and the TRL data is shown as the solid lines. Table 1 below presents the min, max and vectorial RMS correlation between TRL and SOLT. All data is in dB; frequency is in MHz. The min and max presents the best and worst correlation at a given frequency; the RMS vectorial difference is given across all frequencies. Larger magnitude implies a better correlation with TRL calibration procedure. TRL is the most accurate calibration procedure.

TABLE 1
Statistical Correlation Between TRL and SOLT

| | | | |
|---|---|---|---|
| MIN = −68.09 at Freq = 15360.00 | MAX = −37.36 at Freq = 11560.00 | RMS = −45.20 | S11 |
| MIN = −64.49 at Freq = 11830.00 | MAX = −51.30 at Freq = 15140.00 | RMS = −55.93 | S12 |
| MIN = −47.89 at Freq = 12120.00 | MAX = −35.13 at Freq = 15740.00 | RMS = −41.61 | S13 |
| MIN = −88.44 at Freq = 10360.00 | MAX = −55.89 at Freq = 12900.00 | RMS = −62.41 | S14 |
| MIN = −83.82 at Freq = 12740.00 | MAX = −55.44 at Freq = 15170.00 | RMS = −63.48 | S21 |
| MIN = −71.63 at Freq = 8450.00 | MAX = −37.70 at Freq = 13420.00 | RMS = −44.52 | S22 |
| MIN = −94.48 at Freq = 9430.00 | MAX = −49.46 at Freq = 15940.00 | RMS = −57.62 | S23 |
| MIN = −41.86 at Freq = 13420.00 | MAX = −38.32 at Freq = 14910.00 | RMS = −40.08 | S24 |
| MIN = −46.77 at Freq = 8000.00 | MAX = −35.48 at Freq = 15740.00 | RMS = −41.13 | S31 |
| MIN = −83.57 at Freq = 8250.00 | MAX = −49.15 at Freq = 15950.00 | RMS = −57.15 | S32 |
| MIN = −67.94 at Freq = 8350.00 | MAX = −26.91 at Freq = 15730.00 | RMS = −34.91 | S33 |
| MIN = −69.77 at Freq = 8150.00 | MAX = −52.86 at Freq = 15880.00 | RMS = −59.63 | S34 |
| MIN = −99.16 at Freq = 11270.00 | MAX = −57.24 at Freq = 12920.00 | RMS = −63.12 | S41 |
| MIN = −42.86 at Freq = 15300.00 | MAX = −38.32 at Freq = 15640.00 | RMS = −40.34 | S42 |
| MIN = −60.57 at Freq = 8100.00 | MAX = −46.99 at Freq = 15700.00 | RMS = −52.26 | S43 |
| MIN = −75.82 at Freq = 8930.00 | MAX = −36.58 at Freq = 14300.00 | RMS = −43.40 | S44 |

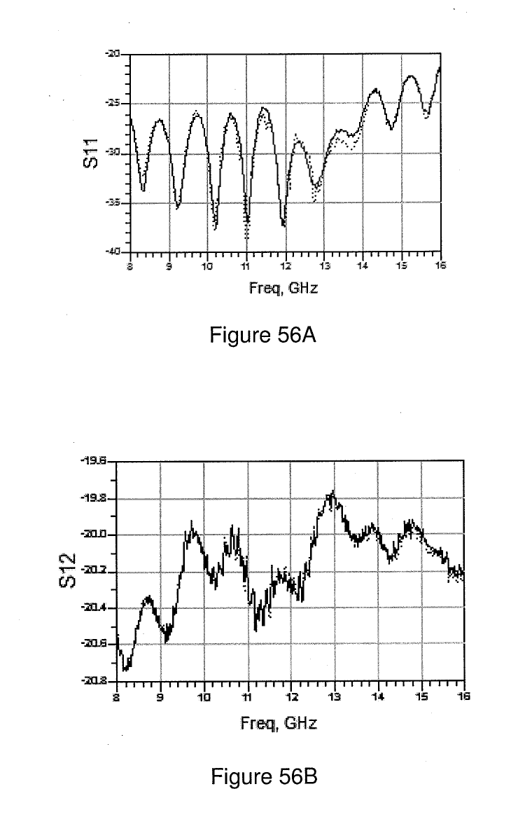

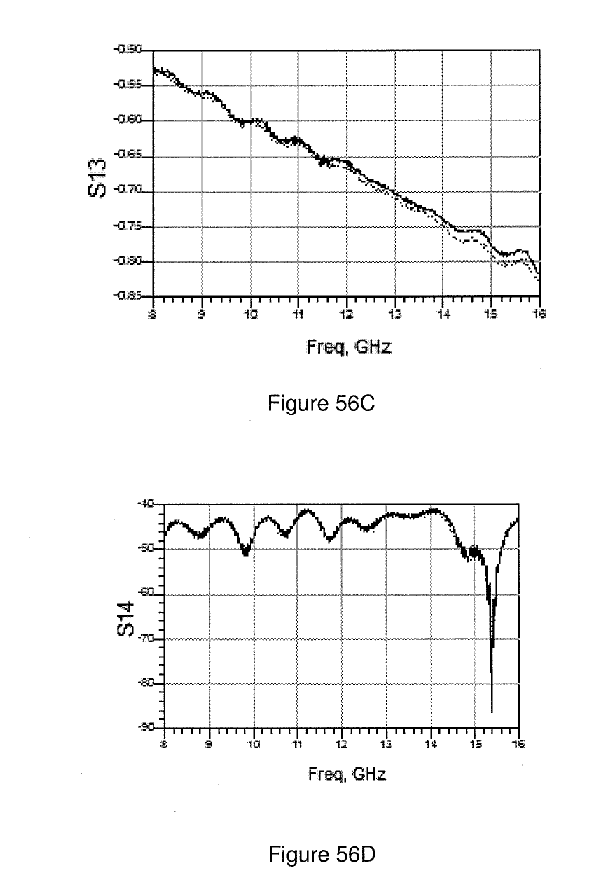

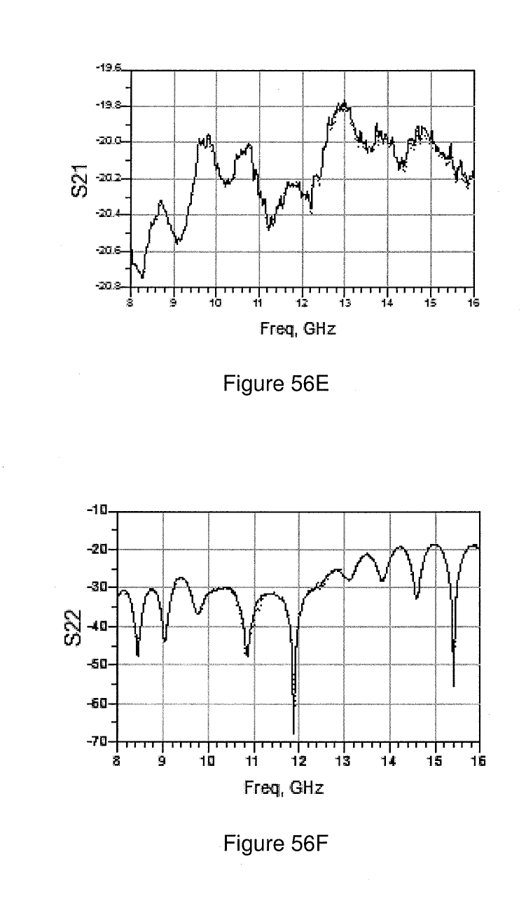

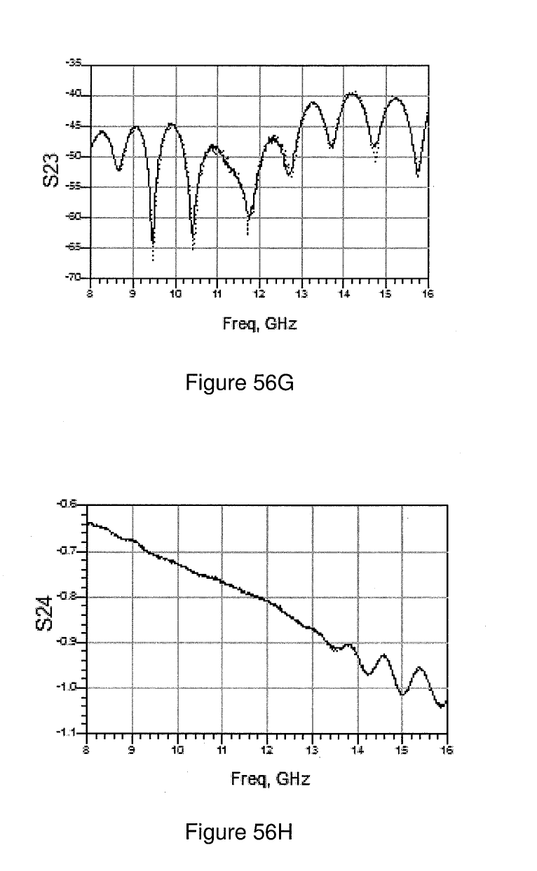

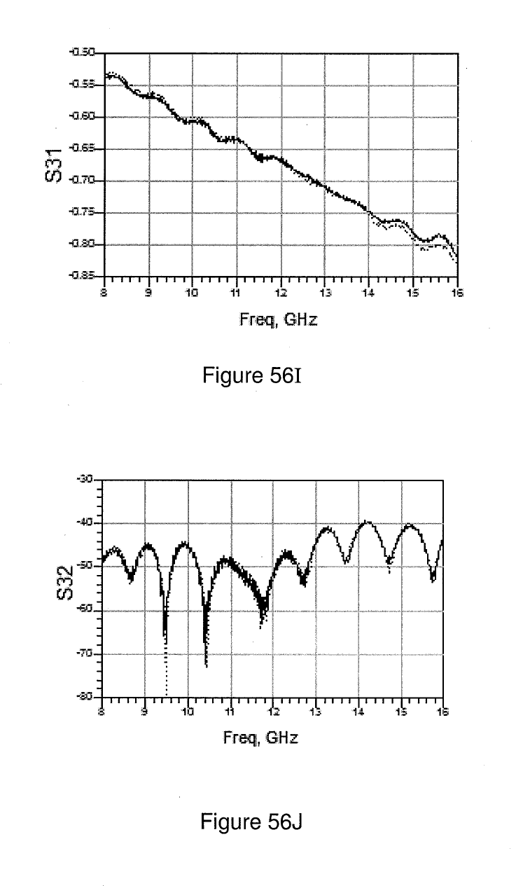

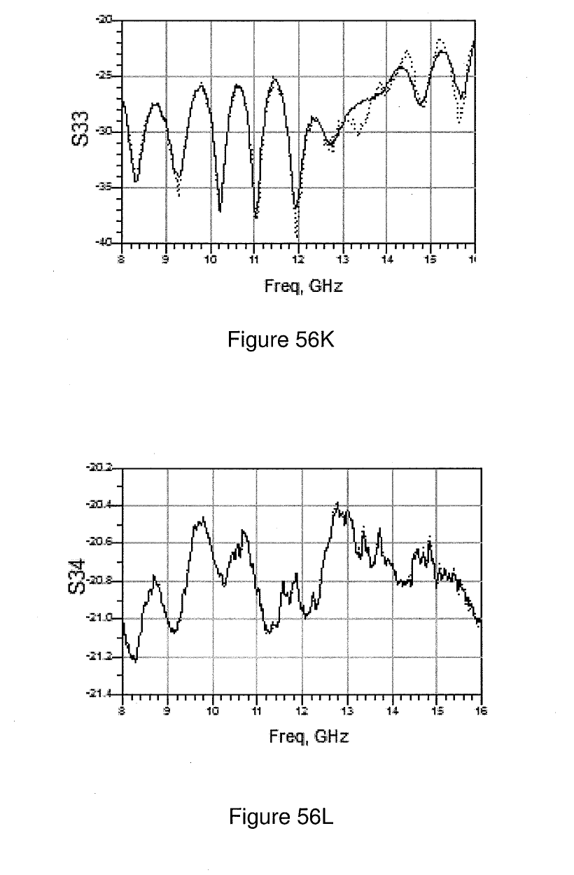

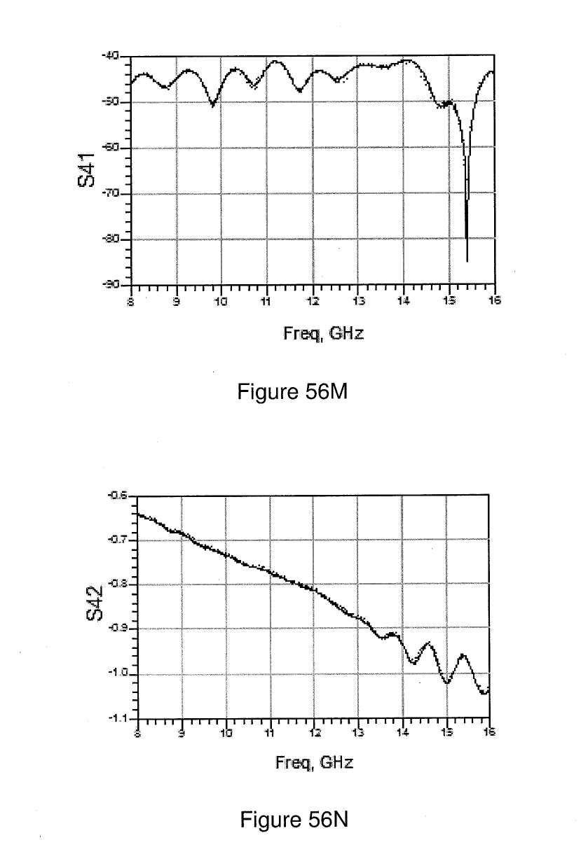

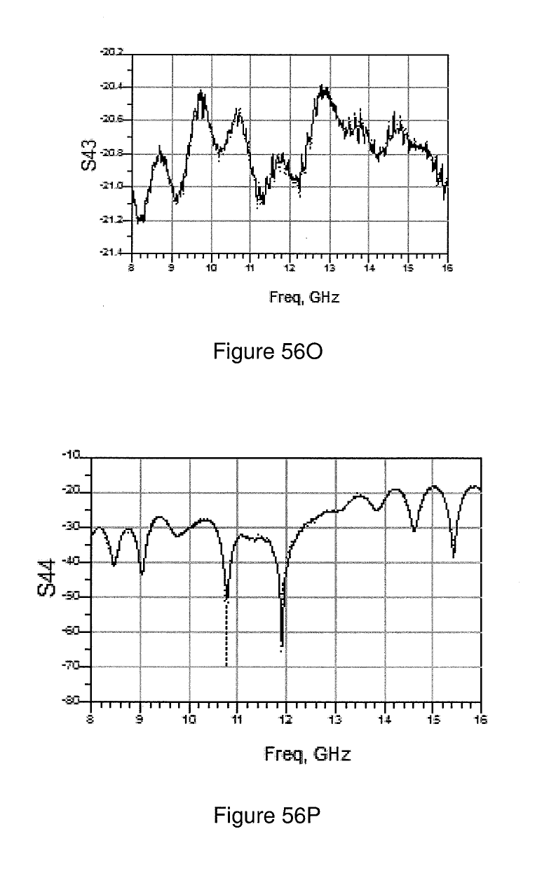

FIGS. 56A-56P illustrate the overlay of S-parameter magnitude of the directional coupler measurement with the same VNA using uSLT (according to an embodiment of the present invention) calibration and overlaid with the TRL data of FIGS. 55A-55P, respectively. In FIGS. 56A-56P, the dotted lines represent the uSLT data and the solid lines represent the TRL data. Table 2 below presents a statistical comparison between TRL and uSLT procedure. Analyzing the RMS vectorial differences, there is significantly better correlation between uSLT and TRL calibration procedure. All data is in dB, with frequency in MHz.

TABLE 2
Statistical Correlation Between TRL and uSLT

| | | | |
|---|---|---|---|
| MIN = −73.68 at Freq = 14640.00 | MAX = −38.42 at Freq = 11520.00 | RMS = −47.66 | S11 |
| MIN = −67.96 at Freq = 12540.00 | MAX = −50.92 at Freq = 15430.00 | RMS = −56.90 | S12 |
| MIN = −52.84 at Freq = 8520.00 | MAX = −45.38 at Freq = 15670.00 | RMS = −47.88 | S13 |
| MIN = −95.61 at Freq = 13770.00 | MAX = −58.31 at Freq = 12740.00 | RMS = −66.82 | S14 |
| MIN = −95.65 at Freq = 9270.00 | MAX = −62.67 at Freq = 14400.00 | RMS = −70.65 | S21 |
| MIN = −89.30 at Freq = 8080.00 | MAX = −36.71 at Freq = 15730.00 | RMS = −50.26 | S22 |
| MIN = −94.71 at Freq = 11850.00 | MAX = −56.80 at Freq = 14530.00 | RMS = −65.24 | S23 |
| MIN = −52.61 at Freq = 8080.00 | MAX = −46.14 at Freq = 14980.00 | RMS = −48.88 | S24 |
| MIN = −52.17 at Freq = 8480.00 | MAX = −46.26 at Freq = 14680.00 | RMS = −48.44 | S31 |
| MIN = −87.16 at Freq = 10970.00 | MAX = −55.52 at Freq = 15150.00 | RMS = −62.77 | S32 |
| MIN = −72.90 at Freq = 12490.00 | MAX = −34.12 at Freq = 15710.00 | RMS = −44.25 | S33 |
| MIN = −74.42 at Freq = 11380.00 | MAX = −58.37 at Freq = 14960.00 | RMS = −63.30 | S34 |
| MIN = −97.75 at Freq = 8210.00 | MAX = −59.01 at Freq = 12740.00 | RMS = −67.85 | S41 |
| MIN = −55.58 at Freq = 8060.00 | MAX = −48.51 at Freq = 14950.00 | RMS = −51.77 | S42 |
| MIN = −61.02 at Freq = 8090.00 | MAX = −49.55 at Freq = 15290.00 | RMS = −54.26 | S43 |
| MIN = −93.52 at Freq = 13200.00 | MAX = −39.94 at Freq = 12950.00 | RMS = −49.33 | S44 |

A significant advantage of the procedure according to aspects and embodiments of the invention is the fact that all standards can be unknown. Therefore, it is an ideal method for fixture or on-wafer measurements where on-board calibration standards are not possible to characterize or have traceability. Referring to Table 3 below, a 20-port VNA has 190 two-port S-parameter combinations; all 2-by-2 S-parameters are listed.

TABLE 3
Number of Two-Port Combinations are N(N − 1)/2. There are 190 Two-Port
Connections for 20-Port Electronic Calibration

| | | | | | | | | | |
|---|---|---|---|---|---|---|---|---|---|
| 1-2 | | | | | | | | | |
| 1-3 | 2-3 | | | | | | | | |
| 1-4 | 2-4 | 3-4 | | | | | | | |
| 1-5 | 2-5 | 3-5 | 4-5 | | | | | | |
| 1-6 | 2-6 | 3-6 | 4-6 | 5-6 | | | | | |
| 1-7 | 2-7 | 3-7 | 4-7 | 5-7 | 6-7 | | | | |
| 1-8 | 2-8 | 3-8 | 4-8 | 5-8 | 6-8 | 7-8 | | | |
| 1-9 | 2-9 | 3-9 | 4-9 | 5-9 | 6-9 | 7-9 | 8-9 | | |
| 1-10 | 2-10 | 3-10 | 4-10 | 5-10 | 6-10 | 7-10 | 8-10 | 9-10 | |
| 1-11 | 2-11 | 3-11 | 4-11 | 5-11 | 6-11 | 7-11 | 8-11 | 9-11 | 10-11 |
| 1-12 | 2-12 | 3-12 | 4-12 | 5-12 | 6-12 | 7-12 | 8-12 | 9-12 | 10-12 |
| 1-13 | 2-13 | 3-13 | 4-13 | 5-13 | 6-13 | 7-13 | 8-13 | 9-13 | 10-13 |
| 1-14 | 2-14 | 3-14 | 4-14 | 5-14 | 6-14 | 7-14 | 8-14 | 9-14 | 10-14 |
| 1-15 | 2-15 | 3-15 | 4-15 | 5-15 | 6-15 | 7-15 | 8-15 | 9-15 | 10-15 |
| 1-16 | 2-16 | 3-16 | 4-16 | 5-16 | 6-16 | 7-16 | 8-16 | 9-16 | 10-16 |
| 1-17 | 2-17 | 3-17 | 4-17 | 5-17 | 6-17 | 7-17 | 8-17 | 9-17 | 10-17 |
| 1-18 | 2-18 | 3-18 | 4-18 | 5-18 | 6-18 | 7-18 | 8-18 | 9-18 | 10-18 |
| 1-19 | 2-19 | 3-19 | 4-19 | 5-19 | 6-19 | 7-19 | 8-19 | 9-19 | 10-19 |
| 1-20 | 2-20 | 3-20 | 4-20 | 5-20 | 6-20 | 7-20 | 8-20 | 9-20 | 10-20 |
| . . . | 11-12 | | | | | | | | |
| | 11-13 | 12-13 | | | | | | | |
| | 11-14 | 12-14 | 13-14 | | | | | | |
| | 11-15 | 12-15 | 13-15 | 14-15 | | | | | |
| | 11-16 | 12-16 | 13-16 | 14-16 | 15-16 | | | | |
| | 11-17 | 12-17 | 13-17 | 14-17 | 15-17 | 16-17 | | | |
| | 11-18 | 12-18 | 13-18 | 14-18 | 15-18 | 16-18 | 17-18 | | |
| | 11-19 | 12-19 | 13-19 | 14-19 | 15-19 | 16-19 | 17-19 | 18-19 | |
| | 11-20 | 12-20 | 13-20 | 14-20 | 15-20 | 16-20 | 17-20 | 18-20 | 19-20 |

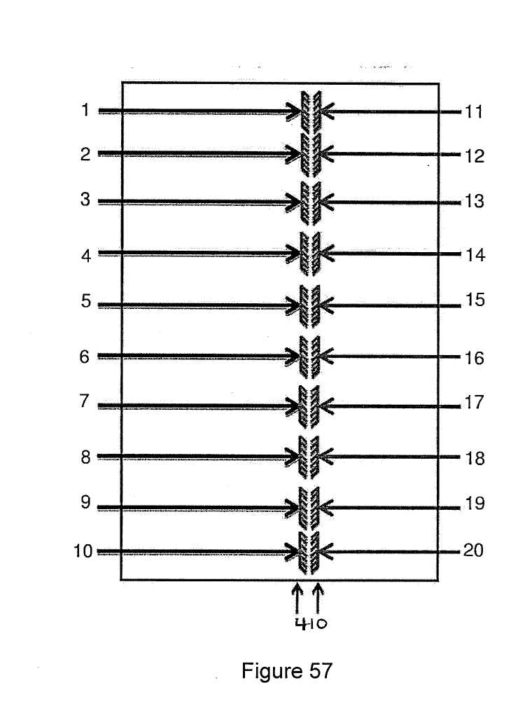

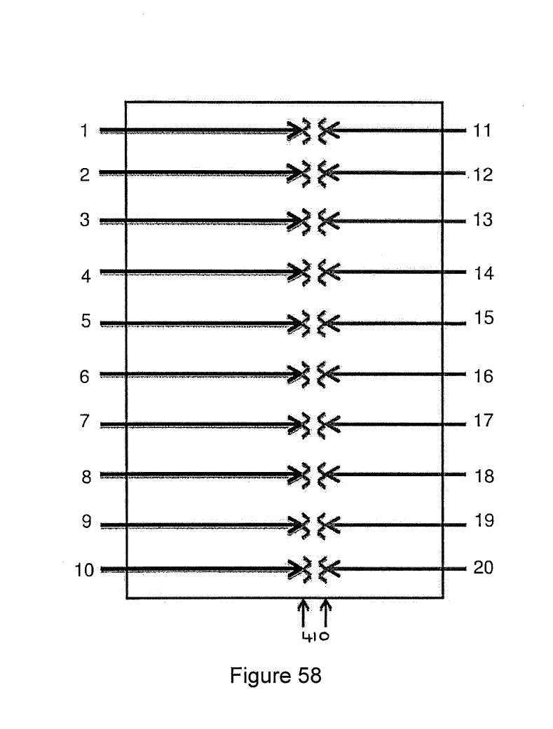

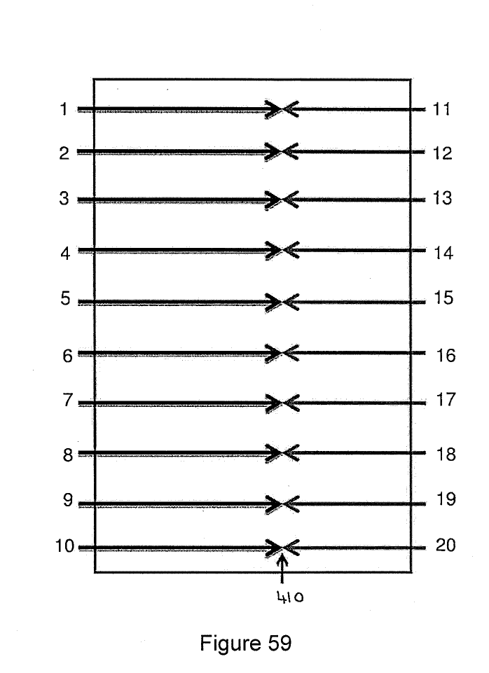

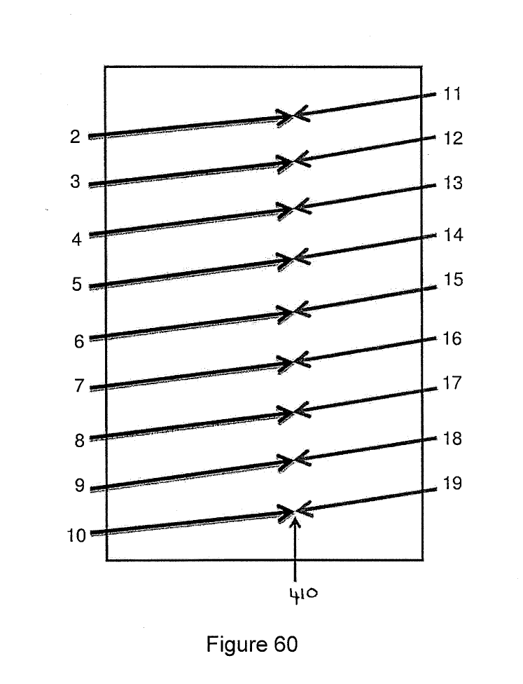

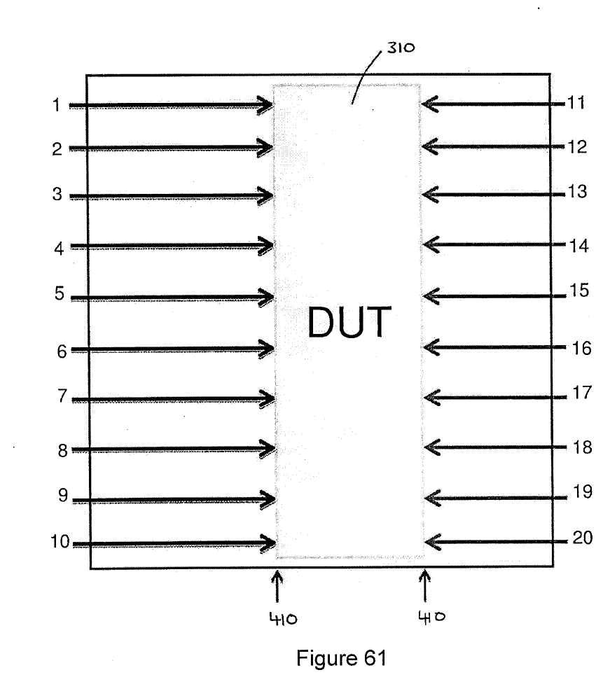

Referring to FIGS. 57 through 61, there are illustrated uSLT fixture calibration standards for systematic error correction of a 20-port VNA. FIG. 57 illustrates unknown short measurements at the device reference plane 410. All shorts are substantially the same. FIG. 58 illustrates the load measurements at the device reference plane 410. In one example, there is approximately 25 to 30 dB return loss at the highest measurement frequency. A 20-port calibration requires 19 thru measurements in order to calculate the transmission tracking terms. FIG. 59 shows 10 direct opposite port connections and FIG. 60 shows 9 closest direct opposite port connections. None of the traces have to be equal to each other, but electrically each trace from any fixture standard compared to its corresponding trace from another fixture standard has to be substantially the same. FIG. 61 shows the fixture where the DUT 310 is inserted for measurement. Again, electrically each trace of DUT fixture up to the device reference plane 410 must be substantially the same compared to its corresponding trace from another fixture standard.

With reference to FIG. 57 and FIG. 58, first the measured termination impulse response is time gated by the location of unknown high reflection standards. Then, the gated impulse response is converted back to frequency domain. As discussed above, the reconstructed frequency domain response is equivalent of putting a perfect termination on the measurement located at a specified DRP 410. Referring to FIG. 59 thru standard, from direct opposite port connection, directivity, source match and reflection tracking of each port is calculated. By programming the appropriate switches in the test-set the load matches and corresponding transmission tracking are calculated. Referring to FIG. 60 thru standard, from closest direct opposite port connection, the rest of transmission tracking terms are determined, as discussed above. From Equations (1) through (28), the systematic error coefficients of each two-port combination are calculated. Based on Equations (35) through (40), each DUT's 2-by-2, S-parameter matrix is corrected by its corresponding systematic error coefficients described by Equations (1) through (28). Each corrected 2-by-2, S-parameter matrix is normalized to the corresponding source and load impedances presented by the VNA. The normalized 2-by-2, S-parameter matrix is grouped into 20-by-20 S-parameter matrix where the redundant reflection terms are not used. Finally from Equation (39); the 20-by-20 normalized S-parameter matrix, 20-by-20 identity matrix and 20-by-20 load impedances matrix presented by the VNA, the standard 20-by-20 S-parameters are calculated.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only.

What is claimed is:

1. A method of calibrating a measurement path in a vector network analyzer having two reference receivers and first and second measurement ports, the method comprising:
presenting a high reflection calibration standard and measuring a reflection characteristic for each of the first and second measurement ports to provide high reflection data;
converting the high reflection data into the time domain and calculating a location of the high reflection calibration standard at each of a first device reference plane at the first measurement port and a second device reference plane at the second measurement port;
presenting a load calibration standard and measuring the reflection characteristic for each of the first and second measurement ports to provide load data;
converting the load data to the time domain to provide time domain impulse response load data;
gating the time domain impulse response load data based on the locations of the high reflection calibration standard at each of the first and second device reference planes to provide gated time domain data;
reconstructing frequency domain load data from the gated time domain data to provided reconstructed frequency domain data;
connecting the first and second measurement ports together and measuring forward and reverse transmission characteristics; and
calculating systematic error coefficients for the vector network analyzer based on the reconstructed frequency domain data and the forward and reverse transmission characteristics.

2. The method of claim 1, wherein calculating the systematic error coefficients includes calculating directivity, source match, load match, reflection tracking, and transmission tracking error coefficients for each of the first and second measurement ports.

3. The method of claim 1, wherein presenting the high reflection standard includes presenting a short circuit.

4. The method of claim 1, wherein presenting the high reflection standard includes presenting an open circuit.

5. The method of claim 1, wherein presenting the load calibration standard includes presenting matched loads to each of the first and second measurement ports.

6. The method of claim 1, further comprising measuring a device and de-embedding measurements of the device using the systematic error coefficients of the vector network analyzer.

7. The method of claim 1, wherein presenting the high reflection calibration standard, the load calibration standard and the connecting the first and second measurement ports together comprises providing an electronic calibration standard and coupling the electronic calibration standard to the first and second measurement ports.

8. The method of claim 1, wherein presenting the high reflection calibration standard and the load calibration standard comprises providing mechanical calibration standards and coupling the mechanical calibration standards to the first and second measurement ports.

9. The method of claim 1, wherein measuring the reflection characteristics and measuring forward and reverse transmission characteristics includes:
measuring raw data from each of the two reference receivers and first and second measurement ports; and
from the raw data, determining the reflection characteristics and the forward and reverse transmission characteristics.

10. An apparatus for calibrating a measurement path comprising:
a vector network analyzer having at least two reference receivers, two test channels, a first measurement port and a second measurement port;
means for measuring and storing high reflection characteristics for each of the first and second measurement ports when a high reflection calibration standard is connected thereto, load reflection characteristics for each of the first and second measurement ports when a matched load calibration standard is attached thereto, and through forward and reverse reflection and transmission characteristics for each of the first and second measurement ports when connected to each other;
a processor configured to convert the high reflection characteristics into reflection time-domain data and calculate a location of the high reflection calibration standard at each of the first and second measurement ports, to convert the load reflection characteristics into load time-domain data, to gate the load time-domain data by the location of the high reflection calibration standard at each respective measurement port to provide gated load time-domain data, and to reconstruct corrected frequency-domain load reflection characteristics from the gated load time-domain data, the controller being further configured to calculate error coefficients for the first and second measurement ports based on the corrected frequency-domain load reflection characteristics and the through forward and reverse reflection and transmission characteristics.

11. The apparatus of claim 10, wherein the error coefficients include directivity, source match, load match, transmission tracking, and reflection tracking coefficients.

12. The apparatus of claim 10, further comprising:
means for measuring two port device resulting in a raw measurement of the device; and
wherein the controller is further configured to correct the raw measurement using the error coefficients.

13. The apparatus of claim 10, wherein the high reflection calibration standard is a short circuit calibration standard.

14. The apparatus of claim 10, wherein the high reflection calibration standard is an open circuit calibration standard.

15. The apparatus for measuring as recited in claim 10, wherein said means for measuring further comprises means for measuring a two port device to obtain DUT measurements, and wherein said processor is further configure to correct said DUT measurements using the error coefficients for the first and second measurement ports.

16. A method of measuring a device under test comprising:
providing a vector network analyzer having at least two measurement ports;
measuring a first reflection characteristic of a high reflection calibration standard at each measurement port;
measuring a second reflection characteristic of a matched load calibration standard at each measurement port;
converting the first reflection characteristic from frequency-domain into an input time-domain impulse response and calculating a location of the high reflection calibration standard at a device reference plane of each measurement port;
converting the second reflection characteristic from the frequency domain into a time-domain impulse response and gating the time domain impulse response by the location of the high reflection calibration standard at the device reference plane of each respective measurement port;
reconstructing a corrected second reflection characteristic from the gated time-domain impulse response;
connecting the measurement ports together and measuring forward and reverse reflection and transmission characteristics;
calculating error coefficients for the at least two measurement ports based upon the forward and reverse reflection and transmission characteristics and the corrected second reflection characteristic;
connecting the device under test to the measurement ports;
measuring S-parameters at the measurement ports; and
correcting for systematic errors in the S-parameters based upon the error coefficients to yield a corrected S-parameter matrix for the device under test.

17. The method of claim 16, wherein the vector network analyzer further includes two reference channels, and wherein measuring the first and second reflection characteristics includes:
collecting first raw data from each of the two reference channels and the at least two measurement ports; and
determining the first and second reflection characteristics from the first raw data.

18. The method of claim 17, wherein measuring the forward and reverse reflection and transmission characteristics includes:
collecting second raw data from each of the two reference channels and the at least two measurement ports; and
determining the forward and reverse reflection and transmission characteristics from the second raw data.

19. The method of claim 16, wherein calculating the error coefficients includes calculating directivity, source match, load match, reflection tracking, and transmission tracking error coefficients for each of the at least two measurement ports.
